(19) United States
(12) Patent Application Publication
(10) Pub. No.: US 2024/0014218 A1
(43) Pub. Date: Jan. 11, 2024

(54) SEMICONDUCTOR DEVICE AND METHOD OF FABRICATING THE SEMICONDUCTOR DEVICE

(71) Applicant: Semiconductor Energy Laboratory Co., Ltd., Atsugi-shi, Kanagawa-ken (JP)

(72) Inventors: Rai SATO, Tochigi (JP); Yasuharu HOSAKA, Tochigi (JP); Yasutaka NAKAZAWA, Tochigi (JP); Takashi SHIRAISHI, Tochigi (JP); Kiyofumi OGINO, Isehara (JP); Kenichi OKAZAKI, Atsugi (JP)

(21) Appl. No.: 18/035,150

(22) PCT Filed: Nov. 8, 2021
(86) PCT No.: PCT/IB2021/060296

§ 371 Date: May 3, 2023

(30) Foreign Application Priority Data
Nov. 17, 2020 (JP) 2020-191029

(51) Int. Cl. H01L 27/12; H01L 29/423; H01L 29/786

(52) U.S. Cl. CPC H01L 27/1225; H01L 29/42384; H01L 29/78696; H01L 29/7869; H01L 27/1288; H01L 2029/42388; G02F 1/1368

(57) ABSTRACT

A semiconductor device including a transistor with high on-state current and a fabrication method thereof are provided. A semiconductor device having favorable electrical characteristics and a fabrication method thereof are provided. The semiconductor device includes a substrate, an island-shaped insulating layer over the substrate, and a transistor over the substrate and the insulating layer. The transistor includes a gate electrode, a gate insulating layer, a semiconductor layer, and a pair of conductive layers. One of the pair of the conductive layers includes a region overlapping with the insulating layer, and the other of the pair of the conductive layers includes a region not overlapping with the insulating layer. The level of a top surface of the other of the pair of the conductive layers is lower than the level of a top surface of the one of the pair of the conductive layers. Each of the pair of the conductive layers is in contact with the semiconductor layer. The semiconductor layer includes a region overlapping with the gate electrode through the gate insulating layer.

### TECHNICAL FIELD

One embodiment of the present invention relates to a semiconductor device and a fabrication method of the semiconductor device. One embodiment of the present invention relates to a transistor and a fabrication method of the transistor.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a fabrication method thereof. A semiconductor device generally means a device that can function by utilizing semiconductor characteristics.

### BACKGROUND ART

As a semiconductor material that can be used in a transistor, an oxide semiconductor using a metal oxide has been attracting attention. For example, Patent Document 1 discloses a semiconductor device that achieves increased field-effect mobility (simply referred to as mobility or μFE in some cases) by stacking a plurality of oxide semiconductor layers, containing indium and gallium in an oxide semiconductor layer serving as a channel in the plurality of oxide semiconductor layers, and making the proportion of indium higher than the proportion of gallium.

A metal oxide that can be used for a semiconductor layer can be formed by a sputtering method or the like, and thus can be used for a semiconductor layer of a transistor included in a large display device. In addition, capital investment can be reduced because part of production equipment for a transistor using polycrystalline silicon or amorphous silicon can be retrofitted and utilized. A transistor using a metal oxide has field-effect mobility higher than that in the case where amorphous silicon is used; thus, a high-performance display device provided with driver circuits can be obtained.

Patent Document 2 discloses a thin film transistor in which an oxide semiconductor film including a low-resistance region including at least one kind in a group consisting of aluminum, boron, gallium, indium, titanium, silicon, germanium, tin, and lead as a dopant is used for a source region and a drain region.

### REFERENCES

### Patent Documents

[Patent Document 1] Japanese Published Patent Application No. 2014-7399
[Patent Document 2] Japanese Published Patent Application No. 2011-228622

### SUMMARY OF THE INVENTION

### Problems to be Solved by the Invention

An example of a method of improving the performance of a semiconductor device is increasing the on-state current of a transistor included in the semiconductor device. An example of a method of increasing the on-state current of a transistor is downsizing of a transistor, specifically, reducing the channel length of a transistor.

For example, in order to reduce the channel length of each of a BGTC (Bottom Gate Top Contact) transistor, a BGBC (Bottom Gate Bottom Contact) transistor, a TGTC (Top Gate Top Contact) transistor, and a TGBC (Top Gate Bottom Contact) transistor, the distance between a source electrode and a drain electrode needs to be short. However, it is difficult for a photolithography method to form a pattern finer than the exposure limit of a light exposure apparatus; thus, there is a limit of shortening the distance between the source electrode and the drain electrode.

An object of one embodiment of the present invention is to provide a semiconductor device including a transistor with high on-state current and a fabrication method thereof. Another object of one embodiment of the present invention is to provide a semiconductor device having favorable electrical characteristics and a fabrication method thereof. Another object of one embodiment of the present invention is to provide a method of fabricating a semiconductor device with high productivity. Another object of one embodiment of the present invention is to provide a novel semiconductor device and a fabrication method thereof.

Note that the description of these objects does not preclude the existence of other objects. One embodiment of the present invention does not have to achieve all these objects. Objects other than these can be derived from the description of the specification, the drawings, the claims, and the like.

### Means for Solving the Problems

One embodiment of the present invention is a semiconductor device including a substrate, an island-shaped insulating layer over the substrate, and a transistor over the substrate and the insulating layer. The transistor includes a gate electrode, a gate insulating layer, a semiconductor layer, and a pair of conductive layers. One of the pair of the conductive layers includes a region overlapping with the insulating layer, and the other of the pair of the conductive layers includes a region not overlapping with the insulating layer. The level of an end surface of the other of the pair of the conductive layers is lower than the level of an end surface of the one of the pair of the conductive layers. Each of the pair of the conductive layers is in contact with the semiconductor layer. The semiconductor layer includes a region overlapping with the gate electrode through the gate insulating layer.

In the semiconductor device, it is preferable that the conductive layer be in contact with a top surface and a side surface of the insulating layer and each of the pair of the conductive layers be in contact with a top surface of the semiconductor layer.

In the semiconductor device, it is preferable that the conductive layer be in contact with a top surface and a side surface of the insulating layer and each of the pair of the conductive layers be in contact with a bottom surface of the semiconductor layer.

In the semiconductor device, it is preferable that the semiconductor layer be in contact with a top surface and a side surface of the insulating layer and each of the pair of the conductive layers be in contact with a top surface of the semiconductor layer.

In the semiconductor device, it is preferable that the one of the pair of the conductive layers be in contact with a top surface of the insulating layer and the other of the pair of the conductive layers be in contact with a side surface of the insulating layer. Each of the pair of the conductive layers is preferably in contact with a bottom surface of the semiconductor layer.

In the semiconductor device, the taper angle of the insulating layer is preferably greater than or equal to 450 and less than 90°.

In the semiconductor device, the semiconductor layer preferably includes a first layer and a second layer in this order from the gate insulating layer side. The second layer preferably includes a region with a crystallinity higher than a crystallinity of the first layer.

In the semiconductor device, the semiconductor layer preferably includes a first layer, a second layer, and a third layer in this order from the gate insulating layer side. It is preferable that the first layer include a region with a crystallinity higher than a crystallinity of the second layer and the third layer include a region with a crystallinity higher than a crystallinity of the second layer.

One embodiment of the present invention is a method of fabricating a semiconductor device, including a step of forming an island-shaped first insulating layer and an island-shaped second insulating layer over a substrate, a step of forming a gate electrode in contact with a top surface and a side surface of the first insulating layer, a step of forming a gate insulating layer over the gate electrode, a step of forming, over the gate insulating layer, a semiconductor layer comprising a region overlapping with the gate electrode, a step of forming a conductive film over the semiconductor layer, a step of forming a resist over the conductive film, a step of exposing the resist to light with use of a photomask having a light-shielding portion, thereby forming a first unexposed region over the first light-shielding portion that is shield by the light-shielding portion and a second unexposed region between the first insulating layer and the second insulating layer, a step of developing the resist to form a first resist mask and a second resist mask in the first unexposed region and the second unexposed region, respectively, and a step of processing the conductive film using the first resist mask and the second resist mask as a mask to form a pair of conductive layers. The pair of the conductive layers are preferably apart from each other over the semiconductor layer.

### Effect of the Invention

One embodiment of the present invention can provide a semiconductor device including a transistor with high on-state current and a fabrication method thereof. One embodiment of the present invention can provide a method of fabricating a semiconductor device having favorable electrical characteristics and a fabrication method thereof. One embodiment of the present invention can provide a method of fabricating a semiconductor device with high productivity. One embodiment of the present invention can provide a novel semiconductor device and a fabrication method thereof.

Note that the description of these effects does not preclude the existence of other effects. One embodiment of the present invention does not have to have all of these effects. Effects other than these can be derived from the description of the specification, the drawings, the claims, and the like.

### BRIEF DESCRIPTION OF THE DRAWINGS

FIG. 1A and FIG. 1B are cross-sectional views illustrating a structure example of a transistor.

FIG. 2A and FIG. 2B are cross-sectional views illustrating a structure example of a transistor.

FIG. 3A and FIG. 3B are cross-sectional views illustrating a structure example of a transistor.

FIG. 4A and FIG. 4B are cross-sectional views illustrating a structure example of a transistor.

FIG. 5A and FIG. 5B are cross-sectional views illustrating a structure example of a transistor.

FIG. 6A and FIG. 6B are cross-sectional views illustrating a structure example of a transistor.

FIG. 7 is a cross-sectional view illustrating a structure example of a semiconductor device.

FIG. 8 is a cross-sectional view illustrating a structure example of a transistor.

FIG. 9 is a cross-sectional view illustrating a structure example of a semiconductor device.

FIG. 10 is a cross-sectional view illustrating a structure example of a semiconductor device.

FIG. 11A, FIG. 11B, and FIG. 11C are cross-sectional views illustrating a method of fabricating a semiconductor device.

FIG. 12A and FIG. 12B are cross-sectional views illustrating a method of fabricating a semiconductor device.

FIG. 13A and FIG. 13B are cross-sectional views illustrating a method of fabricating a semiconductor device.

FIG. 14 is a cross-sectional view illustrating a method of fabricating a semiconductor device.

FIG. 15 is a cross-sectional view illustrating a method of fabricating a semiconductor device.

FIG. 16 is a cross-sectional view illustrating a method of fabricating a semiconductor device.

FIG. 17 is a cross-sectional view illustrating a method of fabricating a semiconductor device.

FIG. 18 is a cross-sectional view illustrating a method of fabricating a semiconductor device.

FIG. 19A and FIG. 19B are cross-sectional views illustrating a method of fabricating a semiconductor device.

FIG. 20A, FIG. 20B, and FIG. 20C are top views of display devices.

FIG. 21 is a cross-sectional view of a display device.

FIG. 22 is a cross-sectional view of a display device.

FIG. 23 is a cross-sectional view of a display device.

FIG. 24 is a cross-sectional view of a display device.

FIG. 25 is a cross-sectional view of a display device.

FIG. 26A is a block diagram of a display device. FIG. 26B and FIG. 26C are circuit diagrams of the display device.

FIG. 27A, FIG. 27C, and FIG. 27D are circuit diagrams of a display device. FIG. 27B is a timing chart of the display device.

FIG. 28A and FIG. 28B illustrate a structure example of a display module.

FIG. 29A and FIG. 29B illustrate a structure example of an electronic device.

FIG. 30A, FIG. 30B, FIG. 30C, and FIG. 30D illustrate structure examples of electronic devices.

FIG. 31A and FIG. 31B are STEM images of Example.

FIG. 32A and FIG. 32B are STEM images of Example.

FIG. 33A and FIG. 33B are STEM images of Example.

### MODE FOR CARRYING OUT THE INVENTION

Hereinafter, embodiments will be described with reference to the drawings. Note that the embodiments can be implemented in many different modes, and it will be readily understood by those skilled in the art that modes and details thereof can be changed in various ways without departing from the spirit and scope thereof. Thus, the present invention should not be construed as being limited to the following description of the embodiments.

In each drawing described in this specification, the size, the layer thickness, or the region of each component is exaggerated for clarity in some cases.

Ordinal numbers such as “first”, “second”, and “third” used in this specification are used in order to avoid confusion among components, and the terms do not limit the components numerically.

In this specification, terms for describing arrangement, such as “over” and “under,” are used for convenience to describe the positional relationship between components with reference to drawings. The positional relationship between components is changed as appropriate in accordance with a direction in which each component is described. Thus, terms for the description are not limited to those used in this specification, and the description can be rephrased appropriately depending on the situation.

In this specification and the like, functions of a source and a drain of a transistor are sometimes interchanged with each other when a transistor of opposite polarity is employed or the direction of current is changed in circuit operation. Therefore, the terms “source” and “drain” can be used interchangeably.

In this specification and the like, “electrically connected” includes the case where connection is made through an “object having any electric function”. Here, there is no particular limitation on the “object having any electric function” as long as electric signals can be transmitted and received between components that are connected through the object. Examples of the “object having any electric function” include a switching element such as a transistor, a resistor, an inductor, a capacitor, and other elements with a variety of functions as well as an electrode and a wiring.

In this specification and the like, the term “film” and the term “layer” can be interchanged with each other. For example, in some cases, the term “conductive layer” can be interchanged with the term “conductive film”. Similarly, in some cases, the term “insulating layer” can be interchanged with the term “insulating film”.

Unless otherwise specified, off-state current in this specification and the like refers to drain current of a transistor in an off state (also referred to as a non-conducting state or a cutoff state). Unless otherwise specified, an off state refers to a state where the voltage V_{g}s between a gate and a source is lower than the threshold voltage Vth in an n-channel transistor (higher than Vth in a p-channel transistor).

In this specification and the like, a display panel that is one embodiment of a display device has a function of displaying (outputting) an image or the like on (to) a display surface. Thus, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

Note that in this specification and the like, a touch panel that is one embodiment of a display device has a function of displaying an image or the like on a display surface and a function of a touch sensor capable of sensing the contact, press, approach, or the like of a sensing target such as a finger or a stylus with or to the display surface. Thus, the touch panel is one embodiment of an input/output device.

A touch panel can also be referred to as, for example, a display panel (or a display device) with a touch sensor, or a display panel (or a display device) having a touch sensor function. A touch panel can include a display panel and a touch sensor panel. Alternatively, a touch panel can have a function of a touch sensor in the display panel or on the surface of the display panel.

In this specification and the like, a substrate of a touch panel on which a connector or an IC is mounted is referred to as a touch panel module, a display module, or simply a touch panel or the like in some cases.

### Embodiment 1

In this embodiment, a semiconductor device of one embodiment of the present invention, a fabrication method thereof, and the like will be described.

One embodiment of the present invention is a semiconductor device including a substrate, an island-shaped first insulating layer over the substrate, and a transistor over the substrate and the first insulating layer. The transistor includes a gate electrode, a gate insulating layer, a semiconductor layer, and a pair of conductive layers. One of the pair of the conductive layers functions as one of a source electrode and a drain electrode, and the other of the pair of the conductive layers functions as the other of the source electrode and the drain electrode.

The one of the pair of the conductive layers is provided over the first insulating layer, and includes a region overlapping with the first insulating layer. Meanwhile, the other of the pair of the conductive layers includes a region not overlapping with the first insulating layer. The level of an end surface of the other of the pair of the conductive layers is lower than the level of an end surface of the one of the pair of the conductive layers. With such a structure, the distance between the one of the pair of the conductive layers and the other of the pair of the conductive layers can be shorter than the exposure limit of a light exposure apparatus. That is, the distance between the source electrode and the drain electrode can be reduced, so that the transistor can have a high on-state current.

The semiconductor device of one embodiment of the present invention can be formed in the following manner: an island-shaped first insulating layer and an island-shaped second insulating layer are provided over a substrate, and a transistor is provided over the substrate and the first insulating layer.

The pair of the conductive layers included in the transistor can be formed in the following manner: a resist is formed over a conductive film to be the pair of the conductive layers, the resist is exposed to light and developed with a photomask having a light-shielding portion to form a resist mask, and the conductive film is processed with use of the resist mask as a mask.

At this time, the thickness of the resist is thin over the first insulating layer and thick between the first insulating layer and the second insulating layer. In the light exposure, a first unexposed region which is shielded from light by the light-shielding portion of the photomask is formed over the first insulating layer. Furthermore, light exposure is performed such that a part of the resist between the first insulating layer and the second insulating layer is not exposed to light; thus, a second unexposed region is formed between the first insulating layer and the second insulating layer. Moreover, the resist is developed, so that a first resist mask and a second resist mask can be formed in the first unexposed region and the second unexposed region, respectively. The conductive film is processed using the first resist mask and the second resist mask as a mask, whereby the pair of the conductive layers can be formed.

The one of the pair of the conductive layers is formed using the light-shielding portion of the photomask and the other of the pair of the conductive layers is formed without using the light-shielding portion of the photomask, so that the distance between the one of the pair of the conductive layers and the other of the pair of the conductive layers can be shorter than the exposure limit of a light exposure apparatus.

A semiconductor device of one embodiment of the present invention and a fabrication method thereof will be described below.

### Structure Example 1

### Structure Example 1-1

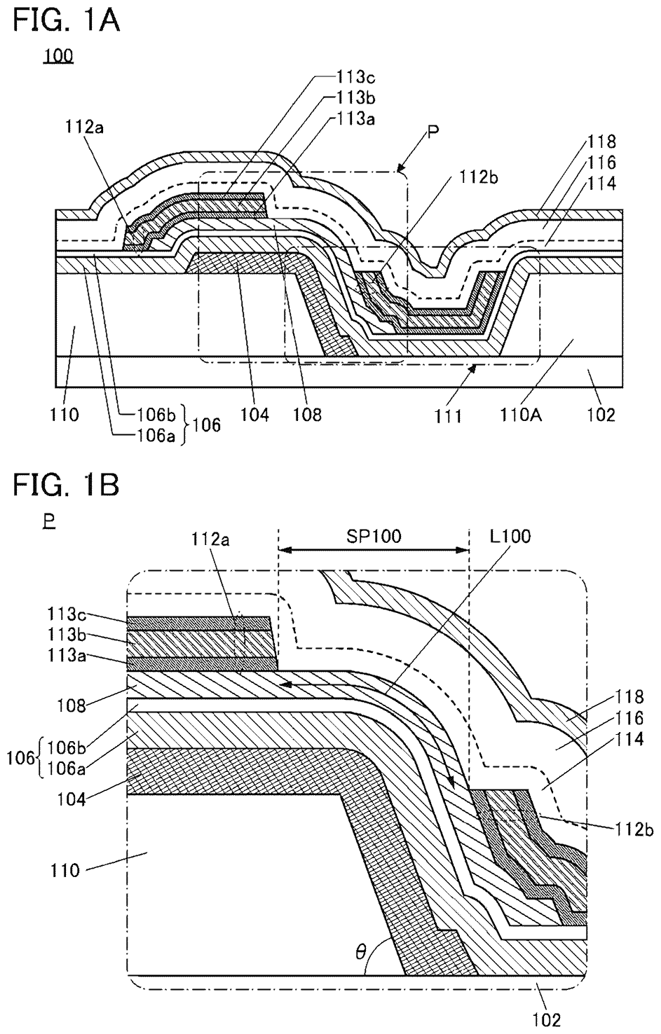

Transistors that can be used in the semiconductor device of one embodiment of the present invention are described. FIG. 1A illustrates a schematic cross-sectional view of a transistor 100 in the channel length direction.

The transistor 100 includes a conductive layer 104, an insulating layer 106, a semiconductor layer 108, a conductive layer 112a, and a conductive layer 112b. The conductive layer 104 functions as a gate electrode. Part of the insulating layer 106 functions as a gate insulating layer. The conductive layer 112a functions as one of a source electrode and a drain electrode, and the conductive layer 112b functions as the other. A region of the semiconductor layer 108 which overlaps with the conductive layer 104 functions as a channel formation region.

The transistor 100 is what is called a bottom-gate transistor including a gate electrode below the semiconductor layer 108. Furthermore, the transistor 100 can be referred to as a BGTC transistor because the transistor 100 includes the source electrode and the drain electrode above the semiconductor layer 108. Here, a side of the semiconductor layer 108 opposite to the conductive layer 104 side is sometimes referred to as a back channel side. The transistor 100 has what is called a channel-etched structure in which no protective layer is provided between the back channel side of the semiconductor layer 108 and the source and drain electrodes.

The transistor 100 is provided over the insulating layer 110. The insulating layer 110 has an island shape and is provided over a substrate 102.

The conductive layer 104 is provided over the insulating layer 110 and in contact with a top surface and a side surface of the insulating layer 110. The conductive layer 104 has a curved shape along the top surface and the side surface of the insulating layer 110. The conductive layer 104 may further be in contact with the substrate 102. One end portion of the conductive layer 104 can be in contact with the insulating layer 110, and the other end portion can be in contact with the substrate 102. The structure in which the conductive layer 104 is in contact with the substrate 102 can reduce a step between the end portion of the conductive layer 104 and the substrate 102. Accordingly, the step coverage with a layer formed over the conductive layer 104 (e.g., the insulating layer 106) is improved, which can prevent defects such as step disconnection or a void from being generated in the layer.

The insulating layer 106 is provided over the insulating layer 110, the conductive layer 104, and the substrate 102, and in contact with the top surface of the insulating layer 110, a top surface and a side surface of the conductive layer 104, and the substrate 102. The insulating layer 106 may be provided over an island-shaped insulating layer 110A adjacent to the insulating layer 110, and may be in contact with a top surface and a side surface of the insulating layer 110A.

The semiconductor layer 108 has an island-like shape and is in contact with a top surface of the insulating layer 106. The semiconductor layer 108 includes a region overlapping with the conductive layer 104 with the insulating layer 106 positioned therebetween.

Each of the conductive layer 112a and the conductive layer 112b is provided over the semiconductor layer 108 and in contact with a top surface of the semiconductor layer 108. Each of the conductive layer 112a and the conductive layer 112b may be in contact with a side surface of the semiconductor layer 108 and the top surface of the insulating layer 106.

The conductive layer 112a includes a region overlapping with the insulating layer 110 and is provided over the insulating layer 110. The conductive layer 112b is provided in a groove 111 between the insulating layer 110 and the island-shaped insulating layer 110A adjacent to the insulating layer 110. The conductive layer 112b includes a region not overlapping with the insulating layer 110. In the cross-sectional view, the conductive layer 112b has a U-shape when being provided in the groove 111. Thus, the level of a side surface of the conductive layer 112b is higher than the level of a top surface of the conductive layer 112b in some cases. The level of the top surface of the conductive layer 112b positioned in the groove 111 is lower than the level of a top surface of the conductive layer 112a positioned over the insulating layer 110. The level of the side surface of the conductive layer 112b is lower than the level of a side surface of the conductive layer 112a. The level of the end surface of the conductive layer 112b is lower than the level of the end surface of the conductive layer 112a.

Note that in this specification and the like, an end surface of a layer includes a top surface and side surfaces in the case where a surface in contact with a surface where the layer is to be formed is regarded as a bottom surface.

Note that in this specification and the like, in the case where the levels of top surfaces of layers are compared, the height from the substrate to the highest portion of the top surface of the layer is used. Similarly, in the case where the levels of side surfaces of layers are compared, the height from the substrate to the highest portion of the side surface of the layer is used. Similarly, in the case where the levels of end surfaces (top surfaces and side surfaces) of layers are compared, the height from the substrate to the highest portion of the end surface (the top surface and the side surface) of the layer is used.

FIG. 1A illustrates an example in which one end portion of the conductive layer 112b and the other end portion of the conductive layer 112b are level with or substantially level with each other; however, one embodiment of the present invention is not limited to this. The level of the one end portion of the conductive layer 112b may be different from the level of the other end portion.

The conductive layer 112a and the conductive layer 112b are preferably formed with the same material. The use of the same material can make the conductive layer 112a and the conductive layer 112b have the same or substantially the same resistivity. Furthermore, the conductive layer 112a and the conductive layer 112b are preferably formed in the same step. By the formation of the conductive layer 112a and the conductive layer 112b in the same step, the manufacturing cost can be reduced and the production yield can be increased.

End portions of the insulating layer 110 are preferably tapered. The taper angle θ of the end portion of the insulating layer 110 is preferably less than 90°. The taper angle θ of the end portion of the insulating layer 110 is preferably greater than or equal to 450 and less than 90°, further preferably greater than or equal to 50° and less than or equal to 85°, further preferably greater than or equal to 55° and less than or equal to 85°, further preferably greater than or equal to 60° and less than or equal to 85°, further preferably greater than or equal to 60° and less than or equal to 80°, further preferably greater than or equal to 65° and less than or equal to 80°, further preferably greater than or equal to 70° and less than or equal to 80°. By setting the taper angle θ of the insulating layer 110 in the above range, the step coverage with a layer formed over the insulating layer 110 (e.g., the conductive layer 104) can be improved and defects such as step disconnection or a void can be prevented from being generated in the layer. In addition, the distance between the conductive layer 112a and the conductive layer 112b can be shorter than the exposure limit of a light exposure apparatus.

Similarly, the end portions of the insulating layer 110A are preferably tapered. The description of the insulating layer 110 can be referred to for the taper angle of the insulating layer 110A; thus, the detailed description thereof is omitted. Note that the taper angle θ of the insulating layer 110 and the taper angle of the insulating layer 110A may be the same or different.

Note that in this specification and the like, a taper angle refers to an angle formed between an end surface of a layer and a formation surface where the layer is formed.

FIG. 1A illustrates an example in which the insulating layer 110 and the insulating layer 110A have the same thickness. The insulating layer 110 and the insulating layer 110A can be formed in the same step. Note that the insulating layer 110 and the insulating layer 110A may be formed in different steps. The insulating layer 110 and the insulating layer 110A may have different thicknesses.

Although FIG. 1A illustrates an example in which the insulating layer 110 and the insulating layer 110A are provided in contact with the substrate 102, one embodiment of the present invention is not limited to this. Another insulating layer may be provided over the substrate 102, and the insulating layer 110 and the insulating layer 110A may be provided over the insulating layer. In that case, the insulating layer may be included between the conductive layer 104 and the substrate 102 and between the insulating layer 106 and the substrate 102.

Another insulating layer may be provided over the substrate 102, the insulating layer 110, and the insulating layer 110A, and the conductive layer 104 may be provided over the insulating layer. In that case, the insulating layer may be included between the insulating layer 106 and the substrate 102, between the insulating layer 106 and the insulating layer 110, and between the insulating layer 106 and the insulating layer 110A.

FIG. 1B is an enlarged view of a region P surrounded by a dashed-dotted line in FIG. 1A. In FIG. 1B, a distance SP100 between the conductive layer 112a and the conductive layer 112b and a channel length L100 of the transistor 100 are indicated by arrows. The channel length L100 can be the length of the semiconductor layer 108 between the conductive layer 112a and the conductive layer 112b. The channel length L100 can be the length of the semiconductor layer 108 in a region between the conductive layer 112a and the conductive layer 112b and in contact with neither the conductive layer 112a nor the conductive layer 112b.

The semiconductor layer 108 includes a curved region between the conductive layer 112a and the conductive layer 112b. In other words, the transistor 100 includes a curved channel formation region. The distance SP100 and the channel length L100 are different values, and the channel length L100 is a larger value than the distance SP100.

The value of the channel length L100 can be smaller than the exposure limit of a light exposure apparatus. For example, the channel length L100 is preferably greater than or equal to 0.2 m and less than 1.5 m, further preferably greater than or equal to 0.3 m and less than or equal to 1.3 m, further preferably less than or equal to 0.4 m and 1.2 m, further preferably less than or equal to 0.5 m and 1.1 m, further preferably less than or equal to 0.6 m and 1.0 m. The transistor 100 can have the channel length L100 which is shorter than the exposure limit of a light exposure apparatus by providing the conductive layer 112a over the insulating layer 110 and providing the conductive layer 112b in the groove 111. For example, when the exposure limit of a light exposure apparatus is 1.5 m, the channel length L100 can be less than 1.5 m.

The reduction in the channel length L100 can increase the on-state current of the transistor 100. With the use of the transistor 100, a circuit capable of high-speed operation can be fabricated. Furthermore, the area occupied by a circuit portion can be reduced. For example, the use of the transistor 100 for a display device can reduce signal delay in each wiring and can suppress display unevenness even in the display device in which the number of wirings is increased because of an increase in size or an increase in resolution. In addition, the area occupied by a circuit portion can be reduced, whereby the bezel of the display device can be narrowed.

An insulating layer 114, an insulating layer 116, and an insulating layer 118 are provided to cover the conductive layer 112a, the conductive layer 112b, and the semiconductor layer 108. The insulating layer 114, the insulating layer 116, and the insulating layer 118 each function as a protective layer of the transistor 100.

The conductive layer 104 is preferably formed using a conductive film containing a metal or an alloy, in which case the electric resistance can be reduced. The use of a conductive material containing copper for the conductive layer 104 is particularly preferable. Note that an oxide film may be used as the conductive layer 104.

It is preferable to use an oxide film as the insulating layer 106. It is particularly preferable to use an oxide film for a portion in contact with the semiconductor layer 108.

The insulating layer 106 preferably has high withstand voltage. The high withstand voltage of the insulating layer 106 results in a transistor with high reliability.

The absolute value of the stress of the insulating layer 106 is preferably small. The small absolute value of the stress of the insulating layer 106 can inhibit occurrence of problems during the process caused by stress such as warpage of the substrate.

The insulating layer 106 preferably functions as a barrier film that inhibits diffusion of impurities such as water, hydrogen, and sodium into the transistor 100 from the substrate 102 side. In addition, the insulating layer 106 preferably functions as a barrier film that inhibits diffusion of a component of the conductive layer 104 into the transistor 100. The insulating layer 106 functions as a barrier film that inhibits diffusion of impurities and the like; thus, the transistor can have favorable electrical characteristics and high reliability.

Moreover, the amount of impurities such as water and hydrogen released from the insulating layer 106 itself is preferably small. With the insulating layer 106 from which a small amount of impurities is released, diffusion of impurities to the transistor 100 side is inhibited, and the transistor can have favorable electrical characteristics and high reliability.

Furthermore, the insulating layer 106 preferably functions as a barrier film that inhibits diffusion of oxygen. The insulating layer 106 having a function of inhibiting diffusion of oxygen inhibits diffusion of oxygen into the conductive layer 104 from above the insulating layer 106 and thus can inhibit oxidation of the conductive layer 104. Consequently, the transistor can have favorable electrical characteristics and high reliability.

The insulating layer 106 may have a stacked-layer structure. FIG. 1A illustrates a structure in which the insulating layer 106 has a two-layer structure of an insulating layer 106a and an insulating layer 106b over the insulating layer 106a. For example, a nitride film can be used as the insulating layer 106a positioned on the substrate 102 side, and an oxide film can be used as the insulating layer 106b in contact with the semiconductor layer 108.

The insulating layer 106a preferably has high withstand voltage. The high withstand voltage of the insulating layer 106 results in a transistor with high reliability.

The absolute value of the stress of the insulating layer 106a is preferably small. The small absolute value of the stress of the insulating layer 106 can inhibit occurrence of problems during the process caused by stress such as warpage of the substrate.

The insulating layer 106a preferably functions as a barrier film that inhibits diffusion of impurities such as water, hydrogen, and sodium into the transistor 100 from the substrate 102 side. In addition, the insulating layer 106a preferably functions as a barrier film that inhibits diffusion of a component of the conductive layer 104 into the transistor 100. The insulating layer 106a has a function of inhibiting diffusion of impurities and the like; thus, the transistor can have favorable electrical characteristics and high reliability.

Moreover, the amount of impurities such as water and hydrogen released from the insulating layer 106a itself is preferably small. With the insulating layer 106a from which a small amount of impurities is released, diffusion of impurities to the transistor 100 side is inhibited, and the transistor can have favorable electrical characteristics and high reliability.

Furthermore, the insulating layer 106a preferably functions as a barrier film that inhibits diffusion of oxygen. The insulating layer 106a having a function of inhibiting diffusion of oxygen inhibits diffusion of oxygen into the conductive layer 104 from above the insulating layer 106a and thus can inhibit oxidation of the conductive layer 104. Consequently, the transistor can have favorable electrical characteristics and high reliability.

As the insulating layer 106a, for example, an oxide film of aluminum oxide, aluminum oxynitride, hafnium oxide, hafnium oxynitride, gallium oxide, gallium oxynitride, yttrium oxide, yttrium oxynitride, or the like or a nitride film of silicon nitride, silicon nitride oxide, aluminum nitride, aluminum nitride oxide, or the like can be used. It is particularly suitable to use silicon nitride for the insulating layer 106a.

The insulating layer 106b includes a region in contact with the channel formation region of the semiconductor layer 108. The insulating layer 106b preferably has a low defect density. Moreover, the amount of impurities including hydrogen, such as water and hydrogen, released from the insulating layer 106b itself is preferably small. An oxide film of silicon oxide, silicon oxynitride, or the like can be suitably used as the insulating layer 106b.

The insulating layer 106 having the stacked-layer structure as illustrated in FIG. 1A allows the transistor to have favorable electrical characteristics and high reliability.

A nitride film may be formed as the insulating layer 106a, and then oxygen may be added to an upper portion of the insulating layer 106a to form an oxygen-containing region; the oxygen-containing region may be regarded as the insulating layer 106b. Examples of treatment for adding oxygen include heat treatment or plasma treatment in an oxygen-containing atmosphere, and ion doping treatment.

Note that in this specification and the like, oxynitride refers to a substance that contains more oxygen than nitrogen in its composition, and oxynitride is included in oxide. Nitride oxide refers to a substance that contains more nitrogen than oxygen in its composition, and nitride oxide is included in nitride.

Although the insulating layer 106 has a two-layer structure of the insulating layer 106a and the insulating layer 106b in FIG. 1A, one embodiment of the present invention is not limited thereto. The insulating layer 106 may have a single-layer structure or a stacked-layer structure of three or more layers. Each of the insulating layer 106a and the insulating layer 106b may have a stacked-layer structure of two or more layers.

The semiconductor layer 108 contains a metal oxide exhibiting semiconductor characteristics (hereinafter, also referred to as an oxide semiconductor). Oxide semiconductors can be classified into a single crystal oxide semiconductor and a non-single-crystal oxide semiconductor. Examples of a non-single-crystal oxide semiconductor include a CAAC-OS, a polycrystalline oxide semiconductor, an nc-OS, an amorphous-like oxide semiconductor (a-like OS), and an amorphous oxide semiconductor.

It is preferable to use a metal oxide film having crystallinity as the semiconductor layer 108. The semiconductor layer 108 preferably contains at least indium and oxygen. When the semiconductor layer 108 contains an oxide of indium, the carrier mobility can be increased; accordingly, for example, a transistor enabling higher current flow than a transistor containing amorphous silicon can be obtained.

Here, the composition of the semiconductor layer 108 is described. The semiconductor layer 108 preferably contains a metal oxide containing at least indium and oxygen. Moreover, the semiconductor layer 108 may contain zinc additionally. The semiconductor layer 108 may contain gallium.

Typically, an indium oxide, an indium zinc oxide (In—Zn oxide), an indium gallium zinc oxide (also denoted as In—Ga—Zn oxide or IGZO), or the like can be used for the semiconductor layer 108. Alternatively, an indium tin oxide (In—Sn oxide), an indium tin oxide containing silicon, or the like can be used. The material that can be used for the semiconductor layer 108 is described in detail later.

For example, the semiconductor layer 108 preferably contains indium, an element M (the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc. In particular, the element M is preferably one or more kinds selected from aluminum, gallium, yttrium, and tin.

Specifically, an oxide containing indium, gallium, and zinc is preferably used for the semiconductor layer 108. In the semiconductor layer 108, the proportion of In atoms is preferably higher than or equal to the proportion of Ga atoms. For example, the atomic ratio of metal elements in the semiconductor layer 108 can be any of the following: In:Ga:Zn=1:1:1, In:Ga:Zn=1:1:1.2, In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=5:2:5, In:Ga:Zn=10:1:3, In:Ga:Zn=10:1:6, In:Ga:Zn=10:1:8, and a neighborhood thereof.

When the proportion of In atoms is higher than the proportion of Ga atoms in the semiconductor layer 108, the carrier mobility of the semiconductor layer 108 is high, which enables the transistor 100 to have high on-state current. For example, as the atomic ratio of metal elements in the semiconductor layer 108, any of the following can be suitably employed: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=5:2:5, In:Ga:Zn=10:1:3, In:Ga:Zn=10:1:6, In:Ga:Zn=10:1:8, and a neighborhood thereof.

The semiconductor layer 108a and the semiconductor layer 108b may have the same composition or substantially the same compositions. When the semiconductor layer 108a and the semiconductor layer 108b have the same composition or substantially the same compositions, the semiconductor layer 108a and the semiconductor layer 108b can be formed using the same sputtering target, reducing the manufacturing cost.

It is preferable to use a metal oxide film having crystallinity as the semiconductor layer 108. For example, a metal oxide film having a CAAC (c-axis aligned crystal) structure, which is described later, a polycrystalline structure, a nano-crystal (nc) structure, or the like can be used. By using a metal oxide film having crystallinity as the semiconductor layer 108, the density of defect states in the semiconductor layer 108 can be reduced, which enables the semiconductor device to have high reliability.

As the semiconductor layer 108 has higher crystallinity, the density of defect states in the film can be lower. By contrast, the use of a metal oxide film with low crystallinity enables a transistor to flow a large amount of current.

In the case where the metal oxide film is formed by a sputtering method, the crystallinity of the formed metal oxide film can be increased as the substrate temperature (the stage temperature) at the time of formation is higher. The crystallinity of the formed metal oxide film can be increased as the proportion of a flow rate of an oxygen gas in the whole deposition gas (also referred to as oxygen flow rate ratio) used at the time of formation is higher.

The thickness of the semiconductor layer 108 is preferably greater than or equal to 10 nm and less than or equal to 100 nm, further preferably greater than or equal to 15 nm and less than or equal to 70 nm, still further preferably greater than or equal to 20 nm and less than or equal to 50 nm, yet still further preferably greater than or equal to 25 nm and less than or equal to 40 nm.

The substrate temperature at the time of forming the semiconductor layer 108 is preferably higher than or equal to room temperature (25° C.) and lower than or equal to 200° C., further preferably higher than or equal to room temperature and lower than or equal to 130° C. With the substrate temperature in the above range, the bending or warpage of the substrate can be inhibited in the case where a large-area glass substrate is used.

Here, oxygen vacancies that might be formed in the semiconductor layer 108 will be described.

In the case where the semiconductor layer 108 includes an oxide semiconductor, hydrogen contained in the oxide semiconductor reacts with oxygen bonded to a metal atom to be water, and thus sometimes forms an oxygen vacancy (V_{O}) in the oxide semiconductor. In some cases, a defect where hydrogen enters an oxygen vacancy (hereinafter, referred to as V_{O}H) functions as a donor and generates an electron serving as a carrier. In other cases, bonding of part of hydrogen to oxygen bonded to a metal atom generates electrons serving as carriers. Thus, a transistor using an oxide semiconductor that contains a large amount of hydrogen is likely to be normally on. Moreover, hydrogen in an oxide semiconductor is easily transferred by a stress such as heat or an electric field; thus, a large amount of hydrogen in an oxide semiconductor might reduce the reliability of a transistor.

V_{O}H can serve as a donor of the oxide semiconductor. However, it is difficult to evaluate the defects quantitatively. Thus, the oxide semiconductor is sometimes evaluated by not its donor concentration but its carrier concentration. Therefore, in this specification and the like, the carrier concentration assuming the state where an electric field is not applied is sometimes used, instead of the donor concentration, as the parameter of the oxide semiconductor. That is, “carrier concentration” in this specification and the like can be replaced with “donor concentration” in some cases.

Accordingly, in the case where an oxide semiconductor is used as the semiconductor layer 108, the amount of V_{O}H in the semiconductor layer 108 is preferably reduced as much as possible so that the semiconductor layer 108 becomes a highly purified intrinsic or substantially highly purified intrinsic semiconductor layer. In order to obtain such an oxide semiconductor with sufficiently reduced V_{O}H, it is important to remove impurities such as water and hydrogen in the oxide semiconductor (this treatment is sometimes referred to as dehydration or dehydrogenation treatment) and supply oxygen to the oxide semiconductor to fill oxygen vacancies (this treatment is sometimes referred to as oxygen adding treatment). When an oxide semiconductor with sufficiently reduced impurities such as V_{O}H is used for a channel formation region of a transistor, stable electrical characteristics can be given.

When an oxide semiconductor is used for the semiconductor layer 108, the carrier concentration of the oxide semiconductor in a region functioning as a channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

The insulating layer 114 and the insulating layer 116 have a function of protective films for the transistor 100. Furthermore, the insulating layer 114 and the insulating layer 116 each have a function of supplying oxygen to the semiconductor layer 108.

Supplying oxygen from the insulating layer 114 and the insulating layer 116 to the semiconductor layer 108, particularly to the back channel side of the semiconductor layer 108, can reduce V_{O} and V_{O}H in the semiconductor layer 108, so that a highly reliable transistor can be obtained. Examples of treatment for supplying oxygen to the semiconductor layer 108 include heat treatment in an oxygen-containing atmosphere and plasma treatment in an oxygen-containing atmosphere.

The conductive layer 112a and the conductive layer 112b are preferably formed using a conductive film containing a metal or an alloy, in which case the electric resistance can be reduced. The use of a conductive material containing copper for the conductive layer 112a and the conductive layer 112b is particularly preferable. Note that an oxide film may be used as the conductive layer 112a and the conductive layer 112b.

The amount of nitrogen oxide (NOₓ; x is greater than 0 and less than or equal to 2) released from the insulating layer 114 in contact with the semiconductor layer 108 is preferably small. Examples of nitrogen oxide include NO₂ and NO. The amount of ammonia released from the insulating layer 114 is preferably large.

Nitrogen oxide forms a state in the insulating layer 114 and the like. The state is positioned in the energy gap of the semiconductor layer 108. Thus, when nitrogen oxide is diffused to the interface between the insulating layer 114 and the semiconductor layer 108, an electron may be trapped by the state on the insulating layer 114 side. As a result, the trapped electron remains in the vicinity of the interface between the insulating layer 114 and the semiconductor layer 108; hence, the threshold voltage of the transistor is shifted in the positive direction.

Nitrogen oxide reacts with ammonia and oxygen by application of heat. Since nitrogen oxide included in the insulating layer 114 reacts with ammonia included in the insulating layer 114 and the insulating layer 116 by application of heat, the amount of nitrogen oxide included in the insulating layer 114 is reduced. Thus, electrons are hardly trapped at the interface between the insulating layer 114 and the semiconductor layer 108.

When a film from which a large amount of ammonia is released and a small amount of nitrogen oxide is released is used as the insulating layer 114, a change in the threshold voltage of the transistor can be inhibited, which can reduce a change in the electrical characteristics of the transistor.

As the insulating layer 114, for example, an oxide film such as a silicon oxide film or a silicon oxynitride film is preferably formed with a plasma-enhanced chemical vapor deposition apparatus (a PECVD apparatus or simply referred to as a plasma CVD apparatus). In that case, a mixed gas including a deposition gas containing silicon, an oxidizing gas, and an ammonia gas is preferably used as a source gas. The insulating layer 114 formed using the mixed gas including the ammonia gas can be the insulating layer 114 from which a large amount of ammonia is released. As the deposition gas containing silicon, for example, one or more of silane, disilane, trisilane, and silane fluoride can be used. As the oxidizing gas, a gas containing oxygen can be suitably used. As the oxidizing gas, for example, one or more of oxygen (O₂), ozone (O₃), dinitrogen monoxide (N₂O), nitrogen monoxide (NO), and nitrogen dioxide (NO₂) can be used.

In the formation of the insulating layer 114, the flow rate of the oxidizing gas is preferably more than 20 times and 200 times or less, further preferably 30 times or more and 150 times or less, still further preferably 40 times or more and 100 times or less, yet still further preferably 40 times or more and 80 times or less as high as the flow rate of the deposition gas. In the formation of the insulating layer 114, the flow rate of the ammonia gas is preferably lower than or equal to the flow rate of the oxidizing gas. The flow rate of the ammonia gas is preferably 0.01 times or more and 1 time or less, further preferably 0.02 times or more and 0.9 times or less, still further preferably 0.03 times or more and 0.8 times or less, yet further preferably 0.04 times or more and 0.6 times or less, yet still further preferably 0.05 times or more and 0.5 times or less as high as the flow rate of the oxidizing gas. With the above-described flow rates of the gases, the insulating layer 114 from which a large amount of ammonia is released can be obtained. Since the amount of nitrogen oxide released from the insulating layer 114 is reduced, a transistor with a small change in the threshold voltage can be obtained. In addition, with the above-described flow rates of the gases, the insulating layer 114 with few defects can be formed even when the pressure in the treatment chamber is relatively high. Note that the preferred flow rate of the ammonia gas with respect to the flow rate of the oxidizing gas may vary depending on the conditions such as pressure and power at the time of forming the insulating layer 114.

The pressure in the treatment chamber at the time of forming the insulating layer 114 is preferably 200 Pa or lower, further preferably 150 Pa or lower, still further preferably 120 Pa or lower, yet still further preferably 100 Pa or lower. With the pressure in the above range, the insulating layer 114 from which a small amount of nitrogen oxide is released and in which the amount of defects is small can be formed.

Note that an insulating layer from which a large amount of ammonia is released and a small amount of nitrogen oxide is released is a film which releases ammonia more than nitrogen oxide in thermal desorption spectroscopy (TDS) analysis; the released amount of ammonia is typically greater than or equal to 1×10¹⁸/cm³ and less than or equal to 5×10¹⁹/cm³. Note that the released amount of ammonia is the released amount in the range of the surface temperature of a film from 50° C. to 650° C., preferably from 50° C. to 550° C.

The insulating layer 114 preferably has a low defect density. When the defect density of the insulating layer 114 is high, oxygen is bonded to the defects and the oxygen permeability of the insulating layer 114 decreases. With the use of the insulating layer 114 having a low defect density, the transistor with a small change in the threshold voltage and excellent electrical characteristics can be obtained. In the case where an insulating film containing silicon is used as the insulating layer 114, for example, the spin density of a signal that appears at g=2.001 due to a dangling bond of silicon is preferably lower than or equal to 3×10¹⁷ spins/cm³ in ESR measurement.

The insulating layer 114 is formed over the semiconductor layer 108, and thus is preferably a film formed under conditions where damage to the semiconductor layer 108 is small. For example, the insulating layer 114 can be formed at a sufficiently low deposition rate. For example, when the insulating layer 114 is formed by a plasma CVD method under a low-power condition, damage to the semiconductor layer 108 can be extremely small.

The insulating layer 116 is preferably formed using an oxide film and further preferably includes a region containing oxygen in excess of that in the stoichiometric composition. In other words, the insulating layer 116 includes an insulating film capable of releasing oxygen. It is also possible to supply oxygen into the insulating layer 116 by forming the insulating layer 116 in an oxygen atmosphere, performing heat treatment or the second plasma treatment on the formed insulating layer 116 in an oxygen atmosphere, or forming an oxide film over the insulating layer 116 in an oxygen atmosphere, for example. Note that the insulating layer 116 includes a region where the released amount of oxygen molecules in TDS is greater than or equal to 1.0×10¹⁹ molecules/cm³, preferably greater than or equal to 3.0×10²⁰ molecules/cm³. The released amount of oxygen is the total amount in the range of the heat treatment temperature in TDS from 50° C. to 650° C. or from 50° C. to 550° C.

The defect density of the insulating layer 116 is preferably low, and typically, the spin density of a signal that appears at g=2.001 due to a dangling bond of silicon is preferably lower than 1.5×10¹⁸ spins/cm³, further preferably lower than or equal to 1×10¹⁸ spins/cm³ by ESR measurement. Note that the insulating layer 116 is more apart from the semiconductor layer 108 than the insulating layer 114 is, and thus may have higher defect density than the insulating layer 114.

As the insulating layer 114 and the insulating layer 116, an insulating layer including one or more kinds of a silicon oxide film, a silicon oxynitride film, a silicon nitride oxide film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film can be used, for example.

Insulating films formed of the same kind of material can be used as the insulating layer 114 and the insulating layer 116; thus, an interface between the insulating layer 114 and the insulating layer 116 cannot be clearly observed in some cases. Then, in this embodiment, the boundary (interface) between the insulating layer 114 and the insulating layer 116 cannot be clearly observed in some cases. Then, in the drawings illustrating one embodiment of the present invention, the boundary is denoted by a dashed line. Although the two-layer structure of the insulating layer 114 and the insulating layer 116 is described in this embodiment, one embodiment of the present invention is not limited thereto. For example, a single-layer structure of the insulating layer 114 or a stacked-layer structure of three or more layers may be employed.

After the insulating layer 114 is formed, the insulating layer 116 is preferably formed successively without exposure of the surface of the insulating layer 114 to the air. The insulating layer 116 is formed successively after the formation of the insulating layer 114, so that attachment of impurities to the interface between the insulating layer 114 and the insulating layer 116 can be inhibited.

The insulating layer 118 has a function of a protective film of the transistor 100. The insulating layer 118 inhibits diffusion of impurities such as water and hydrogen into the transistor 100 from the outside of the transistor 100. That is, the reliability and moisture resistance of the transistor 100 can be improved, so that a semiconductor device can have increased reliability.

The insulating layer 118 preferably functions as a barrier film that inhibits diffusion of impurities such as water and hydrogen into the transistor 100 from the outside of the transistor 100. The amount of impurities including hydrogen, such as water and hydrogen, released from the insulating layer 118 itself is preferably small. In addition, the insulating layer 118 preferably functions as a barrier film that inhibits diffusion of oxygen. As the insulating layer 118, for example, an oxide film of aluminum oxide, aluminum oxynitride, hafnium oxide, hafnium oxynitride, gallium oxide, gallium oxynitride, yttrium oxide, yttrium oxynitride, or the like or a nitride film of silicon nitride, silicon nitride oxide, aluminum nitride, aluminum nitride oxide, or the like can be used. It is particularly suitable to use silicon nitride for the insulating layer 118.

Here, when heat is applied in the state where the insulating layer 116 is exposed, oxygen contained in the insulating layer 114 and the insulating layer 116 might be released to the outside. Release of oxygen contained in the insulating layer 114 and the insulating layer 116 to the outside reduces the amount of oxygen contained in the insulating layer 114 and the insulating layer 116, which may reduce the amount of oxygen to be supplied to the semiconductor layer 108. Thus, a temperature at which the formation of at least the insulating layer 118 is started is preferably a temperature at which oxygen contained in the insulating layer 114 and the insulating layer 116 is not released to the outside. When the insulating layer 118 has a function of inhibiting diffusion of oxygen and the insulating layer 118 is formed at a temperature at which oxygen contained in the insulating layer 114 and the insulating layer 116 is not released to the outside, oxygen can be supplied to the semiconductor layer 108 and oxygen vacancies in the semiconductor layer 108 can be filled efficiently.

The insulating layer 118 having a function of inhibiting diffusion of impurities such as water and hydrogen and a function of inhibiting diffusion of oxygen is preferably a dense film. For example, a dense film can be obtained when a substrate temperature at the time of forming the insulating layer 118 is increased.

The substrate temperature at the time of forming the insulating layer 118 is preferably higher than or equal to 180° C. and lower than or equal to 400° C., further preferably higher than or equal to 200° C. and lower than or equal to 380° C., still further preferably higher than or equal to 220° C. and lower than or equal to 360° C., yet still further preferably higher than or equal to 240° C. and lower than or equal to 350° C. With the substrate temperature in the above range, release of oxygen contained in the insulating layer 114 and the insulating layer 116 to the outside can be inhibited and the insulating layer 118 can be a dense film.

With such a structure, a transistor that has favorable electrical characteristics and extremely high reliability can be obtained.

FIG. 1A illustrates an example in which the conductive layer 112a and the conductive layer 112b each have a stacked-layer structure in which a conductive layer 113a, a conductive layer 113b, and a conductive layer 113c are stacked in this order from the formation surface side.

A low-resistance conductive material is preferably used for the conductive layer 113b. The conductive layer 113a and the conductive layer 113c can be each independently formed using a conductive material different from that of the conductive layer 113b. When the conductive layer 113b is sandwiched between the conductive layer 113a and the conductive layer 113c, it is possible to inhibit oxidation of a surface of the conductive layer 113b and diffusion of the components of the conductive layer 113b into neighboring layers. With such a structure, the conductive layer 112a and the conductive layer 112b can have extremely low resistance.

In each of the conductive layer 112a and the conductive layer 112b, the topmost conductive layer 113c preferably contains a material that is less likely to be bonded to oxygen than a conductive film containing copper, aluminum, or the like, or a material that is less likely to be deprived of its conductivity even when being oxidized. In addition, a material into which oxygen in the semiconductor layer 108 is less likely to diffuse is preferably used for the conductive layer 113a that is in contact with the semiconductor layer 108. For the topmost conductive layer 113c and the conductive layer 113a that is in contact with the semiconductor layer, a conductive material containing one or more of titanium, tungsten, molybdenum, chromium, tantalum, zinc, indium, platinum, and ruthenium can be used, for example. The conductive layer 113a and the conductive layer 113c can be formed using the same conductive material. Alternatively, the conductive layer 113a and the conductive layer 113c may be formed using different conductive materials.

The conductive layer 113b preferably contains one or more of copper, silver, gold, and aluminum. Specifically, the conductive layer 113b preferably contains one or more of copper and aluminum. For the conductive layer 113b, a conductive material having lower resistance than the conductive layer 113a and the conductive layer 113c is preferably used. In that case, the conductive layer 112a and the conductive layer 112b can have extremely low resistance.

When the conductive layer 113b containing copper or aluminum is sandwiched between the conductive layer 113a and the conductive layer 113c, it is possible to inhibit oxidation of a surface of the conductive layer 113b and diffusion of an element contained in the conductive layer 113b into neighboring layers. Specifically, provision of the conductive layer 113a between the semiconductor layer 108 and the conductive layer 113b can prevent diffusion of a metal element contained in the conductive layer 113a into the semiconductor layer 108, thereby enabling the transistor 100 to have high reliability.

Here, the insulating layer 114 is provided in contact with an end portion of the conductive layer 113b. According to one embodiment of the present invention, even when a conductive material that is easily oxidized is used for the conductive layer 113b and the insulating layer 114 that includes an oxide film is formed over the conductive layer 113b, a surface of the conductive layer 113b can be inhibited from being oxidized by performing plasma treatment in an atmosphere containing an oxidizing gas and a reducing gas (hereinafter also referred to as first plasma treatment) before formation of the insulating layer 114. Thus, a layer that contains an oxide or the like is not observed at the interface between the conductive layer 113b and the insulating layer 114, which is one of the features of the semiconductor device of one embodiment of the present invention.

Note that the structure of the conductive layer 112a and the conductive layer 112b is not limited to a three-layer structure and may be a two-layer structure or a four-layer structure including a conductive layer containing copper, silver, gold, or aluminum. For example, the conductive layer 112a and the conductive layer 112b may each have a two-layer structure in which the conductive layer 113a and the conductive layer 113b are stacked or a two-layer structure in which the conductive layer 113b and the conductive layer 113c are stacked.

The surface of the semiconductor layer 108 might be damaged at the time of forming the conductive layer 112a and the conductive layer 112b. The damaged layer may be removed because V_{O} is formed in the damaged semiconductor layer 108 and hydrogen in the semiconductor layer 108 enters V_{O} to form V_{O}H in some cases. Removing the damaged layer allows the transistor to have favorable electrical characteristics and high reliability. In that case, the thickness of a region of the semiconductor layer 108 that overlaps with neither the conductive layer 112a nor the conductive layer 112b is smaller than the thickness of a region that overlaps with either the conductive layer 112a or the conductive layer 112b.

Although FIG. 1A and FIG. 1B illustrate an example in which the end portions of the conductive layer 113a, the conductive layer 113b, and the conductive layer 113c are aligned with one another or substantially aligned with one another, one embodiment of the present invention is not limited thereto. It is not necessary that any of the end portions of the conductive layer 113a, the conductive layer 113b, and the conductive layer 113c is aligned with the others or substantially aligned with the others.

The end portions of the conductive layer 113b and the conductive layer 113c may be located inward from the end portion of the conductive layer 113a. With such a structure, the step coverage with the layers (e.g., the insulating layer 114) formed over the conductive layer 113a, the conductive layer 113b, the conductive layer 113c, and the semiconductor layer 108 is improved, which can inhibit generation of defects such as disconnection and voids in the layers.

It is not necessary that the end portions of the conductive layer 113b and the conductive layer 113c are aligned with or substantially aligned with each other. Note that in the case where the end portion of the conductive layer 113b is located inward from the end portion of the conductive layer 113c, the step coverage with the layers (e.g., the insulating layer 118) formed over the conductive layer 112a, the conductive layer 112b, and the semiconductor layer 108 might be poor, which might generate defects such as disconnection and voids in the layers. Thus, the end portion of the conductive layer 113c is preferably located inward from the end portion of the conductive layer 113b.

For the conductive layer 104, any of the above conductive materials that can be used for the conductive layer 113a and the conductive layer 113b can be used as appropriate. The use of a conductive material containing copper is particularly preferable.

For the insulating layer 106 and the insulating layer 114 that are in contact with the semiconductor layer 108, an insulating material containing an oxide is preferably used. In the case where the insulating layer 106 or the insulating layer 114 has a stacked-layer structure, an insulating material containing an oxide is used for a layer in contact with the semiconductor layer 108.

For the insulating layer 106, a nitride film of silicon nitride, aluminum nitride, or the like may be used. In the case where an insulating material containing no oxide is used, treatment for adding oxygen to an upper portion of the insulating layer 106 is preferably performed to form an oxygen-containing region. Examples of the treatment for adding oxygen include heat treatment or plasma treatment in an oxygen-containing atmosphere, and ion doping treatment.

The insulating layer 116 functions as a protective layer protecting the transistor 100. For the insulating layer 116, an inorganic insulating material such as silicon nitride, silicon nitride oxide, silicon oxide, silicon oxynitride, aluminum oxide, or aluminum nitride can be used. In particular, a material less likely to diffuse oxygen, such as silicon nitride or aluminum oxide, is preferably used for the insulating layer 116, in which case release of oxygen from the semiconductor layer 108 or the insulating layer 114 to the outside through the insulating layer 116 due to heat applied during the fabrication process or the like can be prevented.

For the insulating layer 116, an organic insulating material functioning as a planarization film may be used. Alternatively, a stacked-layer film that includes a film containing an inorganic insulating material and a film containing an organic insulating material may be used as the insulating layer 116.

In the semiconductor layer 108, a pair of low-resistance regions, which are positioned in portions in contact with the conductive layer 112a and the conductive layer 112b and in the vicinity thereof and function as a source region and a drain region, may be formed. The regions are part of the semiconductor layer 108 and have lower resistance than the channel formation region. The low-resistance regions can also be referred to as regions with high carrier concentrations, n-type regions, or the like. In the semiconductor layer 108, a region that is sandwiched between the pair of low-resistance regions and overlaps with the conductive layer 104 functions as a channel formation region.

The above is the description of Structure example 1-1.

A structure example of a transistor whose structure is partly different from that of Structure example 1-1 shown above will be described below. Note that description of the same portions as those in Structure example 1-1 shown above is omitted below in some cases. Furthermore, in drawings that are referred to later, the same hatching pattern is applied to portions having functions similar to those in Structure example 1-1 shown above, and the portions are not denoted by reference numerals in some cases.

### Structure Example 1-2

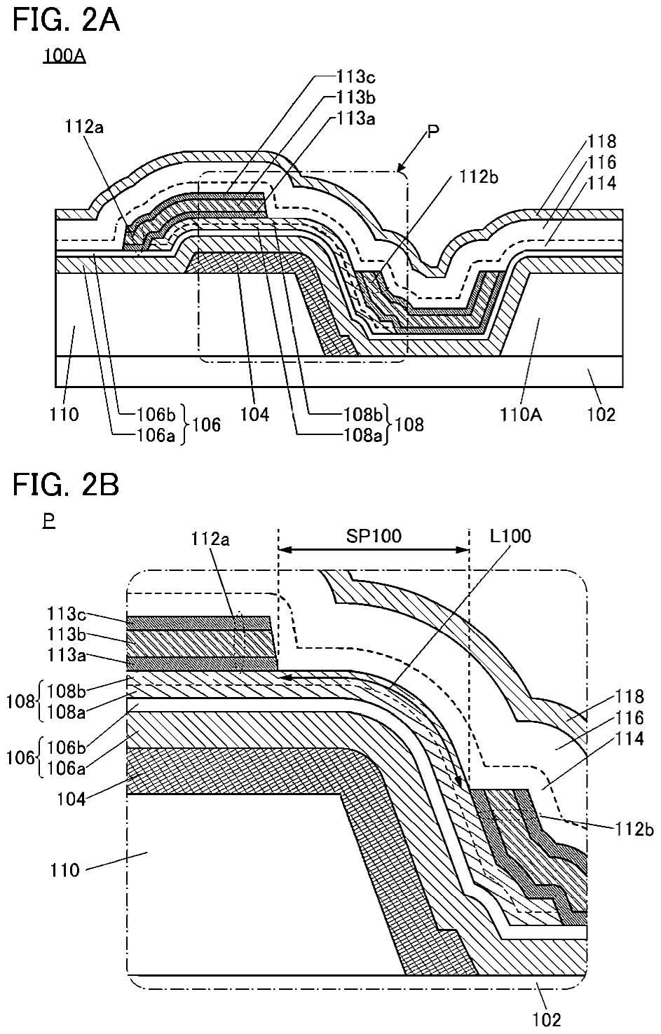

FIG. 2A is a schematic cross-sectional view of a transistor 100A that can be used in a semiconductor device of one embodiment of the present invention in the channel length direction. FIG. 2B is an enlarged view of the region P surrounded by a dashed-dotted line in FIG. 2A. The transistor 100A is different from the transistor 100 mainly in that the semiconductor layer 108 has a stacked structure of the semiconductor layer 108a and the semiconductor layer 108b over the semiconductor layer 108a.

Each of the semiconductor layer 108a and the semiconductor layer 108b preferably includes a metal oxide. Note that a boundary (interface) between the semiconductor layer 108a and the semiconductor layer 108b cannot be clearly observed in some cases. Then, in the drawings illustrating one embodiment of the present invention, the boundary is denoted by a dashed line.

The semiconductor layer 108b, which is positioned on the back channel side, preferably includes a region having higher crystallinity than the semiconductor layer 108a, which is positioned on the conductive layer 104 side. With the semiconductor layer 108b including a region having high crystallinity, the semiconductor layer 108 can be inhibited from being partly etched and lost at the time of forming the conductive layer 112a and the conductive layer 112b. In addition, damage to the semiconductor layer 108 at the time of performing cleaning treatment on the surface of the semiconductor layer 108 can be inhibited.

The semiconductor layer 108a and the semiconductor layer 108b can be formed separately in different formation conditions, for example. The flow rate of oxygen gas in the deposition gas can be made different between the semiconductor layer 108a and the semiconductor layer 108b, for example.

In this case, as the formation conditions of the semiconductor layer 108a, the proportion of oxygen gas flow rate (also referred to as oxygen flow rate ratio or oxygen partial pressure) in the whole gas flow rate is preferably higher than or equal to 0% and lower than 50%, further preferably higher than or equal to 5% and lower than or equal to 30%, still further preferably higher than or equal to 5% and lower than or equal to 20%. With the above oxygen flow rate ratio, the semiconductor layer 108a can have low crystallinity.

The oxygen flow rate ratio at the time of forming the semiconductor layer 108b is preferably higher than the oxygen flow rate ratio at the time of forming the semiconductor layer 108a. As the formation conditions of the semiconductor layer 108b, the oxygen flow rate ratio is preferably higher than or equal to 50% and lower than or equal to 100%, further preferably higher than or equal to 60% and lower than or equal to 100%, still further preferably higher than or equal to 70% and lower than or equal to 100%, yet still further preferably higher than or equal to 80% and lower than or equal to 100%. With the above oxygen flow rate ratio, the semiconductor layer 108b can have high crystallinity.

In the case where the semiconductor layer 108 has a stacked-layer structure, successive formation is preferably performed using the same sputtering target in the same treatment chamber because the interface can be favorable. Although the formation conditions such as pressure, temperature, and power at the time of the formation may vary between the metal oxide films, it is particularly preferable to employ the same conditions except for the oxygen flow rate ratio because the time required for formation steps can be shortened. The semiconductor layer 108 may have a stacked-layer structure of metal oxide films with different compositions. In the case where metal oxide films with different compositions are stacked, successive formation without exposure to the air is preferably performed.

When the semiconductor layer 108 has a stacked-layer structure and the semiconductor layer 108a and the semiconductor layer 108b are formed at the same substrate temperature, the productivity can be increased. In the case where the semiconductor layer 108a and the semiconductor layer 108b are formed at different substrate temperatures, the substrate temperature at the time of forming the semiconductor layer 108b is preferably higher than the substrate temperature at the time of forming the semiconductor layer 108a. The high substrate temperature at the time of forming the semiconductor layer 108b enables the semiconductor layer 108b to have higher crystallinity than the semiconductor layer 108a.

The semiconductor layer 108b preferably include a region having higher crystallinity than the semiconductor layer 108a. For example, it is preferable that a CAC-OS (Cloud-Aligned Composite oxide semiconductor) film be used for the semiconductor layer 108a and a CAAC-OS (c-axis-aligned crystalline oxide semiconductor) film be used for the semiconductor layer 108b.

The crystallinity of the semiconductor layer 108a and the semiconductor layer 108b can be analyzed with X-ray diffraction (XRD), a transmission electron microscope (TEM), electron diffraction, or the like, for example.

The thickness of the semiconductor layer 108a is preferably greater than or equal to 1 nm and less than or equal to 50 nm, further preferably greater than or equal to 5 nm and less than or equal to 30 nm, still further preferably greater than or equal to 5 nm and less than or equal to 20 nm. The thickness of the semiconductor layer 108b is preferably greater than or equal to 1 nm and less than or equal to 50 nm, further preferably greater than or equal to 5 nm and less than or equal to 30 nm, still further preferably greater than or equal to 5 nm and less than or equal to 20 nm.

As the semiconductor layer 108a and the semiconductor layer 108b, layers with different compositions, layers with different crystallinities, or layers with different impurity concentrations may be used. The semiconductor layer 108 may have a stacked-layer structure of three or more layers.

### Structure Example 1-3

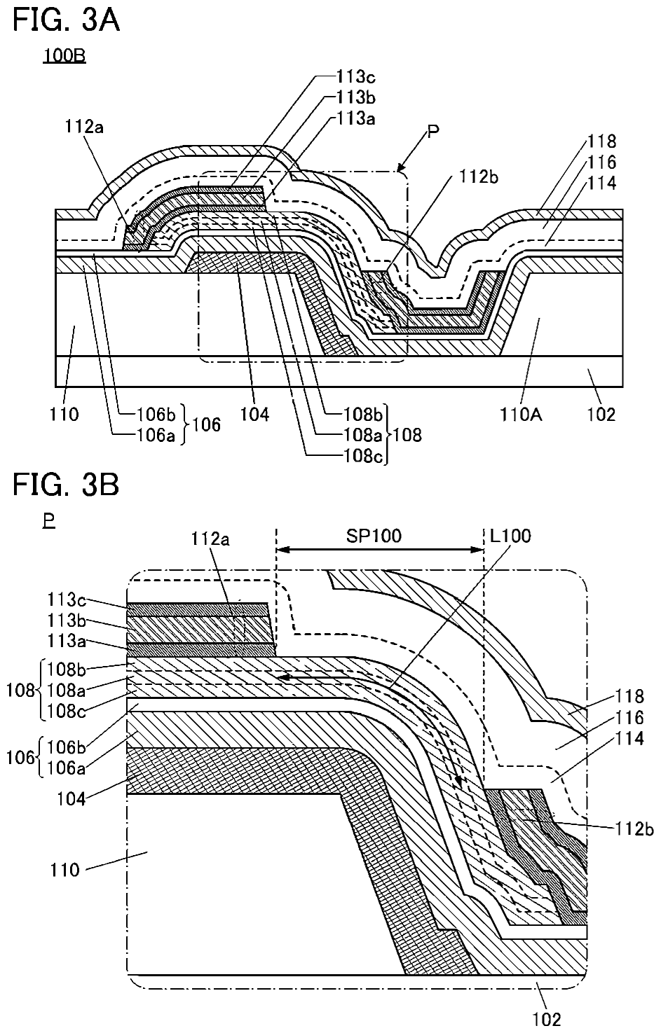

FIG. 3A is a schematic cross-sectional view of a transistor 100B that can be used in a semiconductor device of one embodiment of the present invention in the channel length direction. FIG. 3B is an enlarged view of the region P surrounded by a dashed-dotted line in FIG. 3A. The transistor 100B is different from the transistor 100 mainly in that the semiconductor layer 108 has a stacked structure of a semiconductor layer 108c, the semiconductor layer 108a over the semiconductor layer 108c, and the semiconductor layer 108b over the semiconductor layer 108a. The above description can be referred to for the semiconductor layer 108a and the semiconductor layer 108b; thus, the detailed description thereof is omitted.

Each of the semiconductor layer 108a, the semiconductor layer 108b, and the semiconductor layer 108c preferably contains a metal oxide. Note that a boundary (an interface) between the semiconductor layer 108c and the semiconductor layer 108a cannot be clearly identified in some cases, as well as a boundary (an interface) between the semiconductor layer 108a and the semiconductor layer 108b. Thus, in the drawings illustrating one embodiment of the present invention, these boundaries are denoted by dashed lines.

The semiconductor layer 108c positioned on the insulating layer 106 side preferably includes a region having higher crystallinity than the semiconductor layer 108a. The semiconductor layer 108a, the semiconductor layer 108b, and the semiconductor layer 108c can be formed separately in different formation conditions, for example. For example, the flow rate of an oxygen gas in the deposition gas can be made different between the semiconductor layer 108a, the semiconductor layer 108b, and the semiconductor layer 108c.

The oxygen flow rate ratio at the time of forming the semiconductor layer 108c is preferably higher than the oxygen flow rate ratio at the time of forming the semiconductor layer 108a. As the formation conditions of the semiconductor layer 108c, the oxygen flow rate ratio is preferably higher than or equal to 50% and lower than or equal to 100%, further preferably higher than or equal to 60% and lower than or equal to 100%, still further preferably higher than or equal to 70% and lower than or equal to 100%, yet still further preferably higher than or equal to 80% and lower than or equal to 100%. With the above oxygen flow rate ratio, oxygen can be suitably supplied to the insulating layer 106 in the formation of a film to be the semiconductor layer 108c. By the supply of oxygen to the insulating layer 106, oxygen is supplied to the semiconductor layer 108 in a later step, so that oxygen vacancies V_{O}H and V_{O}H in the semiconductor layer 108 can be reduced. In addition, the crystallinity of the semiconductor layer 108c can be increased. The above description can be referred to for the oxygen flow rate ratios for forming the semiconductor layer 108a and the semiconductor layer 108b; thus, the detailed description thereof is omitted.

The semiconductor layer 108c preferably includes a region having higher crystallinity than the semiconductor layer 108a. Furthermore, the semiconductor layer 108b preferably includes a region having higher crystallinity than the semiconductor layer 108a. For example, it is preferable that a CAAC-OS film be used for the semiconductor layer 108c, a CAC-OS film be used for the semiconductor layer 108a, and a CAAC-OS film be used for the semiconductor layer 108b. The crystallinity of the semiconductor layer 108c can be analyzed by the same method as the method of analyzing the semiconductor layer 108a and the semiconductor layer 108b.

The thickness of the semiconductor layer 108c is preferably greater than or equal to 1 nm and less than or equal to 50 nm, further preferably greater than or equal to 5 nm and less than or equal to 30 nm, still further preferably greater than or equal to 5 nm and less than or equal to 20 nm. The thickness of the semiconductor layer 108a is preferably greater than or equal to 1 nm and less than or equal to 50 nm, further preferably greater than or equal to 5 nm and less than or equal to 30 nm, still further preferably greater than or equal to 5 nm and less than or equal to 20 nm. The thickness of the semiconductor layer 108b is preferably greater than or equal to 1 nm and less than or equal to 50 nm, further preferably greater than or equal to 5 nm and less than or equal to 30 nm, still further preferably greater than or equal to 5 nm and less than or equal to 20 nm.

As the semiconductor layer 108c, the semiconductor layer 108a, and the semiconductor layer 108b, layers with different compositions, layers with different crystallinities, or layers with different impurity concentrations may be used. The semiconductor layer 108 may have a stacked-layer structure of four or more layers.

### Structure Example 1-4

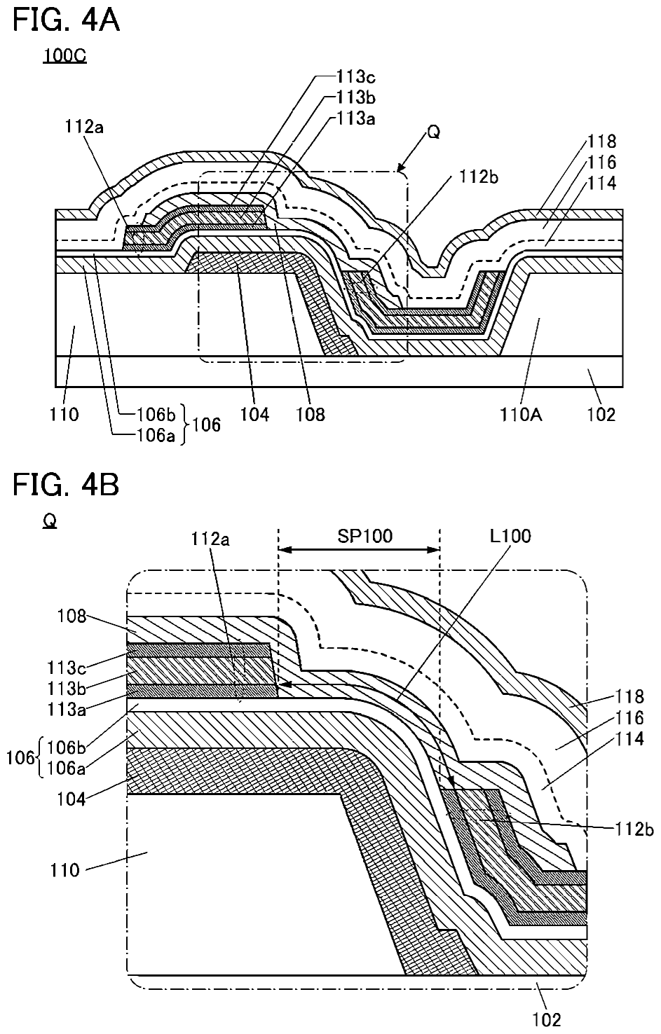

FIG. 4A is a schematic cross-sectional view of a transistor 100C that can be used in a semiconductor device of one embodiment of the present invention in the channel length direction. The transistor 100C is different from the transistor 100 mainly in that the transistor 100C includes the semiconductor layer 108 over the conductive layer 112a and the conductive layer 112b. The transistor 100C is what is called a bottom-gate transistor including a gate electrode below the semiconductor layer 108. Furthermore, the transistor 100C can be referred to as a BGBC transistor because the transistor 100C includes the source electrode and the drain electrode below the semiconductor layer 108.

The above description in Structure example 1-1 can be referred to for the conductive layer 104 and the insulating layer 106; thus, the detailed description thereof is omitted. Each of the conductive layer 112a and the conductive layer 112b is provided over the insulating layer 106 and in contact with the top surface of the insulating layer 106. Each of the conductive layer 112a and the conductive layer 112b is in contact with a bottom surface of the semiconductor layer 108. The semiconductor layer 108 is provided over the conductive layer 112a, the conductive layer 112b, and the insulating layer 106. The semiconductor layer 108 is in contact with the top surface and the side surface of the conductive layer 112a, the top surface and the side surface of the conductive layer 112b, and the top surface of the insulating layer 106.

FIG. 4B is an enlarged view of a region Q surrounded by a dashed-dotted line in FIG. 4A. The semiconductor layer 108 includes a curved region between the conductive layer 112a and the conductive layer 112b. In other words, the transistor 100C includes a curved channel formation region. The distance SP100 and the channel length L100 are different values, and the channel length L100 is a larger value than the distance SP100.

For example, the value of the channel length L100 can be smaller than the exposure limit of a light exposure apparatus. The transistor 100C can have the channel length L100 which is shorter than the exposure limit of a light exposure apparatus by providing the conductive layer 112a over the insulating layer 110 and providing the conductive layer 112b in the groove 111.

### Structure Example 1-5

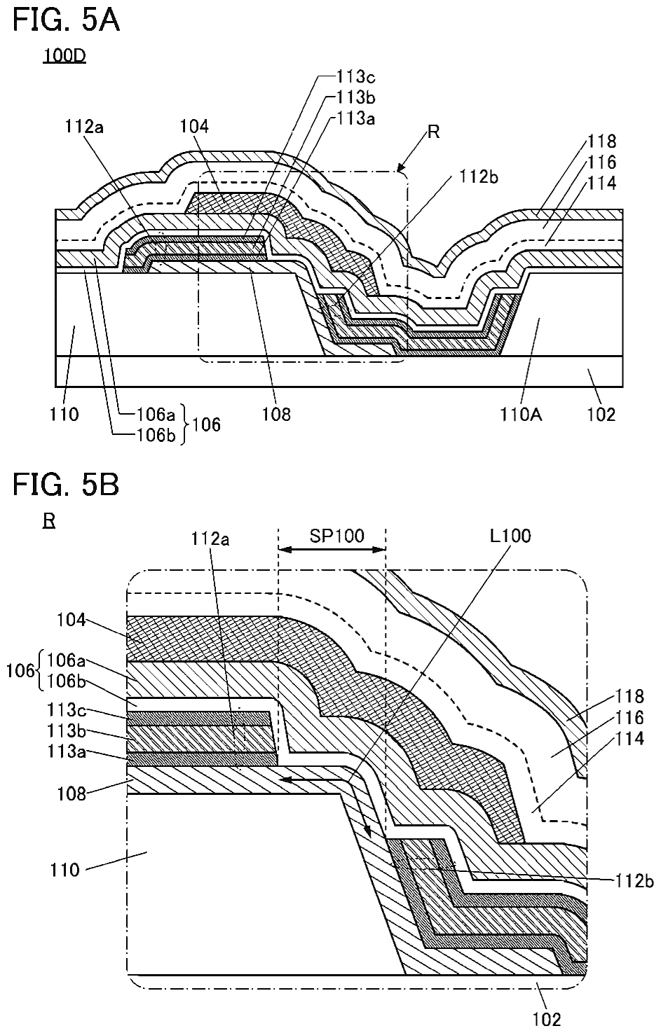

FIG. 5A is a schematic cross-sectional view of a transistor 100D that can be used in a semiconductor device of one embodiment of the present invention in the channel length direction. The transistor 100D is different from the transistor 100 mainly in that the transistor 100D includes the conductive layer 104 over the semiconductor layer 108.

The transistor 100D is what is called a top-gate transistor including a gate electrode above the semiconductor layer 108. Furthermore, the transistor 100D can be referred to as a TGTC transistor because the transistor 100D includes the source electrode and the drain electrode above the semiconductor layer 108.

The above description in Structure example 1-1 can be referred to for the semiconductor layer 108, the conductive layer 112a, and the conductive layer 112b; thus, the detailed description thereof is omitted. The insulating layer 106 is provided over the semiconductor layer 108, the conductive layer 112a, and the conductive layer 112b. The insulating layer 106 is in contact with the top surface and the side surface of the conductive layer 112a, the top surface and the side surface of the conductive layer 112b, and the top surface of the semiconductor layer 108. In the case where the insulating layer 106 has a stacked-layer structure, the insulating layer 106a is preferably provided on the semiconductor layer 108 side such that the semiconductor layer 108 and the insulating layer 106a are in contact with each other. The conductive layer 104 is provided over the insulating layer 106 to be in contact with the top surface of the insulating layer 106. In the case where the insulating layer 106 has a stacked-layer structure, the insulating layer 106b is preferably provided on the conductive layer 104 side such that the conductive layer 104 and the insulating layer 106b are in contact with each other.

FIG. 5B is an enlarged view of a region R surrounded by a dashed-dotted line in FIG. 5A. The semiconductor layer 108 includes a curved region between the conductive layer 112a and the conductive layer 112b. In other words, the transistor 100D includes a curved channel formation region. The distance SP100 and the channel length L100 are different values, and the channel length L100 is a larger value than the distance SP100.

For example, the value of the channel length L100 can be smaller than the exposure limit of a light exposure apparatus. The transistor 100D can have the channel length L100 which is shorter than the exposure limit of a light exposure apparatus by providing the conductive layer 112a over the insulating layer 110 and providing the conductive layer 112b in the groove 111.

### Structure Example 1-6

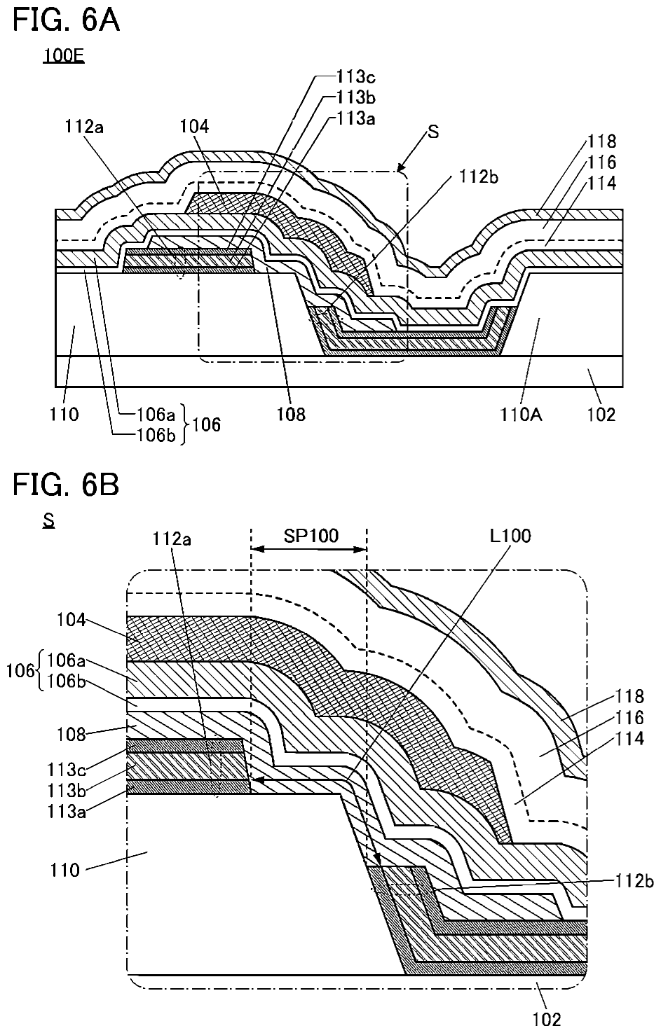

FIG. 6A is a schematic cross-sectional view of a transistor 100E that can be used in a semiconductor device of one embodiment of the present invention in the channel length direction. The transistor 100E is different from the transistor 100 mainly in that the transistor 100E includes the semiconductor layer 108 over the conductive layer 112a and the conductive layer 112b and the conductive layer 104 over the semiconductor layer 108.

The transistor 100E is what is called a top-gate transistor including agate electrode above the semiconductor layer 108. Furthermore, the transistor 100E can be referred to as a TGBC transistor because the transistor 100E includes the source electrode and the drain electrode below the semiconductor layer 108.

The above description can be referred to for the conductive layer 112a, the conductive layer 112b, the semiconductor layer 108, the insulating layer 106, and the conductive layer 104; thus, the detailed description thereof is omitted.

FIG. 6B is an enlarged view of a region S surrounded by a dashed-dotted line in FIG. 6A. The semiconductor layer 108 includes a curved region between the conductive layer 112a and the conductive layer 112b. In other words, the transistor 100E includes a curved channel formation region. The distance SP100 and the channel length L100 are different values, and the channel length L100 is a larger value than the distance SP100.

For example, the value of the channel length L100 can be smaller than the exposure limit of a light exposure apparatus. The transistor 100D can have the channel length L100 which is shorter than the exposure limit of a light exposure apparatus by providing the conductive layer 112a over the insulating layer 110 and providing the conductive layer 112b in the groove 111.

### Structure Example 2

A structure of a semiconductor device including the transistor described above in Structure example 1 will be described below with reference to drawings.

### Structure Example 2-1

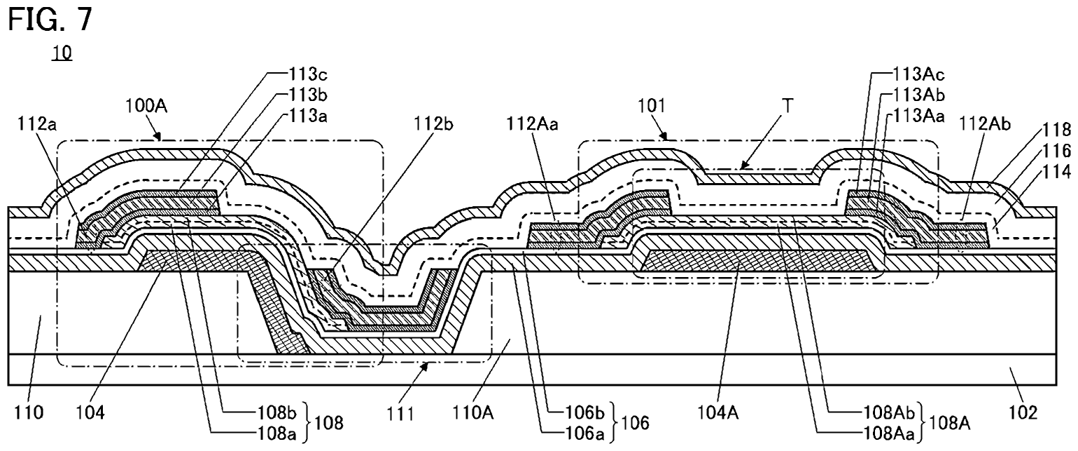

A structure example of a semiconductor device 10 that is one embodiment of the present invention is illustrated in FIG. 7. Here, a semiconductor device including the transistor 100A is described as an example. The semiconductor device 10 includes the transistor 100A over the insulating layer 110 and a transistor 101 over the insulating layer 110A. The above description can be referred to for the transistor 100A; thus, the detailed description thereof is omitted.

The transistor 101 includes a conductive layer 104A, the insulating layer 106, a semiconductor layer 108A, a conductive layer 112Aa, and a conductive layer 112Ab. The conductive layer 104A functions as a gate electrode. Part of the insulating layer 106 functions as a gate insulating layer. The conductive layer 112Aa functions as one of a source electrode and a drain electrode, and the conductive layer 112Ab functions as the other. A region of the semiconductor layer 108A which overlaps with the conductive layer 104A functions as a channel formation region.

The transistor 101 includes a gate electrode below the semiconductor layer 108A and includes a source electrode and a drain electrode above the semiconductor layer 108A; that is, the transistor 101 is a BGTC transistor. The transistor 101 has what is called a channel-etched structure in which no protective layer is provided between the back channel side of the semiconductor layer 108A and the source and drain electrodes.

The transistor 101 is provided over the insulating layer 110A. The insulating layer 110A has an island shape and is provided over the substrate 102.

The conductive layer 104A is provided over the insulating layer 110A and in contact with a top surface and a side surface of the insulating layer 110A. The conductive layer 104A has a flat shape along the top surface of the insulating layer 110A.

The semiconductor layer 108A has an island-like shape and is in contact with a top surface of the insulating layer 106. The semiconductor layer 108A includes a region overlapping with the conductive layer 104A with the insulating layer 106 positioned therebetween. Each of the conductive layer 112Aa and the conductive layer 112Ab is provided over the semiconductor layer 108A and in contact with a top surface of the semiconductor layer 108A. Each of the conductive layer 112Aa and the conductive layer 112Ab may be in contact with a side surface of the semiconductor layer 108A and the top surface of the insulating layer 106.

The conductive layer 112Aa and the conductive layer 112b are each provided over the insulating layer 110A. In a region overlapping with the conductive layer 104A, a top surface of the conductive layer 112Aa and a top surface of the conductive layer 112Ab are level with or substantially level with each other. In a region not overlapping with the conductive layer 104A, the top surface of the conductive layer 112Aa and the top surface of the conductive layer 112Ab are level with or substantially level with each other.

Although FIG. 7 illustrates an example in which in the region overlapping with the conductive layer 104A, a side surface of the conductive layer 112Aa and a side surface of the conductive layer 112Ab are level with or substantially level with each other and in the region not overlapping with the conductive layer 104A, a side surface of the conductive layer 112Aa and a side surface of the conductive layer 112Ab are level with or substantially level with each other, one embodiment of the present invention is not limited to this. The level of the side surface of the conductive layer 112Aa and the level of the side surface of the conductive layer 112Ab may be different.

FIG. 7 illustrates an example in which the conductive layer 112Aa and the conductive layer 112Ab each have a stacked-layer structure in which a conductive layer 113Aa, a conductive layer 113Ab, and a conductive layer 113Ac are stacked in this order from the formation surface side. For the conductive layer 113Aa, a material that can be used for the conductive layer 113a can be used. For the conductive layer 113Ab, a material that can be used for the conductive layer 113b can be used. For the conductive layer 113Ac, a material that can be used for the conductive layer 113c can be used. The conductive layer 112Aa and the conductive layer 112Ab can be formed in the same steps as the conductive layer 112a and the conductive layer 112b.

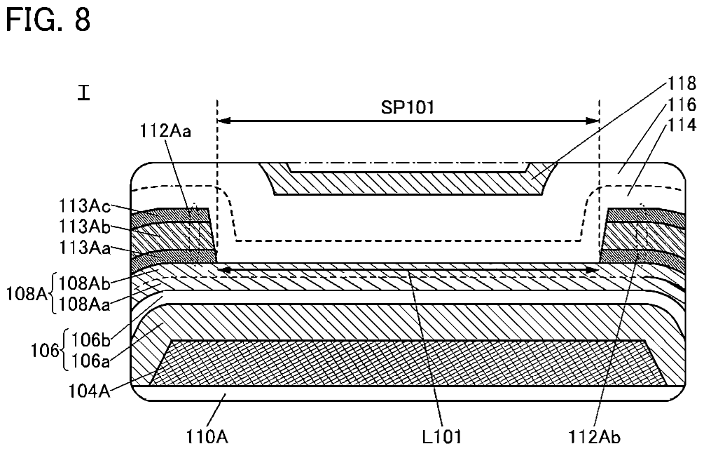

FIG. 8 is an enlarged view of a region T surrounded by a dashed-dotted line in FIG. 7. In FIG. 8, a distance SP101 between the conductive layer 112Aa and the conductive layer 112Ab and a channel length L101 of the transistor 101 are indicated by arrows. The semiconductor layer 108 between the conductive layer 112Aa and the conductive layer 112Ab has a flat shape. It can be said that the transistor 101 includes a flat channel formation region. The distance SP101 and the channel length L101 have the same value or substantially the same values.

The channel length L101 of the transistor 101 can have a larger value than the channel length L100 of the transistor 100A. For example, the channel length L101 can have a value larger than the exposure limit of a light exposure apparatus. The transistor 101 with a long channel length can show favorable saturation characteristics in a saturation region.

The conductive layer 104A can be formed in the same step as the conductive layer 104. The semiconductor layer 108A can be formed in the same step as the semiconductor layer 108. The conductive layer 112Aa and the conductive layer 112Ab can be formed in the same step as the conductive layer 112a and the conductive layer 112b. That is, the transistor 101 and the transistor 100A can be formed over the same substrate in the same step.

The semiconductor layer 108A preferably has a stacked structure of a semiconductor layer 108Aa and a semiconductor layer 108Ab over the semiconductor layer 108Aa. The semiconductor layer 108Aa can be formed in the same step as the semiconductor layer 108a. The semiconductor layer 108Ab can be formed in the same step as the semiconductor layer 108b. Although FIG. 7 illustrates an example in which each of the semiconductor layer 108 and the semiconductor layer 108A has a stacked-layer structure, one embodiment of the present invention is not limited to this. One of the semiconductor layer 108 and the semiconductor layer 108A may have a single layer structure and the other may have a stacked-layer structure.

In the semiconductor device 10 of one embodiment of the present invention, the transistor 100A which has a short channel length and a high on-state current and the transistor 101 which has a long channel length and favorable saturation characteristics can be formed over the same substrate in the same step. With such a structure, the semiconductor device 10 can have high performance by utilizing the advantages of the respective transistors. In addition, the manufacturing cost of the semiconductor device 10 can be reduced.

Although FIG. 7 illustrates a structure in which the transistor 101 is provided over the insulating layer 110A which is adjacent to the insulating layer 110, one embodiment of the present invention is not limited to this. The transistor 101 is not necessarily provided over the insulating layer. The transistor 101 may be provided over an insulating layer which is not adjacent to the insulating layer 110.

Although FIG. 7 illustrates an example of the semiconductor device 10 in which the BGTC transistor 100A is provided over the insulating layer 110 and the BGTC transistor 101 is provided over the insulating layer 110A, one embodiment of the present invention is not limited to this. The transistor described in Structure example 1 can be used as the transistor over the insulating layer 110. The transistor over the insulating layer 110 and the transistor over the insulating layer 110A may have different structures. For example, a BGTC transistor can be provided over the insulating layer 110 and a TGTC transistor can be provided over the insulating layer 110A. Note that the structure of the transistor over the insulating layer 110A is not particularly limited. For example, a TGTC transistor may be provided over the insulating layer 110 and a TGSA (Top Gate Self Align) transistor may be provided over the insulating layer 110A.

The semiconductor device 10 of one embodiment of the present invention can be used for a display device, for example. The semiconductor device 10 can be used not only for a display device but also for a variety of circuits and devices. For example, the transistor of one embodiment of the present invention can be suitably used in various circuits in an IC chip mounted on an electronic device or the like, such as an arithmetic circuit, a memory circuit, a driver circuit, and an interface circuit; or driver circuits for a display device in which a liquid crystal element, an organic EL element, or the like is used or for various sensor devices such as a touch sensor, an optical sensor, and a biosensor.

### Structure Example 2-2

A structure example of a semiconductor device whose structure is partly different from that of Structure example 2-1 shown above will be described below. Note that description of the same portions as those in Structure example 2-1 shown above is omitted below in some cases. Furthermore, in drawings that are referred to later, the same hatching pattern is applied to portions having functions similar to those in Structure example 2 shown above, and the portions are not denoted by reference numerals in some cases.

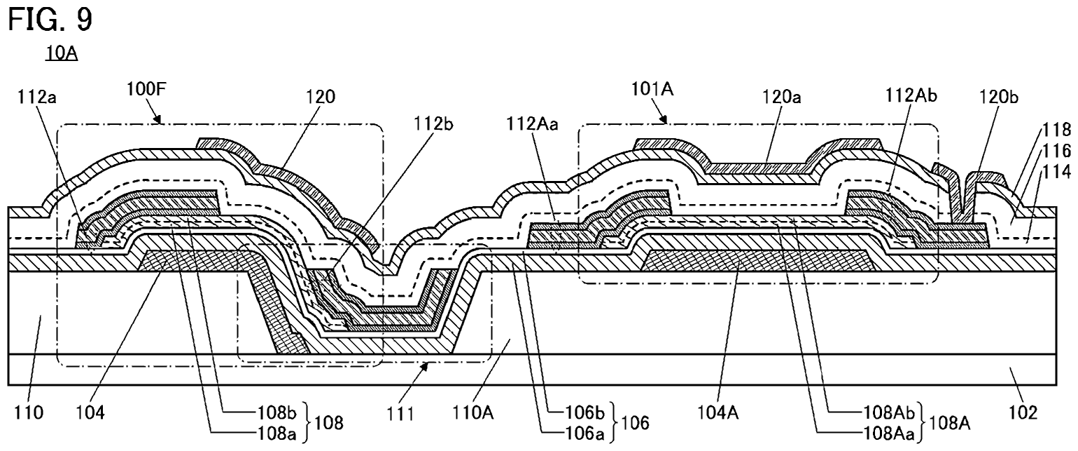

A structure example of a semiconductor device 10A that is one embodiment of the present invention is illustrated in FIG. 9. The semiconductor device 10A includes a transistor 100F and a transistor 101A. The transistor 100F is different from the above-described transistor 100 mainly in that the transistor 100F includes a conductive layer 120 over the insulating layer 118. The transistor 101A is different from the transistor 101 mainly in that the transistor 101A includes a conductive layer 120a and a conductive layer 120b over the insulating layer 118.

The conductive layer 120 includes a region overlapping with the semiconductor layer 108 with the insulating layer 114, the insulating layer 116, and the insulating layer 118 therebetween. The semiconductor layer 108 is positioned between the conductive layer 104 and the conductive layer 120, and the conductive layer 104, the semiconductor layer 108, and the conductive layer 120 include a region where they overlap with one another. The transistor 100F is a dual-gate transistor including the conductive layer 104 functioning as a gate electrode and the conductive layer 120 functioning as a back gate electrode over and under the semiconductor layer 108. Here, in the transistor 100F, part of the insulating layer 106 functions as a first gate insulating layer, and part of each of the insulating layer 114, the insulating layer 116, and the insulating layer 118 functions as a second gate insulating layer.

The conductive layer 120 may be electrically connected to the conductive layer 104 through an opening (not illustrated) provided in the insulating layer 106, the insulating layer 114, the insulating layer 116, and the insulating layer 118. Accordingly, the same potential can be supplied to the conductive layer 120 and the conductive layer 104, which enables the transistor 100F to have high on-state current.

A structure in which the conductive layer 104 and the conductive layer 120 are not connected to each other may be employed. In that case, a constant potential may be supplied to one of the gate electrode and the backgate electrode, and a signal for driving the transistor 100F may be supplied to the other. In that case, the potential supplied to one of the gate electrode and the backgate electrode enables control of the threshold voltage at the time of driving the transistor 100F with the other. When the same potential is supplied to the conductive layer 104 and the conductive layer 120, the amount of current that can flow in an on state can be increased.

With such a structure, the transistor 100F can have favorable electrical characteristics and extremely high reliability.

The conductive layer 120a includes a region overlapping with the semiconductor layer 108A with the insulating layer 114, the insulating layer 116, and the insulating layer 118 therebetween. The semiconductor layer 108A is positioned between the conductive layer 104A and the conductive layer 120a, and the conductive layer 104A, the semiconductor layer 108A, and the conductive layer 120a include a region where they overlap with one another. The transistor 101A is a dual-gate transistor including the conductive layer 104A functioning as a gate electrode and the conductive layer 120a functioning as a back gate electrode over and under the semiconductor layer 108A. Here, in the transistor 101A, part of the insulating layer 106 functions as a first gate insulating layer, and part of each of the insulating layer 114, the insulating layer 116, and the insulating layer 118 functions as a second gate insulating layer.

The conductive layer 120a may be electrically connected to the conductive layer 104A through an opening (not illustrated) provided in the insulating layer 106, the insulating layer 114, the insulating layer 116, and the insulating layer 118. Accordingly, the same potential can be supplied to the conductive layer 120a and the conductive layer 104A, which enables the transistor 101A to have high on-state current.

A structure in which the conductive layer 104A and the conductive layer 120a are not connected to each other may be employed. In that case, a constant potential may be supplied to one of the gate electrode and the backgate electrode, and a signal for driving the transistor 101A may be supplied to the other. In that case, the potential supplied to one of the electrodes enables control of the threshold voltage at the time of driving the transistor 101A with the other of the electrodes. When the same potential is supplied to the conductive layer 104A and the conductive layer 120a, the amount of current that can flow in an on state can be increased.

With such a structure, the transistor 101A can have favorable electrical characteristics and extremely high reliability.

The conductive layer 120b is electrically connected to the conductive layer 112Ab through an opening provided in the insulating layer 114, the insulating layer 116, and the insulating layer 118. The conductive layer 120b can be used as a wiring or an electrode. When the semiconductor device 10A is used in a display device, for example, the conductive layer 120b can function as a pixel electrode or a wiring for connection to a pixel electrode.

Although FIG. 9 illustrates an example in which the transistor 100F and the transistor 101A each have a backgate electrode, one embodiment of the present invention is not limited to this. For example, a structure in which the transistor 100F includes the conductive layer 120 and the transistor 101A does not include the conductive layer 120a may be employed. Alternatively, a structure in which the transistor 100F does not include the conductive layer 120 and the transistor 101A includes the conductive layer 120a may be employed. Alternatively, a structure in which neither the transistor 100F nor the transistor 101A includes a backgate electrode may be employed.

The above is the description of Structure example 2-2.

### Structure Example 2-3

A structure example of a semiconductor device whose structure is partly different from that of Structure example 2-1 shown above will be described below. Note that description of the same portions as those in Structure example 3 shown above is omitted below in some cases. Furthermore, in drawings that are referred to later, the same hatching pattern is applied to portions having functions similar to those in Structure example 3 shown above, and the portions are not denoted by reference numerals in some cases.

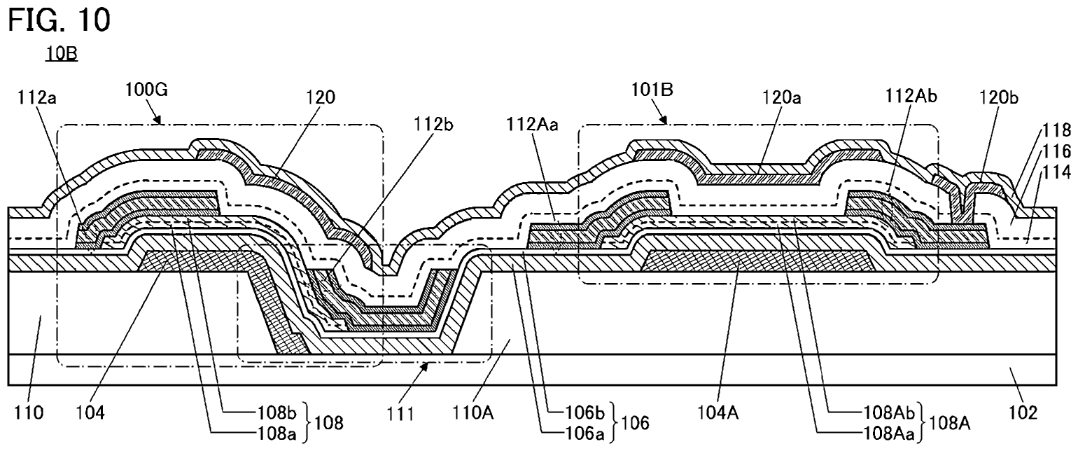

A structure example of a semiconductor device 10B that is one embodiment of the present invention is illustrated in FIG. 10. The semiconductor device 10B includes a transistor 100G and a transistor 101B. The transistor 100G is different from the above-described transistor 100C mainly in that the transistor 100G includes the conductive layer 120 between the insulating layer 116 and the insulating layer 118. The transistor 101B is different from the transistor 101A mainly in that the transistor 101B includes the conductive layer 120a and the conductive layer 120b between the insulating layer 116 and the insulating layer 118.

The conductive layer 120b is electrically connected to the conductive layer 112Ab through an opening provided in the insulating layer 114 and the insulating layer 116.

With such a structure, the distance between the conductive layer 120 and the semiconductor layer 108 is shortened, and thus the electrical characteristics of the transistor 100G can be improved. Similarly, the distance between the conductive layer 120a and the semiconductor layer 108A is shortened, and thus the electrical characteristics of the transistor 101B can be improved.

### Fabrication Method Example 1

A method for fabricating the semiconductor device of one embodiment of the present invention will be described below with reference to drawings. Here, description will be made giving, as an example, the semiconductor device 10 described above.

Note that thin films that form the semiconductor device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD) method and a thermal CVD method. In addition, as an example of the thermal CVD method, a metal organic chemical vapor deposition (MOCVD) method can be given.

The thin films that form the semiconductor device (insulating films, semiconductor films, conductive films, and the like) can be formed by a method such as spin coating, dipping, spray coating, ink-jetting, dispensing, screen printing, or offset printing, a doctor knife, a slit coater, a roll coater, a curtain coater, or a knife coater.

When the thin films that form the semiconductor device are processed, a photolithography method or the like can be used for the processing. Besides, a nanoimprinting method, a sandblasting method, a lift-off method, or the like may be used for the processing of the thin films. Island-shaped thin films may be directly formed by a deposition method using a blocking mask such as a metal mask.

There are two typical examples of a photolithography method. In one of the methods, a resist mask is formed over a thin film that is to be processed, the thin film is processed by etching or the like, and the resist mask is removed. In the other method, after a photosensitive thin film is formed, exposure and development are performed, so that the thin film is processed into a desired shape.

For light used for exposure in a photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. Exposure may be performed by liquid immersion exposure technique. Furthermore, as the light used for the exposure, extreme ultra-violet (EUV) light or X-rays may be used. Furthermore, instead of the light used for the exposure, an electron beam can also be used. It is preferable to use extreme ultra-violet light, X-rays, or an electron beam because extremely minute processing can be performed. Note that in the case of performing exposure by scanning of a beam such as an electron beam, a photomask is not needed.

For etching of the thin film, a dry etching method, a wet etching method, a sandblasting method, or the like can be used.

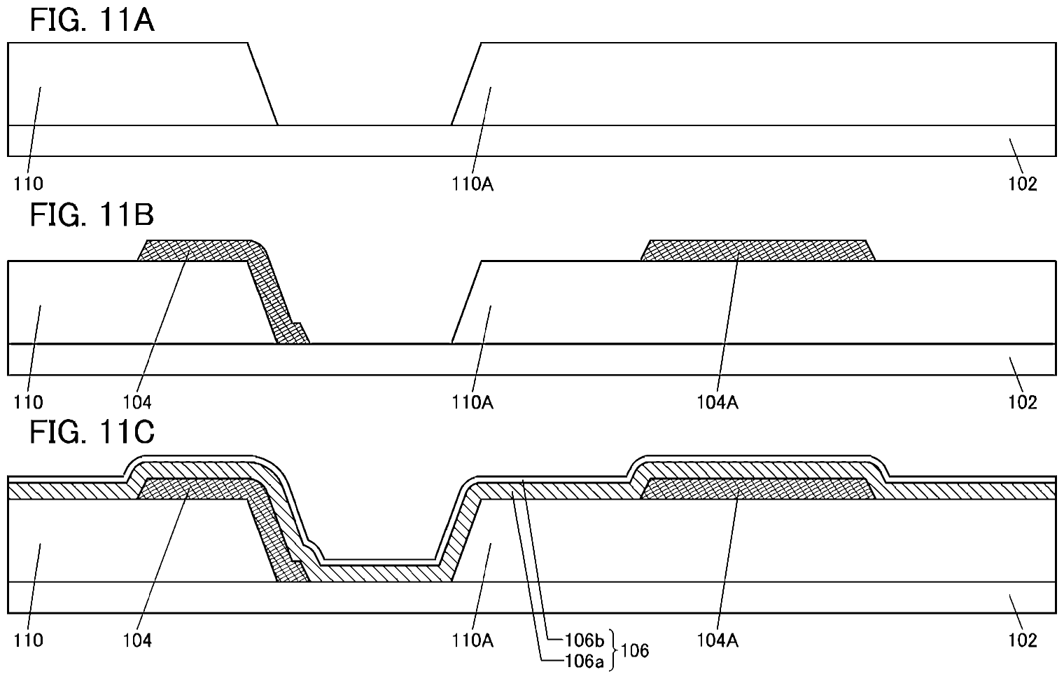

FIG. 11 to FIG. 17 are drawings illustrating a method of fabricating the transistor 100 and the transistor 101. Each drawing shows a cross section in the channel length direction.

### [Formation of Insulating Layer 110 and Insulating Layer 110A]

An insulating film is formed over the substrate 102. The insulating film can be formed by a PECVD method or the like, for example. A resist mask is formed over the insulating film by a lithography process, and then the insulating is processed, so that the insulating layer 110 and the insulating layer 110A each having an island shape are formed (FIG. 11A). For the processing, one or both of a wet etching method and a dry etching method are used.

### [Formation of Conductive Layer 104 and Conductive Layer 104A]

A conductive film is formed over the insulating layer 110, the insulating layer 110A, and the substrate 102, a resist mask is formed over the conductive film by a lithography process, and then the conductive film is processed, whereby the conductive layer 104 and the conductive layer 104A each functioning as a gate electrode are formed (FIG. 11B). For the processing, one or both of a wet etching method and a dry etching method are used. The conductive layer 104 is provided over the insulating layer 110 and is in contact with a top surface and a side surface of the insulating layer 110. The conductive layer 104A is provided over the insulating layer 110A and is in contact with a top surface of the insulating layer 110A.

### [Formation of Insulating Layer 106]

Next, the insulating layer 106 covering the insulating layer 110, the insulating layer 110A, the conductive layer 104, the conductive layer 104A, and the substrate 102 is formed (FIG. 11C). The insulating layer 106 can be formed by a PECVD method or the like, for example.

Heat treatment may be performed after the formation of the insulating layer 106. By the heat treatment, water or hydrogen can be released from the surface and inside of the insulating layer 106.

The heat treatment temperature is preferably higher than or equal to 150° C. and lower than the strain point of the substrate, further preferably higher than or equal to 250° C. and lower than or equal to 450° C., still further preferably higher than or equal to 300° C. and lower than or equal to 450° C. The heat treatment can be performed in an atmosphere containing one or more of a rare gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating layer 106 can be prevented as much as possible. An oven, a rapid thermal annealing (RTA) apparatus, or the like can be used for the heat treatment. The use of the RTA apparatus can shorten the heat treatment time.

Next, treatment for supplying oxygen to the insulating layer 106 may be performed. As the oxygen supply treatment, an oxygen radical, an oxygen atom, an oxygen atomic ion, an oxygen molecular ion, or the like is supplied to the insulating layer 106 by an ion doping method, an ion implantation method, plasma treatment, or the like. Alternatively, a film that inhibits oxygen release may be formed over the insulating layer 106, and then oxygen may be added to the insulating layer 106 through the film. It is preferable to remove the film after addition of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

### [Formation of Semiconductor Layer 108 and Semiconductor Layer 108A]

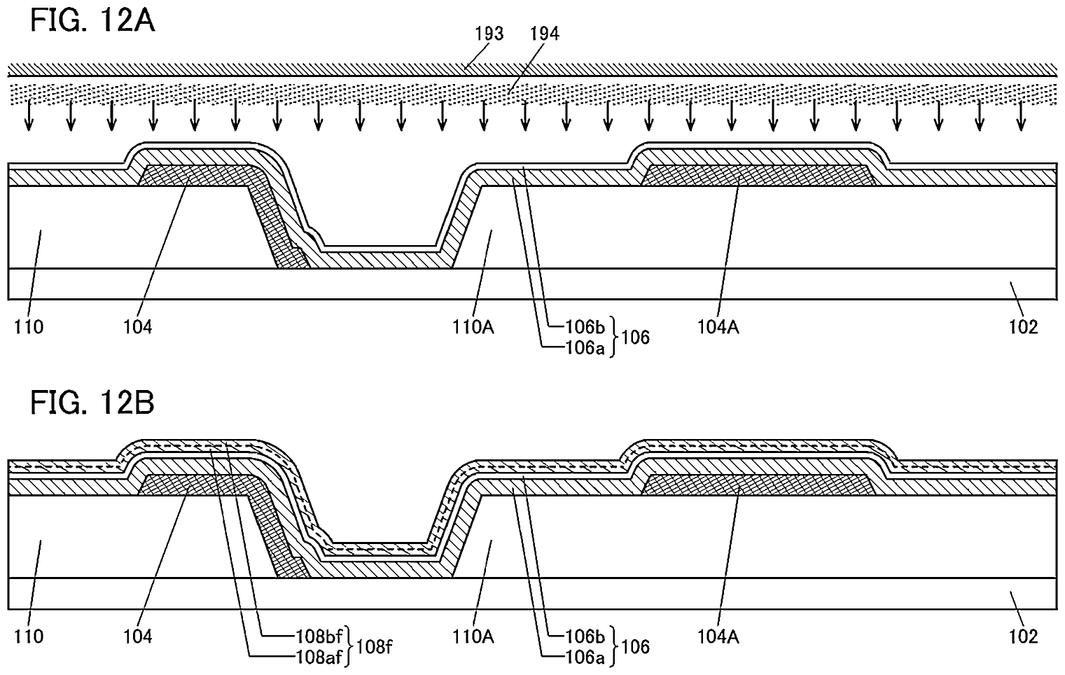

Next, a metal oxide film 108f is formed over the insulating layer 106. Here, a stacked-layer of a metal oxide film 108af and a metal oxide film 108bf over the metal oxide film 108af is formed as the metal oxide film 108f (FIG. 12A and FIG. 12B).

The metal oxide film 108af and the metal oxide film 108bf are each preferably formed by a sputtering method using a metal oxide target. In forming the metal oxide film 108af and the metal oxide film 108bf, an oxygen gas is preferably used. FIG. 12A is a schematic cross-sectional view of the inside of a sputtering apparatus at the time of forming the metal oxide film 108af over the insulating layer 106. A target 193 placed inside the sputtering apparatus and plasma 194 formed under the target 193 are schematically illustrated. For example, in the case of using an oxygen gas at the time of forming the metal oxide film 108af, oxygen can be favorably supplied to the insulating layer 106. For example, in the case where oxide is used for the insulating layer 106a, oxygen can be favorably supplied to the insulating layer 106a. Note that oxygen supplied to the insulating layer 106 is represented by arrows in FIG. 12A.

By supply of oxygen to the insulating layer 106, oxygen can be supplied to the semiconductor layer 108 in a later step, so that oxygen vacancies V_{O}H and V_{O}H in the semiconductor layer 108 can be reduced.

In forming the metal oxide film 108af and the metal oxide film 108bf, an oxygen gas and an inert gas (e.g., a helium gas, an argon gas, or a xenon gas) may be mixed. Note that the proportion of the oxygen gas in the whole deposition gas (hereinafter, also referred to as an oxygen flow rate ratio) in forming the metal oxide film 108af and the metal oxide film 108bf can be in the range of 0% to 100% inclusive.

When a metal oxide film with relatively low crystallinity is formed with a low oxygen flow rate ratio, a metal oxide film having high conductivity can be obtained. By contrast, when a metal oxide film with relatively high crystallinity is formed with a high oxygen flow rate ratio, a metal oxide film having high etching resistance and electrical stability can be obtained.

Here, the metal oxide film 108af positioned on the conductive layer 104 (functioning as a gate electrode) side is a film with low crystallinity, whereas the metal oxide film 108bf positioned on the back channel side is a film with high crystallinity, which enables a transistor to have high reliability and high field-effect mobility.

More specifically, the oxygen flow rate ratio at the time of forming the metal oxide film 108af is preferably higher than or equal to 0% and lower than 50%, further preferably higher than or equal to 5% and lower than or equal to 30%, still further preferably higher than or equal to 5% and lower than or equal to 20%, typically 10%. The oxygen flow rate ratio at the time of forming the metal oxide film 108bf is preferably higher than the oxygen flow rate ratio at the time of forming the metal oxide film 108af. The oxygen flow rate ratio at the time of forming the metal oxide film 108bf is preferably higher than or equal to 50% and lower than or equal to 100%, further preferably higher than or equal to 60% and lower than or equal to 100%, still further preferably higher than or equal to 70% and lower than or equal to 100%, yet still further preferably higher than or equal to 80% and lower than or equal to 100%, typically 100%.

The substrate temperature for forming the metal oxide film 108af and the metal oxide film 108bf is preferably higher than or equal to room temperature and lower than or equal to 200° C., further preferably higher than or equal to room temperature and lower than or equal to 140° C., for example. The substrate temperature during formation of the metal oxide film 108af and the metal oxide film 108bf is preferably, for example, higher than or equal to room temperature and lower than 140° C. because the productivity is increased.

The metal oxide film 108af and the metal oxide film 108bf can be films with the same composition or substantially the same compositions. The metal oxide film 108af and the metal oxide film 108bf can be formed using the same sputtering target; thus, the manufacturing cost can be reduced. When the same sputtering target is used, the metal oxide film 108af and the metal oxide film 108bf can be formed successively in the same deposition apparatus in a vacuum, which can inhibit entry of impurities into the interface between the semiconductor layer 108a and the semiconductor layer 108b. Although conditions during the formation, such as pressure, temperature, and power, may vary between the metal oxide film 108af and the metal oxide film 108bf, it is preferable to employ the same conditions except for the oxygen flow rate ratio because the time required for the formation steps can be shortened.

Note that the metal oxide film 108af and the metal oxide film 108bf may be films with different compositions from each other. In that case, when an In—Ga—Zn oxide is used for both the metal oxide film 108af and the metal oxide film 108bf, an oxide target in which the proportion of the contained In is higher than that in the metal oxide film 108af is preferably used for the metal oxide film 108bf.

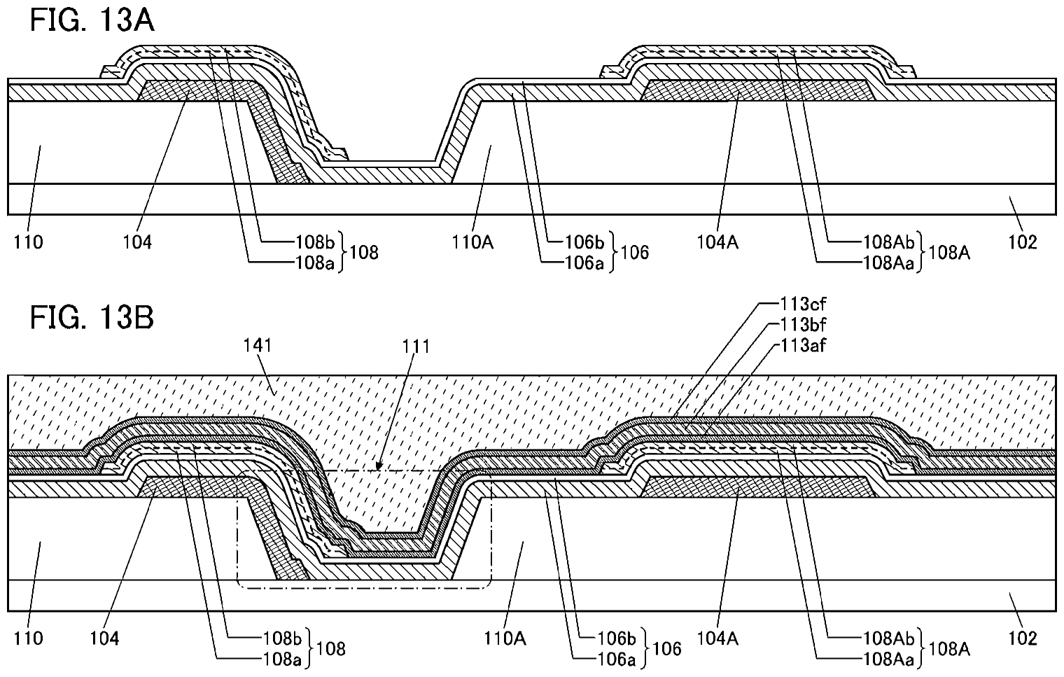

After the formation of the metal oxide film 108af and the metal oxide film 108bf, a resist mask is formed over the metal oxide film 108bf, the metal oxide film 108af and the metal oxide film 108bf are processed by etching, and then the resist mask is removed, whereby the island-shaped semiconductor layer 108 in which the semiconductor layer 108a and the semiconductor layer 108b are stacked and the island-shaped semiconductor layer 108A in which the semiconductor layer 108Aa and the semiconductor layer 108Ab are stacked can be formed (FIG. 13A).

For processing of the metal oxide film 108af and the metal oxide film 108bf, one or both of a wet etching method and a dry etching method can be used.

At the time of forming the semiconductor layer 108 and the semiconductor layer 108A, the thickness of the insulating layer 106 in a region overlapping with neither the semiconductor layer 108 nor the semiconductor layer 108A is sometimes smaller than the thickness of the insulating layer 106 in a region overlapping with the semiconductor layer 108 or the semiconductor layer 108A.

Heat treatment may be performed after the metal oxide film 108af and the metal oxide film 108bf are formed or processed into the semiconductor layer 108 and the semiconductor layer 108A. By the heat treatment, hydrogen or water can be removed from the surfaces and inside of the metal oxide films 108af and 108bf or the semiconductor layers 108 and 108A. In addition, by the heat treatment, the etching rate of the metal oxide films 108af and 108bf or the semiconductor layers 108 and 108A is lowered, which can inhibit the semiconductor layer 108 and the semiconductor layer 108A from being lost in a later step (e.g., the formation of the conductive layer 112a and the conductive layer 112b).

The heat treatment temperature is preferably higher than or equal to 150° C. and lower than the strain point of the substrate, further preferably higher than or equal to 250° C. and lower than or equal to 450° C., still further preferably higher than or equal to 300° C. and lower than or equal to 450° C. The heat treatment can be performed in an atmosphere containing one or more of a rare gas and nitrogen. Alternatively, heating may be performed in the atmosphere, and then heating may further be performed in an oxygen-containing atmosphere. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the semiconductor layers 108 and 108A can be prevented as much as possible. An oven, a rapid thermal annealing (RTA) apparatus, or the like can be used for the heat treatment. The use of the RTA apparatus can shorten the heat treatment time.

### [Formation of Conductive Layer 112a, Conductive Layer 112b, Conductive Layer 112Aa, and Conductive Layer 112Ab]

Next, a conductive film 113af, a conductive film 113bf, and a conductive film 113cf covering the insulating layer 106, the semiconductor layer 108, and the semiconductor layer 108A are formed to be stacked.

The conductive film 113bf is a film to be the conductive layer 113b later and preferably contains copper, silver, gold, or aluminum. The conductive film 113af and the conductive film 113cf are films to be the conductive layer 113a and the conductive layer 113b later, respectively, and each preferably independently contain one or more of titanium, tungsten, molybdenum, chromium, tantalum, zinc, indium, platinum, and ruthenium.

The conductive film 113af, the conductive film 113bf, and the conductive film 113cf are preferably formed by a formation method such as a sputtering method, an evaporation method, or a plating method.

Then, a resist 141 is applied to the conductive film 113cf (FIG. 13B). Here, the thickness of the resist 141 in the region not overlapping with the insulating layer 110 and the insulating layer 110A (over the groove 111) is larger than the thickness of the resist 141 over the insulating layer 110 or over the insulating layer 110A. A negative type resist material or a positive type resist material can be used as the resist 141. The negative type resist material can be suitably used as the resist 141. In this embodiment, an example in which the negative type resist material is used as the resist 141 is described.

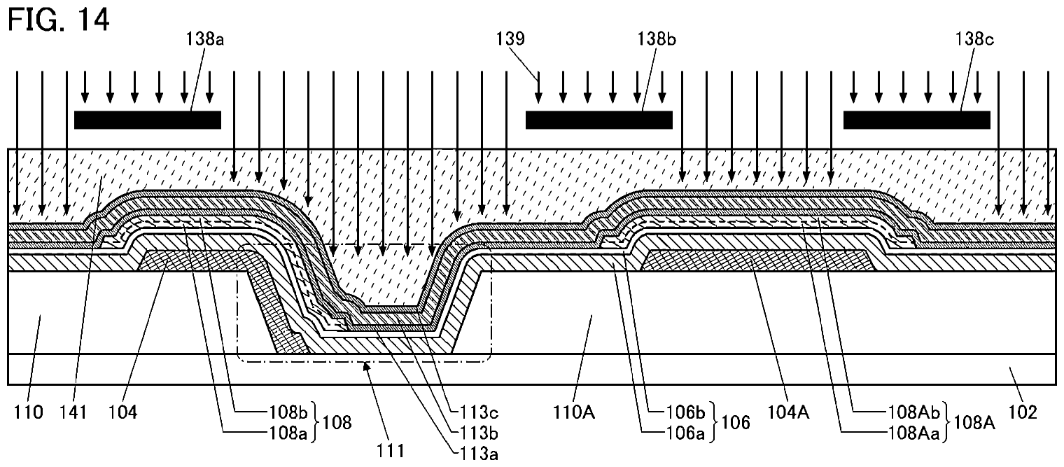

Next, the resist 141 is exposed to light through a photomask (FIG. 14). FIG. 14 illustrates a light-shielding portion 138a, a light-shielding portion 138b, and a light-shielding portion 138c included in the photomask. In addition, light 139 that enters the resist 141 through a mask, which is the light-shielding portion 138a, the light-shielding portion 138b, or the light-shielding portion 138c, is illustrated. The light-shielding portion 138a corresponds to a pattern of the conductive layer 112a, the light-shielding portion 138b corresponds to a pattern of the conductive layer 112Aa, and the light-shielding portion 138c corresponds to a pattern of the conductive layer 112Ab. Note that a light-shielding portion corresponding to the conductive layer 112b provided in the groove 111 is not provided.

Here, the resist 141 is shielded from light in a region overlapping with the light-shielding portion 138a, the light-shielding portion 138b, or the light-shielding portion 138c, so that a region which is not exposed to light (hereinafter also referred to as an unexposed region) is formed. In a region not overlapping with the light-shielding portion 138a, the light-shielding portion 138b, and the light-shielding portion 138c, not the whole of the resist 141 is exposed to light and an unexposed region is partly formed. Specifically, the light exposure time is adjusted such that the resist 141 in a region with a large thickness is exposed to light and the resist 141 in part of a region with a small thickness is not exposed to light; thus, an unexposed region is formed in the resist 141 in the groove 111.

The light exposure time is set such that the distance SP100 between the conductive layer 112a and the conductive layer 112b has a desired value. The thicknesses of the resist 141, the insulating layer 110, and the insulating layer 110A may be set as appropriate in consideration of the light exposure time.

Here, when the thicknesses of the insulating layer 110 and the insulating layer 110A are small, the thickness of the resist 141 over the groove 111 becomes small; thus, formation of an unexposed region in the groove 111 is difficult. Furthermore, it is difficult to separate an unexposed region formed by light shielding by the light-shielding portion 138a and the unexposed region formed in the groove 111. For example, the thickness of each of the insulating layer 110 and the insulating layer 110A is preferably greater than or equal to 200 nm and less than or equal to 3000 nm, further preferably greater than or equal to 400 nm and less than or equal to 2500 nm, further preferably greater than or equal to 600 nm and less than or equal to 2000 nm, further preferably greater than or equal to 800 nm and less than or equal to 1600 nm, further preferably greater than or equal to 800 nm and less than or equal to 1400 nm, further preferably greater than or equal to 800 nm and less than or equal to 1200 nm. With the thicknesses in the above range, the unexposed region apart from the unexposed region formed by light shielding by the light-shielding portion 138a can be formed in the groove 111. In addition, the tact in the formation process of the insulating film to be the insulating layer 110 and the insulating layer 110A can be prevented from becoming worse.

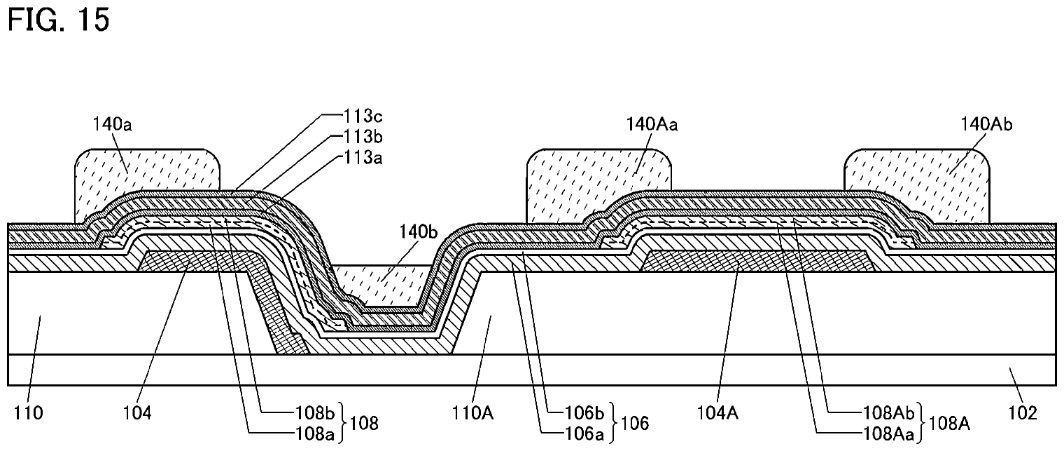

Next, development is performed with a developing solution to remove the resist 141 in the region exposed to light. As a result, a resist mask 140a, a resist mask 140b, a resist mask 140Aa, and a resist mask 140Ab can be formed in the unexposed region (FIG. 15).

Here, the resist mask 140a is formed by the light-shielding portion 138a of the photomask, the resist mask 140Aa is formed by the light-shielding portion 138b, and the resist mask 140Ab is formed by the light-shielding portion 138b. The resist mask 140b is formed without using the light-shielding portion of the photomask. In this manner, with use of the photomask in which the distance between the light-shielding portions is larger than the exposure limit of a light exposure apparatus, the resist mask 140a and the resist mask 140b whose distance is shorter than the exposure limit of a light exposure apparatus can be formed.

For convenience, FIG. 14 and FIG. 15 illustrate an example of 1:1 magnification exposure in which the light-shielding portion 138a, the light-shielding portion 138b, and the light-shielding portion 138c have the same size as the resist mask 140a, the resist mask 140Aa, and the resist mask 140Ab, respectively; however, one embodiment of the present invention is not limited to this. For the formation of the resist mask 140a, the resist mask 140Aa, and the resist mask 140Ab, reduction exposure may be employed. The resist mask 140a, the resist mask 140Aa, and the resist mask 140Ab may be formed by irradiating the resist with an electron beam or an ion beam without using a photomask. When a photomask is not used, the resist mask 140a, the resist mask 140Aa, and the resist mask 140Ab can be made fine.

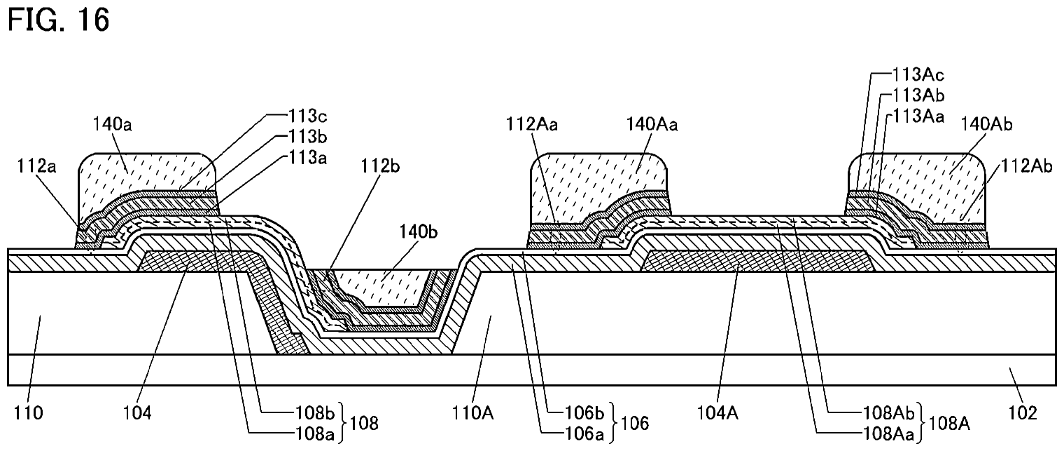

Next, the conductive film 113cf, the conductive film 113bf, and the conductive film 113af are processed using the resist mask 140a, the resist mask 140b, the resist mask 140Aa, and the resist mask 140Ab as a mask, so that the conductive layer 112a, the conductive layer 112b, the conductive layer 112Aa, and the conductive layer 112Ab each having a stacked structure of the conductive layer 113a, the conductive layer 113b, and the conductive layer 113c can be formed (FIG. 16). For the processing, one or both of a wet etching method and a dry etching method may be used. In particular, a dry etching method can be suitably used for microfabrication.

The conductive film 113cf, the conductive film 113bf, and the conductive film 113af can each be etched by wet etching, dry etching, or the like. The three layers can be etched at a time in one step, or each of the three layers may be sequentially etched in a different process.

The conductive layer 112a and the conductive layer 112b are preferably processed to be apart from each other over a channel formation region of the semiconductor layer 108, as illustrated in FIG. 16. In other words, the conductive layer 112a and the conductive layer 112b are preferably processed such that the end portions of them, which are opposite to each other, overlap with both the conductive layer 104 and the semiconductor layer 108. Accordingly, the on-state current of the transistor can be increased. Similarly, the conductive layer 112Aa and the conductive layer 112Ab are preferably processed such that the end portions of them, which are opposite to each other, overlap with both the conductive layer 104A and the semiconductor layer 108A.

At the time of forming the conductive layer 112a, the conductive layer 112b, the conductive layer 112Aa, and the conductive layer 112Ab, the thickness of the semiconductor layer 108 in a region overlapping with neither the conductive layer 112a nor the conductive layer 112b is sometimes smaller than the thickness of the semiconductor layer 108 in a region overlapping with the conductive layer 112a and the conductive layer 112b. Similarly, the thickness of the semiconductor layer 108A in the region overlapping with neither the conductive layer 112Aa nor the conductive layer 112Ab is sometimes smaller than the thickness of the semiconductor layer 108A in the region overlapping with the conductive layer 112Aa or the conductive layer 112Ab.

At the time of formation of the conductive layer 112a, the conductive layer 112b, the conductive layer 112Aa, and the conductive layer 112Ab, the thickness of the insulating layer 106 in a region not overlapping with the conductive layer 112a, the conductive layer 112b, the conductive layer 112Aa, and the conductive layer 112Ab is sometimes smaller than the thickness of the insulating layer 106 in a region overlapping with the conductive layer 112a, the conductive layer 112b, the conductive layer 112Aa, or the conductive layer 112Ab.

### [First Cleaning Treatment]

Next, cleaning treatment (hereinafter, referred to as first cleaning treatment) may be performed. Examples of the first cleaning treatment include wet cleaning using a cleaning solution or the like, plasma treatment using plasma, and cleaning by heat treatment, and any of these cleanings may be performed in combination as appropriate.

The surface of the semiconductor layer 108 might be damaged at the time of forming the conductive film 113cf, the conductive film 113bf, and the conductive film 113af and at the time of forming the conductive layer 112a and the conductive layer 112b. In some cases, V_{O} is formed in the damaged semiconductor layer 108 and hydrogen in the semiconductor layer 108 enters V_{O} to form V_{O}H. The damaged layer can be removed by performing the first cleaning treatment after the formation of the conductive layer 112a and the conductive layer 112b. By the first cleaning treatment, a metal, an organic substance, or the like attached to the surface of the semiconductor layer 108 at the time of forming the conductive layer 112a and the conductive layer 112b can be removed.

Wet cleaning can be suitably used as the first cleaning treatment. In the first cleaning treatment, for example, a cleaning solution containing at least one of phosphoric acid, oxalic acid, and hydrochloric acid is preferably used.

In the first cleaning treatment, a cleaning solution containing phosphoric acid can be particularly suitably used. The concentration of a cleaning solution is preferably determined in consideration of the etching rate of the semiconductor layer 108. In the case where a cleaning solution containing phosphoric acid is used in the first cleaning treatment, for example, the concentration of phosphoric acid is preferably higher than or equal to 0.01 weight % and lower than or equal to 5 weight %, further preferably higher than or equal to 0.02 weight % and lower than or equal to 4 weight %, still further preferably higher than or equal to 0.05 weight % and lower than or equal to 3 weight %, yet further preferably higher than or equal to 0.1 weight % and lower than or equal to 2 weight %, yet still further preferably higher than or equal to 0.15 weight % and lower than or equal to 1 weight %. With the concentration in the above range, the semiconductor layer 108 can be inhibited from being lost, and the damaged layer in the semiconductor layer 108 and a metal, an organic substance, or the like attached to the semiconductor layer 108 can be efficiently removed.

As illustrated in FIG. 16, the first cleaning treatment is preferably performed in a state where the top surfaces of the conductive layer 112a, the conductive layer 112b, the conductive layer 112Aa, and the conductive layer 112Ab are covered with the resist mask 140a, the resist mask 140b, the resist mask 140Aa, and the resist mask 140Ab, respectively. When the first cleaning treatment is performed in the state where the top surfaces of the conductive layer 112a, the conductive layer 112b, the conductive layer 112Aa, and the conductive layer 112Ab are covered with the resist mask, the conductive layer 113c can be inhibited from being lost, for example. In addition, when the first cleaning treatment is performed in the state where the top surfaces of the conductive layer 112a, the conductive layer 112b, the conductive layer 112Aa, and the conductive layer 112Ab are covered with the resist mask, the area of the conductive layer 112a, the conductive layer 112b, the conductive layer 112Aa, and the conductive layer 112Ab exposed at the time of the first cleaning treatment can be reduced, which can inhibit attachment of components of the conductive layer 112a, the conductive layer 112b, the conductive layer 112Aa, and the conductive layer 112Ab to the semiconductor layer 108 and the semiconductor layer 108A.

Then, the resist mask 140a, the resist mask 140b, the resist mask 140Aa, and the resist mask 140Ab are removed.

Note that the first cleaning treatment may be performed after the removal of the resist mask 140a, the resist mask 140b, the resist mask 140Aa, and the resist mask 140Ab.

### [Second Cleaning Treatment]

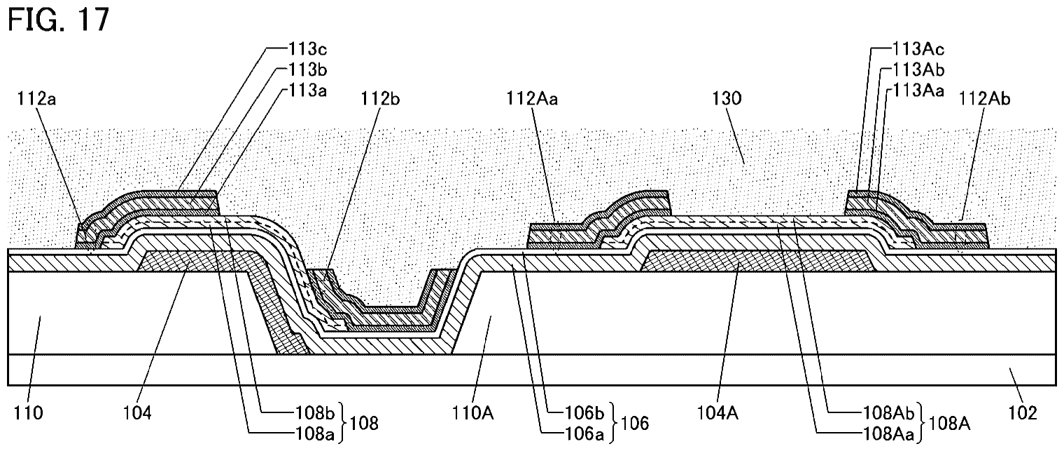

Next, cleaning treatment (hereinafter, referred to as second cleaning treatment) is preferably performed. Examples of the second cleaning treatment include wet cleaning using a cleaning solution or the like, plasma treatment using plasma (first plasma treatment), and cleaning by heat treatment, and any of these cleanings may be performed in combination as appropriate. As the second cleaning treatment, plasma treatment can be suitably used. FIG. 17 schematically illustrates a state in which the surfaces of the semiconductor layer 108, the semiconductor layer 108A, the conductive layer 112a, the conductive layer 112b, the conductive layer 112Aa, the conductive layer 112Ab, and the insulating layer 106 are exposed to plasma 130.

In the case where the first plasma treatment is performed as the second cleaning treatment, a mixed gas including an oxidizing gas and a reducing gas is particularly preferably used for the first plasma treatment. With the use of an oxidizing gas and a reducing gas for the first plasma treatment, oxidation of the conductive layer 112a and the conductive layer 112b can be inhibited and water, hydrogen, and an organic a component of an organic substance adsorbed on the surface of the semiconductor layer 108 can be effectively removed. As the oxidizing gas, the above-described gas can be used. As the reducing gas, the above-described gas can be used.

The flow rate ratio of the oxidizing gas to the reducing gas in the first plasma treatment can be set in accordance with how easily the conductive layer 113a, the conductive layer 113b, and the conductive layer 113c are oxidized, and the flow rate of the reducing gas is preferably at least lower than or equal to the flow rate of the oxidizing gas. When the flow rate of the reducing gas is much lower than the flow rate of the oxidizing gas, the oxidation reaction of the surface of the conductive layer 113b and the like becomes predominant, and an oxide is likely to be formed on the surface. By contrast, when the flow rate of the reducing gas is much higher than the flow rate of the oxidizing gas, the surface of the semiconductor layer 108 might be reduced, and the components of the reducing gas (e.g., hydrogen) might be supplied into the semiconductor layer 108.

In the first plasma treatment, the flow rate of the reducing gas with respect to the flow rate of the oxidizing gas is preferably within the above range. Although the surfaces of the conductive layer 113c, the conductive layer 113b, and the conductive layer 113a are also exposed to the plasma 130 in the first plasma treatment, the reducing gas included in the gas used for the first plasma treatment immediately reduces the surfaces even when the surfaces are oxidized; thus, the formation of an oxide is inhibited. This can effectively remove water, hydrogen, a component of an organic substance, or the like adsorbed on the surface of the semiconductor layer 108 while inhibiting oxidation of the conductive layer 113b even when a material that is easily oxidized, such as copper or aluminum, is used for the conductive layer 113b, for example.

Here, the case where the reducing gas is not included in the gas used for the first plasma treatment is described. In the case where the reducing gas is not included and the conductive layer 113b is exposed to plasma, an oxide might be formed in part of the conductive layer 113b. In the case where a material that is easily oxidized is used also for the conductive layer 113a or the conductive layer 113c, an oxide is formed also on their surfaces. The oxidation of at least one of the conductive layer 113a, the conductive layer 113b, and the conductive layer 113c increases resistance, which might adversely affect the electrical characteristics or reliability of the transistor. An oxide formed on the surface of the conductive layer 113a, the conductive layer 113b, or the conductive layer 113c might contaminate the surface of the semiconductor layer 108b when a portion thereof is scattered during the first plasma treatment or in the later formation of the insulating layer 114. An oxide attached to the semiconductor layer 108b can function as a donor or an acceptor, which might adversely affect the electrical characteristics and reliability of the transistor. In the case where a copper element diffuses into the semiconductor layer 108, for example, the copper element functions as a carrier trap and might degrade the electrical characteristics and reliability of the transistor.

By contrast, in the case where the reducing gas is included in the gas used for the first plasma treatment, even when the surfaces of the conductive layer 113c, the conductive layer 113b, and the conductive layer 113a, especially the side surface of the conductive layer 113b, are exposed, the oxidation of the surfaces can be inhibited. Thus, the oxidation of the conductive layer 112a and the conductive layer 112b can be inhibited and water, hydrogen, and a component of an organic substance adsorbed on the surface of the semiconductor layer 108 can be effectively removed, which allows the transistor to have high reliability.

The treatment time of the first plasma treatment is preferably adjusted. In the case where the treatment time of the first plasma treatment is long, the oxidation reaction due to the oxidizing gas proceeds, and the surfaces of the conductive layer 113a, the conductive layer 113b, and the conductive layer 113c might be oxidized. In addition, in the case where the treatment time of the first plasma treatment is long, the reduction reaction due to a second gas proceeds, and the surface of the semiconductor layer 108 might be reduced. Thus, the treatment time of the first plasma treatment is preferably adjusted such that the oxidation of the surfaces of the conductive layer 113a, the conductive layer 113b, and the conductive layer 113c and the reduction of the surface of the semiconductor layer 108 can be inhibited. The treatment time of the first plasma treatment is preferably longer than or equal to 5 sec and shorter than or equal to 180 sec, further preferably longer than or equal to 10 sec and shorter than or equal to 120 sec, still further preferably longer than or equal to 15 sec and shorter than or equal to 60 sec, for example. The treatment time in the above range enables the transistor to have favorable electrical characteristics and high reliability.

The pressure in a treatment chamber during the first plasma treatment is preferably higher than or equal to 50 Pa, further preferably higher than or equal to 100 Pa, still further preferably higher than or equal to 150 Pa, yet further preferably higher than or equal to 200 Pa, yet still further preferably higher than or equal to 250 Pa, yet still further preferably higher than or equal to 300 Pa. The pressure in the above range can reduce damage to the semiconductor layer 108. The upper limit of the pressure in the treatment chamber during the first plasma treatment is preferably set to pressure at which plasma is stably generated. For example, the pressure is preferably lower than or equal to 2000 Pa, further preferably lower than or equal to 1500 Pa, still further preferably lower than or equal to 1300 Pa, yet further preferably lower than or equal to 1000 Pa, yet still further preferably lower than or equal to 700 Pa, yet still further preferably lower than or equal to 500 Pa.

An oxygen-containing gas is preferably used for the first plasma treatment. With the use of an oxygen-containing gas, oxygen can be supplied to the semiconductor layer 108. Then, the oxygen can reduce oxygen vacancies (V_{O}) and V_{O}H in the semiconductor layer 108 (oxygen addition).

### [Formation of Insulating Layer 114]

Next, the insulating layer 114 is formed to cover the conductive layer 112a, the conductive layer 112b, the semiconductor layer 108, and the insulating layer 106.

The insulating layer 114 is preferably formed in, for example, an oxygen-containing atmosphere. It is particularly preferable that the insulating layer 114 be formed by a plasma CVD method in an oxygen-containing atmosphere. Thus, the insulating layer 114 with few defects can be formed. It is preferable that the amount of ammonia released from the insulating layer 114 be large and the amount of nitrogen oxide released from the insulating layer 114 be small. When the insulating layer 114 from which a large amount of ammonia is released and a small amount of nitrogen oxide is released is used, a change in the threshold voltage of the transistor can be inhibited, which can reduce a change in the electrical characteristics of the transistor.

As the insulating layer 114, for example, an oxide film such as a silicon oxide film or a silicon oxynitride film is preferably formed with a plasma-enhanced chemical vapor deposition apparatus (a PECVD apparatus or simply referred to as a plasma CVD apparatus). In that case, a mixed gas including a deposition gas containing silicon and an oxidizing gas is preferably used as a source gas. It is preferable that the source gas further contain ammonia. The insulating layer 114 formed using a mixed gas containing ammonia can be the insulating layer 114 from which a large amount of ammonia is released. As the deposition gas containing silicon, the above-described gas can be used. As the oxidizing gas, the above-described gas can be used.

In the case where silicon oxynitride is used for the insulating layer 114, for example, the insulating layer 114 can be formed using a mixed gas containing monosilane, dinitrogen monoxide, and ammonia.

In the formation of the insulating layer 114, the flow rate of the oxidizing gas with respect to the flow rate of the deposition gas is preferably within the above range. In addition, the flow rate of the ammonia gas with respect to the flow rate of the oxidizing gas is preferably within the above range. With the flow rates in the above ranges, the insulating layer 114 from which a large amount of ammonia is released can be obtained. Since the amount of nitrogen oxide released from the insulating layer 114 is reduced, a transistor with a small change in the threshold voltage can be obtained. In addition, with the above-described flow rates of the gases, the insulating layer 114 with few defects can be formed even when the pressure in the treatment chamber is relatively high.

The pressure in the treatment chamber at the time of forming the insulating layer 114 is preferably within the above range. With the pressure in the above range, the insulating layer 114 from which a small amount of nitrogen oxide is released and in which the amount of defects is small can be formed.

The substrate temperature at the time of forming the insulating layer 114 is preferably higher than or equal to 150° C. and lower than or equal to 400° C., further preferably higher than or equal to 160° C. and lower than or equal to 350° C., still further preferably higher than or equal to 180° C. and lower than or equal to 300° C., yet still further preferably higher than or equal to 200° C. and lower than or equal to 250° C. With the substrate temperature in the above range, damage to the semiconductor layer 108, which is the formation surface, can be reduced.

The insulating layer 114 may be formed by a PECVD method using a microwave. A microwave refers to a wave in the frequency range of 300 MHz to 300 GHz. In a microwave, electron temperature and electron energy are low. Furthermore, in supplied power, the proportion of power used for acceleration of electrons is low, and power can be used for dissociation and ionization of more molecules; thus, plasma with a high density (high-density plasma) can be excited. Thus, little plasma damage to the formation surface and a deposit is caused, so that the insulating layer 114 with few defects can be formed.

After the first plasma treatment is performed, the formation of the insulating layer 114 is preferably performed successively without exposure of the surface of the semiconductor layer 108 to the air. The first plasma treatment is preferably performed in the deposition apparatus for the insulating layer 114, for example. In that case, the first plasma treatment is preferably performed in the treatment chamber where the insulating layer 114 is formed. Alternatively, a structure may be employed in which the first plasma treatment is performed in a treatment chamber connected to the above treatment chamber via a gate valve or the like and then transportation to the treatment chamber for the insulating layer 114 is performed without exposure to the air and under reduced pressure. In the case where the first plasma treatment and the formation of the insulating layer 114 are successively performed in the same treatment chamber of the same apparatus, the first plasma treatment and the formation of the insulating layer 114 are preferably performed at the same temperature.

A case where the first plasma treatment and the formation of the insulating layer 114 are performed using a plasma-enhanced chemical vapor deposition apparatus will be described as an example. Here, the insulating layer 114 is silicon oxynitride.

In the first plasma treatment, a mixed gas including an oxidizing gas of dinitrogen monoxide (N₂O) and a reducing gas of ammonia can be used, and in the formation of the insulating layer 114, a mixed gas including a deposition gas of monosilane, an oxidizing gas of dinitrogen monoxide (N₂O), and ammonia can be used. Here, in the first plasma treatment and the formation of the insulating layer 114, dinitrogen monoxide (N₂O) and ammonia can be used in common. That is, the first plasma treatment is performed using dinitrogen monoxide (N₂O) and ammonia; and then, a monosilane gas is supplied, whereby the insulating layer 114 can be formed. Since the first plasma treatment and the formation of the insulating layer 114 can be performed successively in the same treatment chamber in this manner, impurities at the interface between the semiconductor layer 108 and the insulating layer 114 can be reduced; thus, the interface can be favorable.

After the formation of the insulating layer 114, treatment for supplying oxygen to the insulating layer 114 may be performed. As the treatment for supplying oxygen, a method similar to that for the insulating layer 106 can be used.

### [Formation of Insulating Layer 116]

Next, the insulating layer 116 is formed to cover the insulating layer 114.

For the insulating layer 116, an insulating film that is less likely to diffuse oxygen, hydrogen, and water than the insulating layer 114 is preferably used. With the insulating layer 116 that is less likely to diffuse oxygen, oxygen in the semiconductor layer 108 can be prevented from being released to the outside through the insulating layer 114. Furthermore, with the insulating layer 116 that is less likely to diffuse hydrogen, hydrogen, water, and the like can be prevented from diffusing to the semiconductor layer 108 or the like from the outside.

The substrate temperature at the time of forming the insulating layer 116 is preferably higher than or equal to 150° C. and lower than or equal to 400° C., further preferably higher than or equal to 160° C. and lower than or equal to 350° C., still further preferably higher than or equal to 180° C. and lower than or equal to 300° C., yet still further preferably higher than or equal to 200° C. and lower than or equal to 250° C. With the substrate temperature in the above range, an insulating film that is less likely to diffuse oxygen, hydrogen, and water can be obtained.

After the formation of the insulating layer 116, treatment for supplying oxygen to the insulating layer 116 may be performed. As the treatment for supplying oxygen, a method similar to that for the insulating layer 106 can be used.

In the case where an oxide film is used for the insulating layer 116, after the formation of the insulating layer 116, plasma treatment may be performed on the surface of the insulating layer 116 in an atmosphere containing nitrogen. By the plasma treatment in an atmosphere containing nitrogen, the surface of the insulating layer 116 or the vicinity thereof is nitrided, which can prevent impurities such as water from being adsorbed onto the surface of the insulating layer 116. In the case where impurities such as water are adsorbed on the surface of the insulating layer 116, the impurities may reach the semiconductor layer 108, and oxygen vacancies (V_{O}), V_{O}H, or the like might be formed in the semiconductor layer 108. When impurities such as water are inhibited from being adsorbed on the surface of the insulating layer 116, the transistor can have high reliability. The plasma treatment is particularly suitable in the case where the surface of the insulating layer 116 is exposed to the air after the formation of the insulating layer 116 before the formation of the insulating layer 118.

After the insulating layer 116 is formed, heat treatment is preferably performed. By the heat treatment, oxygen contained in the insulating layer 114 and the insulating layer 116 is diffused into the semiconductor layer 108, and the oxygen can reduce oxygen vacancies (V_{O}) and V_{O}H in the semiconductor layer 108 (oxygen addition). Specifically, oxygen diffusing into the semiconductor layer 108 fills oxygen vacancies (V_{O}). Oxygen diffusing into the semiconductor layer 108 deprives V_{O}H of hydrogen to be released as a water molecule (H₂O), and V_{O}H that is deprived of hydrogen becomes oxygen vacancies (V_{O}). Furthermore, the oxygen vacancies (V_{O}) generated by depriving V_{O}H of hydrogen are filled with another oxygen reaching the semiconductor layer 108. Reductions in the oxygen vacancies (V_{O}) and V_{O}H in the semiconductor layer 108 result in a highly reliable transistor.

Oxygen diffusing into the semiconductor layer 108 reacts with hydrogen remaining in the semiconductor layer 108 to be released as a water molecule (H₂O). That is, hydrogen can be removed from the semiconductor layer 108 (dehydration or dehydrogenation). This can inhibit generation of V_{O}H caused by bonding of hydrogen remaining in the semiconductor layer 108 to the oxygen vacancies (V_{O}).

The heat treatment can remove hydrogen and water contained in the insulating layer 116 and the insulating layer 114. In addition, the heat treatment can reduce defects contained in the insulating layer 116 and the insulating layer 114.

Moreover, by the heat treatment, nitrogen oxide contained in the insulating layer 114 and the insulating layer 116 reacts with ammonia contained in the insulating layer 114, so that the amount of nitrogen oxide contained in the insulating layer 114 and the insulating layer 116 is reduced. A reduction in the amount of nitrogen oxide can inhibit a change in the threshold voltage of the transistor, which can reduce a change in the electrical characteristics of the transistor. The above description can be referred to for the heat treatment; thus, the detailed description thereof is omitted.

The heat treatment temperature is preferably higher than or equal to 150° C. and lower than the strain point of the substrate, further preferably higher than or equal to 250° C. and lower than or equal to 450° C., still further preferably higher than or equal to 300° C. and lower than or equal to 450° C. The heat treatment can be performed in an atmosphere containing one or more of a rare gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating layer 116 can be prevented as much as possible. An oven, a rapid thermal annealing (RTA) apparatus, or the like can be used for the heat treatment. The use of the RTA apparatus can shorten the heat treatment time.

### [Formation of Insulating Layer 118]

Next, the insulating layer 118 is formed to cover the insulating layer 116 (FIG. 7).

As the insulating layer 118, an insulating film that is less likely to diffuse oxygen, hydrogen, and water than the insulating layer 114 and the insulating layer 116 is preferably used. The insulating layer 118 that is less likely to diffuse oxygen can inhibit release of oxygen in the insulating layer 116, the insulating layer 114, and the semiconductor layer 108 to the outside. Furthermore, the insulating layer 118 that is less likely to diffuse hydrogen can inhibit diffusion of hydrogen and water to the semiconductor layer 108 or the like from the outside. It is particularly suitable to use silicon nitride for the insulating layer 118.

Through the above steps, the semiconductor device 10 can be fabricated.

### Fabrication Method Example 2

A fabrication method of the semiconductor device 10 that is different from the fabrication method in <Fabrication method example 1> shown above will be described. Note that description of the same portions as the above is omitted and different portions will be described.

First, as in <Fabrication method example 1>, the steps up to the formation of the insulating layer 116 are performed. The above description can be referred to for the steps up to the formation of the insulating layer 116; thus, the detailed description thereof is omitted. After the formation of the insulating layer 116, heat treatment is preferably performed. The above description in <Fabrication method example 1> can be referred to for the heat treatment; thus, the detailed description thereof is omitted.

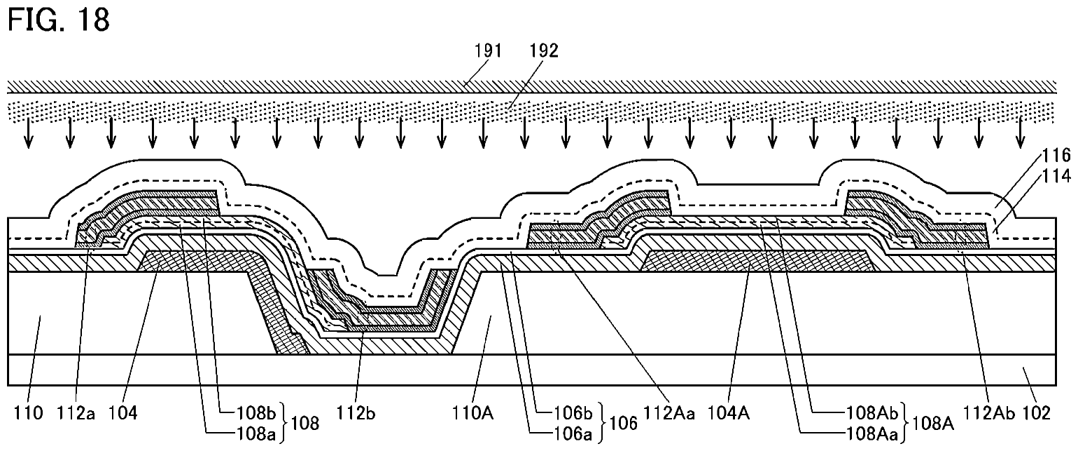

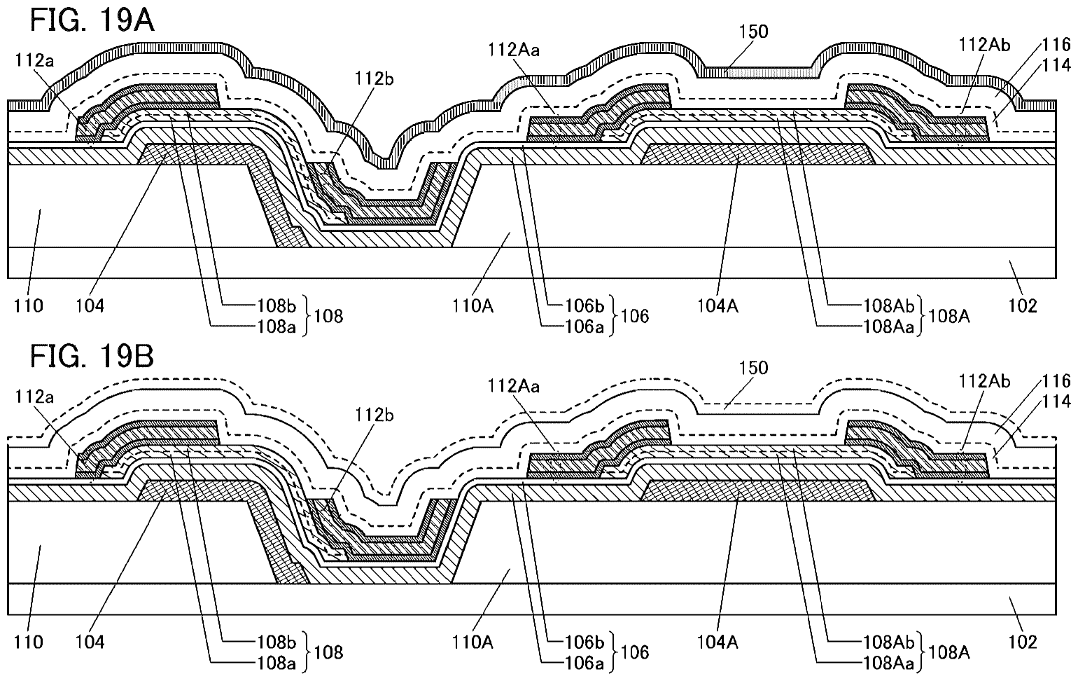

Next, a metal oxide layer 150 is formed to cover the insulating layer 116 (FIG. 18 and FIG. 19A).

The metal oxide layer 150 is preferably formed by a sputtering method using a metal oxide target. In forming the metal oxide layer 150, an oxygen gas is preferably used. FIG. 18 is a schematic cross-sectional view of the inside of a sputtering apparatus at the time of forming the metal oxide layer 150 over the insulating layer 116. A target 191 placed inside the sputtering apparatus and plasma 192 formed under the target 191 are schematically illustrated. For example, in the case of using an oxygen gas at the time of forming the metal oxide layer 150, oxygen can be favorably supplied to the insulating layer 116. Note that oxygen supplied to the insulating layer 116 is represented by arrows in FIG. 18.

The metal oxide layer 150 is formed using a material that does not easily transmit oxygen and hydrogen. The metal oxide layer 150 has a function of inhibiting diffusion of oxygen contained in the insulating layer 114 and the insulating layer 116 to the side opposite to the semiconductor layer 108. In addition, the metal oxide layer 150 has a function of inhibiting diffusion of hydrogen and water from the outside to the side of the insulating layer 114 and the insulating layer 116. The metal oxide layer 150 is preferably formed using a material that is less likely to transmit oxygen and hydrogen than at least the insulating layer 114 and the insulating layer 116.

The metal oxide layer 150 may be an insulating layer or a conductive layer.

The metal oxide layer 150 is preferably formed using an insulating material with a higher dielectric constant than silicon oxide. For example, an aluminum oxide film, a hafnium oxide film, a hafnium aluminate film, or the like can be used.

For the metal oxide layer 150, for example, a conductive oxide such as indium oxide, indium tin oxide (ITO), or indium tin oxide containing silicon (ITSO) can also be used.

For the metal oxide layer 150, an oxide material containing one or more elements that are the same as those of the semiconductor layer 108 is preferably used. It is particularly preferable to use an oxide semiconductor material that can be used for the semiconductor layer 108. In a sputtering target used for forming the metal oxide layer 150, the atomic proportion of In is preferably greater than or equal to the atomic proportion of the element M. Examples of the atomic ratio of the metal elements in such a sputtering target include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, In:M:Zn=10:1:3, In:M:Zn=10:1:6, and In:M:Zn=10:1:8.

In particular, an In—Ga—Zn oxide (IGZO) where the element M is Ga can be suitably used as the metal oxide layer 150. In the case where the semiconductor layer 108 is an In—Ga—Zn oxide, a sputtering target used for forming the In—Ga—Zn oxide preferably has the atomic proportion of In higher than or equal to the atomic proportion of the element Ga. Examples of the atomic ratio of the metal elements in such a sputtering target include In:Ga:Zn=1:1:1, In:Ga:Zn=1:1:1.2, In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=5:2:5, In:Ga:Zn=10:1:3, In:Ga:Zn=10:1:6, and In:Ga:Zn=10:1:8.

A metal oxide film formed using a sputtering target having the same composition as the semiconductor layer 108 can be used as the metal oxide layer 150. The sputtering target having the same composition as the semiconductor layer 108 is preferably used, in which case the same manufacturing apparatus and the same sputtering target can be used.

When a metal oxide material containing indium and gallium is used for both the semiconductor layer 108 and the metal oxide layer 150, a material whose composition (content ratio) of gallium is higher than that in the semiconductor layer 108 can be used for the metal oxide layer 150. It is preferable to use a material whose composition (content ratio) of gallium is high for the metal oxide layer 150, in which case an oxygen blocking property can be further increased. In that case, the use of a material whose composition of indium is higher than that in the metal oxide layer 150 for the semiconductor layer 108 enables the field-effect mobility of the transistor 100 to be increased.

The metal oxide layer 150 is preferably formed using a sputtering apparatus. For example, in the case where an oxide film is formed using a sputtering apparatus, forming the oxide film in an atmosphere containing an oxygen gas can suitably supply oxygen into the insulating layer 116, the insulating layer 114, or the semiconductor layer 108.

The metal oxide layer 150 is preferably formed in, for example, an oxygen-containing atmosphere. It is particularly preferable to form the metal oxide layer 150 by a sputtering method in an oxygen-containing atmosphere. Thus, oxygen can be supplied to the insulating layer 116, the insulating layer 114, or the semiconductor layer 108 at the time of forming the metal oxide layer 150.

In the case where the metal oxide layer 150 is formed by a sputtering method using an oxide target containing a metal oxide similar to that in the case of the semiconductor layer 108, reference can be made to the above description.

For example, the metal oxide layer 150 may be formed by a reactive sputtering method using oxygen as a deposition gas and a metal target. When aluminum is used for the metal target, for instance, an aluminum oxide film can be formed.

At the time of forming the metal oxide layer 150, the amount of oxygen supplied into the insulating layer 116 can be increased with a higher proportion of the oxygen flow rate to the total flow rate of the deposition gas introduced into a treatment chamber of a deposition apparatus (a higher oxygen flow rate ratio) or with a higher oxygen partial pressure in the treatment chamber. The oxygen flow rate ratio or the oxygen partial pressure is, for example, higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferred that the oxygen flow rate ratio be 100% and the oxygen partial pressure be as close to 100% as possible.

When the metal oxide layer 150 is formed by a sputtering method in an oxygen-containing atmosphere in the above manner, oxygen can be supplied to the insulating layer 116 and release of oxygen from the insulating layer 116 can be prevented during the formation of the metal oxide layer 150. As a result, an extremely large amount of oxygen can be enclosed in the insulating layer 116. Moreover, a large amount of oxygen can be supplied to the semiconductor layer 108 by heat treatment performed later. Thus, the oxygen vacancies in the semiconductor layer 108 can be reduced, leading to a highly reliable transistor.

Next, heat treatment is preferably performed to supply oxygen from the insulating layer 116 to the semiconductor layer 108. The heat treatment can be performed at a temperature higher than or equal to 200° C. and lower than or equal to 400° C. in an atmosphere containing one or more of nitrogen, oxygen, and a rare gas.

By the heat treatment performed after the formation of the metal oxide layer 150, oxygen can be effectively supplied from the metal oxide layer 150 to the semiconductor layer 108.

Next, the metal oxide layer 150 is removed (FIG. 19B). Note that the steps after removal of the metal oxide layer 150 are each preferably performed at a temperature lower than or equal to the temperature of the above heat treatment. In this manner, release of oxygen in the semiconductor layer 108 can be inhibited, which can inhibit formation of oxygen vacancies in the semiconductor layer 108. As a result, the reliability of the transistor can be increased.

There is no particular limitation on a method for removing the metal oxide layer 150, and wet etching can be suitably used. With the use of wet etching, the insulating layer 116 can be inhibited from being etched at the same time as the metal oxide layer 150. This can inhibit a reduction in the thickness of the insulating layer 116 and the thickness of the insulating layer 116 can be uniform.

Next, the insulating layer 118 is formed (FIG. 7). The above description in <Fabrication method example 1> can be referred to for the formation of the insulating layer 118; thus, the detailed description thereof is omitted.

Through the above steps, the semiconductor device 10 can be fabricated.

### Fabrication Method Example 3

A method for fabricating the semiconductor device 10A illustrated in FIG. 9 will be described below. Note that description of the same portions as the above is omitted and different portions will be described.

First, steps up to the formation of the insulating layer 118 are formed in a manner similar to that in the fabrication method example 1 or the fabrication method example 2. The above description can be referred to for the steps before the formation of the insulating layer 118; thus, the detailed description thereof is omitted.

[Formation of Conductive Layer 120, Conductive Layer 120a, and Conductive Layer 120b]

Then, parts of the insulating layer 114, the insulating layer 116, and the insulating layer 118 are etched to form an opening reaching the conductive layer 112Ab. Note that in the case where the conductive layer 120 and the conductive layer 104 are connected, an opening reaching the conductive layer 104 is formed by etching parts of the insulating layer 106, the insulating layer 114, the insulating layer 116, and the insulating layer 118. Similarly, in the case where the conductive layer 120a and the conductive layer 104A are connected, an opening reaching the conductive layer 104A is formed by etching parts of the insulating layer 106, the insulating layer 114, the insulating layer 116, and the insulating layer 118.

Subsequently, a conductive film was formed to cover the opening, and then was processed to form the conductive layer 120, the conductive layer 120a, and the conductive layer 120b (FIG. 9).

Through the above steps, the semiconductor device 10A can be fabricated.

### Fabrication Method Example 4

A method for fabricating the semiconductor device 10B illustrated in FIG. 10 will be described below. Note that description of the same portions as the above is omitted and different portions will be described.

First, steps up to the formation of the insulating layer 116 are formed in a manner similar to that in the fabrication method example 1 or the fabrication method example 2. The above description can be referred to for the steps before the formation of the insulating layer 116; thus, the detailed description thereof is omitted.

[Formation of Conductive Layer 120, Conductive Layer 120a, and Conductive Layer 120b]

Then, parts of the insulating layer 114 and the insulating layer 116 are etched to form an opening reaching the conductive layer 112Ab. Note that in the case where the conductive layer 120 and the conductive layer 104 are connected, an opening reaching the conductive layer 104 is formed by etching parts of the insulating layer 106, the insulating layer 114, and the insulating layer 116. Similarly, in the case where the conductive layer 120a and the conductive layer 104A are connected, an opening reaching the conductive layer 104A is formed by etching parts of the insulating layer 106, the insulating layer 114, and the insulating layer 116.

Subsequently, a conductive film was formed to cover the opening, and then was processed to form the conductive layer 120, the conductive layer 120a, and the conductive layer 120b.

### [Formation of Insulating Layer 118]

Next, the insulating layer 118 is formed (FIG. 10). The above description in <Fabrication method example 1> can be referred to for the formation of the insulating layer 118; thus, the detailed description thereof is omitted.

Through the above steps, the semiconductor device 10B can be fabricated.

### <Components of Semiconductor Device>

Components included in the semiconductor device of this embodiment will be described below in detail.

### [Substrate]

Although there is no particular limitation on a material and the like of the substrate 102, it is necessary that the substrate have heat resistance high enough to withstand at least heat treatment performed later. For example, a single crystal semiconductor substrate or a polycrystalline semiconductor substrate using silicon or silicon carbide as a material, a compound semiconductor substrate of silicon germanium or the like, an SOI substrate, a glass substrate, a ceramic substrate, a quartz substrate, a sapphire substrate, or the like may be used as the substrate 102. Alternatively, any of these substrates over which a semiconductor element is provided may be used as the substrate 102.

A flexible substrate may be used as the substrate 102, and the transistor 100 and the like may be formed directly on the flexible substrate. Alternatively, a separation layer may be provided between the substrate 102 and the transistor 100 and the like. The separation layer can be used when part or the whole of a semiconductor device completed thereover is separated from the substrate 102 and transferred onto another substrate. In that case, the transistor 100 and the like can be transferred onto a substrate having low heat resistance or a flexible substrate as well.

### [Insulating Layer 106]

The insulating layer 106 can be formed of a single layer or a stacked layer of an oxide insulating film or a nitride insulating film, for example. To improve the properties of the interface with the semiconductor layer 108, at least a region in the insulating layer 106 that is in contact with the semiconductor layer 108 is preferably formed of an oxide insulating film. Moreover, a film from which oxygen is released by heating is preferably used as the insulating layer 106.

For example, a single layer or a stacked layer using silicon oxide, silicon oxynitride, silicon nitride oxide, silicon nitride, aluminum oxide, hafnium oxide, gallium oxide, a Ga—Zn oxide, or the like can be provided as the insulating layer 106.

In the case where a film other than an oxide film, such as a silicon nitride film, is used for the side of the insulating layer 106 that is in contact with the semiconductor layer 108, pretreatment such as oxygen plasma treatment is preferably performed on a surface in contact with the semiconductor layer 108 to oxidize the surface or the vicinity of the surface.

### [Conductive Film]

Conductive films that constitute the semiconductor device, such as the conductive layer 104 and the conductive layer 104A each functioning as a gate electrode, the conductive layer 120, the conductive layer 120a, the conductive layer 120b functioning as a wiring, the conductive layer 112a, the conductive layer 112b, the conductive layer 112Aa, and the conductive layer 112Ab each functioning as a source electrode or a drain electrode, can each be formed using a metal selected from chromium, copper, aluminum, gold, silver, zinc, molybdenum, tantalum, titanium, tungsten, manganese, nickel, iron, cobalt, molybdenum, and niobium; an alloy containing one or more of the metals as its component; an alloy including a combination of any of the metals; or the like.

For the conductive layer 112a, the conductive layer 112b, the conductive layer 112Aa, and the conductive layer 112Ab that function as a source electrode or a drain electrode, in particular, a low-resistance conductive material containing one or more of copper, silver, gold, and aluminum is preferably used. Copper or aluminum is particularly preferable because of its high mass-productivity.

For the conductive films that constitute the semiconductor device, an oxide conductor or a metal oxide film such as an In—Sn oxide, an In—W oxide, an In—W—Zn oxide, an In—Ti oxide, an In—Ti—Sn oxide, an In—Zn oxide, an In—Sn—Si oxide, or an In—Ga—Zn oxide can also be used.

Here, an oxide conductor (OC) is described. For example, when oxygen vacancies are formed in a metal oxide having semiconductor characteristics and hydrogen is added to the oxygen vacancies, a donor level is formed in the vicinity of the conduction band. As a result, the conductivity of the metal oxide is increased, so that the metal oxide becomes a conductor. The metal oxide having become a conductor can be referred to as an oxide conductor.

The conductive films that constitute the semiconductor device may each have a stacked-layer structure of a conductive film containing the above-described oxide conductor (metal oxide) and a conductive film containing a metal or an alloy. The use of the conductive film containing a metal or an alloy can reduce the wiring resistance. At this time, a conductive film containing an oxide conductor is preferably used as the conductive film on the side in contact with the insulating layer functioning as a gate insulating layer.

A Cu—X alloy film (X is Mn, Ni, Cr, Fe, Co, Mo, Ta, or Ti) may be used for the conductive layer 104, the conductive layer 112a, and the conductive layer 112b. The use of a Cu—X alloy film enables the manufacturing cost to be reduced because wet etching process can be used in the processing.

The description of the conductive layer 104 can be referred to for the conductive layer 104A; thus, the detailed description thereof is omitted. The description of the conductive layer 112a and the conductive layer 112b can be referred to for the conductive layer 112Aa and the conductive layer 112Ab; thus, the detailed description thereof is omitted.

### [Insulating Layer 110, Insulating Layer 110A, Insulating Layer 114, and Insulating Layer 116]

For the insulating layer 110, one or more of inorganic insulating materials such as a silicon oxide film, a silicon oxynitride film, an aluminum oxide film, a hafnium oxide film, a yttrium oxide film, a zirconium oxide film, a gallium oxide film, a tantalum oxide film, a magnesium oxide film, a lanthanum oxide film, a cerium oxide film, a neodymium oxide film, silicon nitride, silicon nitride oxide, silicon oxide, silicon oxynitride, aluminum oxide, and aluminum nitride formed by a PECVD method, a sputtering method, an ALD method, or the like can be used. It is particularly preferable to use a silicon oxide film or a silicon oxynitride film formed by a plasma CVD method. Note that the insulating layer 110 may have a stacked structure of two or more layers.

The description of the insulating layer 110 can be referred to for the insulating layer 110A; thus, the detailed description thereof is omitted.

As the insulating layer 114 provided over the semiconductor layer 108, an insulating layer including one or more kinds of a silicon oxide film, a silicon oxynitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, and the like formed by a PECVD method, a sputtering method, an ALD method, or the like can be used. It is particularly preferable to use a silicon oxide film or a silicon oxynitride film formed by a plasma CVD method. Note that the insulating layer 114 may have a stacked structure of two or more layers.

As the insulating layer 116 functioning as a protective layer, an insulating layer containing one or more kinds of a silicon nitride oxide film, a silicon nitride film, an aluminum nitride film, an aluminum nitride oxide film, and the like formed by a PECVD method, a sputtering method, an ALD method, or the like can be used. Note that the insulating layer 116 may have a stacked-layer structure of two or more layers.

### [Semiconductor Layer 108 and Semiconductor Layer 108A]

In the case where an In-M-Zn oxide is used for the semiconductor layer 108, a sputtering target used for forming the In-M-Zn oxide preferably has an atomic ratio in which the proportion of In is higher than or equal to the proportion of the element M. Examples of the atomic ratio of the metal elements in such a sputtering target include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, In:M:Zn=10:1:3, In:M:Zn=10:1:6, and In:M:Zn=10:1:8.

In particular, an In—Ga—Zn oxide (IGZO) where the element M is Ga can be suitably used as the semiconductor layer 108. In the case where the semiconductor layer 108 is an In—Ga—Zn oxide, a sputtering target used for forming the In—Ga—Zn oxide preferably has the atomic proportion of In higher than or equal to the atomic proportion of the element Ga. Examples of the atomic ratio of the metal elements in such a sputtering target include In:Ga:Zn=1:1:1, In:Ga:Zn=1:1:1.2, In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=5:2:5, In:Ga:Zn=10:1:3, In:Ga:Zn=10:1:6, and In:Ga:Zn=10:1:8.

A target containing a polycrystalline oxide is preferably used as the sputtering target, which facilitates formation of the semiconductor layer 108 having crystallinity. Note that the atomic ratio in the semiconductor layer 108 to be formed may vary in the range of ±40% from any of the above atomic ratios of the metal elements contained in the sputtering target. For example, in the case where the composition (atomic ratio) of a sputtering target used for the semiconductor layer 108 is In:Ga:Zn=4:2:4.1, the composition (atomic ratio) of the formed semiconductor layer 108 is sometimes In:Ga:Zn=4:2:3 or in the neighborhood thereof.

Note that when the atomic ratio is described as In:Ga:Zn=4:2:3 or in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. When the atomic ratio is described as In:Ga:Zn=5:1:6 or in the neighborhood thereof, the case is included where the atomic proportion of Ga is greater than 0.1 and less than or equal to 2 and the atomic proportion of Zn is greater than or equal to 5 and less than or equal to 7 with the atomic proportion of In being 5. When the atomic ratio is described as In:Ga:Zn=1:1:1 or in the neighborhood thereof, the case is included where the atomic proportion of Ga is greater than 0.1 and less than or equal to 2 and the atomic proportion of Zn is greater than 0.1 and less than or equal to 2 with the atomic proportion of In being 1.

The energy gap of the semiconductor layer 108 is 2 eV or more, preferably 2.5 eV or more. With the use of such a metal oxide having a wider energy gap than silicon, the off-state current of the transistor can be reduced.

The semiconductor layer 108 preferably has a non-single-crystal structure. The non-single-crystal structure includes, for example, a CAAC structure which will be described later, a polycrystalline structure, a microcrystalline structure, and an amorphous structure. Among the non-single-crystal structures, the amorphous structure has the highest density of defect states, whereas the CAAC structure has the lowest density of defect states.

The description of the semiconductor layer 108 can be referred to for the semiconductor layer 108A; thus, the detailed description thereof is omitted.

A CAAC (c-axis aligned crystal) will be described below. A CAAC refers to an example of a crystal structure.

The CAAC structure is a crystal structure of a thin film or the like that has a plurality of nanocrystals (crystal regions having a maximum diameter of less than 10 nm), characterized in that the nanocrystals have c-axis alignment in a particular direction and are not aligned but continuously connected in the a-axis and b-axis directions without forming a grain boundary. In particular, a thin film having the CAAC structure is characterized in that the c-axes of nanocrystals are likely to be aligned in the film thickness direction, the normal direction of the surface where the thin film is formed, or the normal direction of the surface of the thin film.

A CAAC-OS (Oxide Semiconductor) is an oxide semiconductor with high crystallinity. Meanwhile, a clear crystal grain boundary cannot be observed in the CAAC-OS; thus, it can be said that a reduction in electron mobility due to the crystal grain boundary is less likely to occur. Moreover, since the crystallinity of an oxide semiconductor might be decreased by entry of impurities, formation of defects, or the like, the CAAC-OS can be regarded as an oxide semiconductor that has small amounts of impurities and defects (oxygen vacancies or the like). Thus, an oxide semiconductor including a CAAC-OS is physically stable. Therefore, the oxide semiconductor including a CAAC-OS is resistant to heat and has high reliability.

Here, in crystallography, in a unit cell formed with three axes (crystal axes) of the a-axis, the b-axis, and the c-axis, a specific axis is generally taken as the c-axis in the unit cell. In particular, in the case of a crystal having a layered structure, two axes parallel to the plane direction of a layer are regarded as the a-axis and the b-axis and an axis intersecting with the layer is regarded as the c-axis in general. A typical example of such a crystal having a layered structure is graphite, which is classified as a hexagonal system. In a unit cell of graphite, the a-axis and the b-axis are parallel to the cleavage plane and the c-axis is orthogonal to the cleavage plane. For example, an InGaZnO₄ crystal having a YbFe₂O₄ type crystal structure which is a layered structure can be classified as a hexagonal system, and in a unit cell thereof, the a-axis and the b-axis are parallel to the plane direction of the layer and the c-axis is orthogonal to the layer (i.e., the a-axis and the b-axis).

An example of a crystal structure of a metal oxide is described. Note that a metal oxide formed by a sputtering method using an In—Ga—Zn oxide target (In:Ga:Zn=4:2:4.1<atomic ratio>) is described here as an example. A metal oxide that is formed by a sputtering method using the above target at a substrate temperature higher than or equal to 100° C. and lower than or equal to 130° C. is likely to have either the nc (nano crystal) structure or the CAAC structure, or a structure in which both structures are mixed. By contrast, a metal oxide formed by a sputtering method at a substrate temperature set at room temperature is likely to have the nc structure. Note that room temperature here also includes a temperature in the case where a substrate is not heated.

The above is the description of the components.

At least part of this embodiment can be implemented in combination with any of the other embodiments described in this specification as appropriate.

### Embodiment 2

In this embodiment, an example of a display device that includes the transistor exemplified in the above embodiment will be described.

### Structure Example

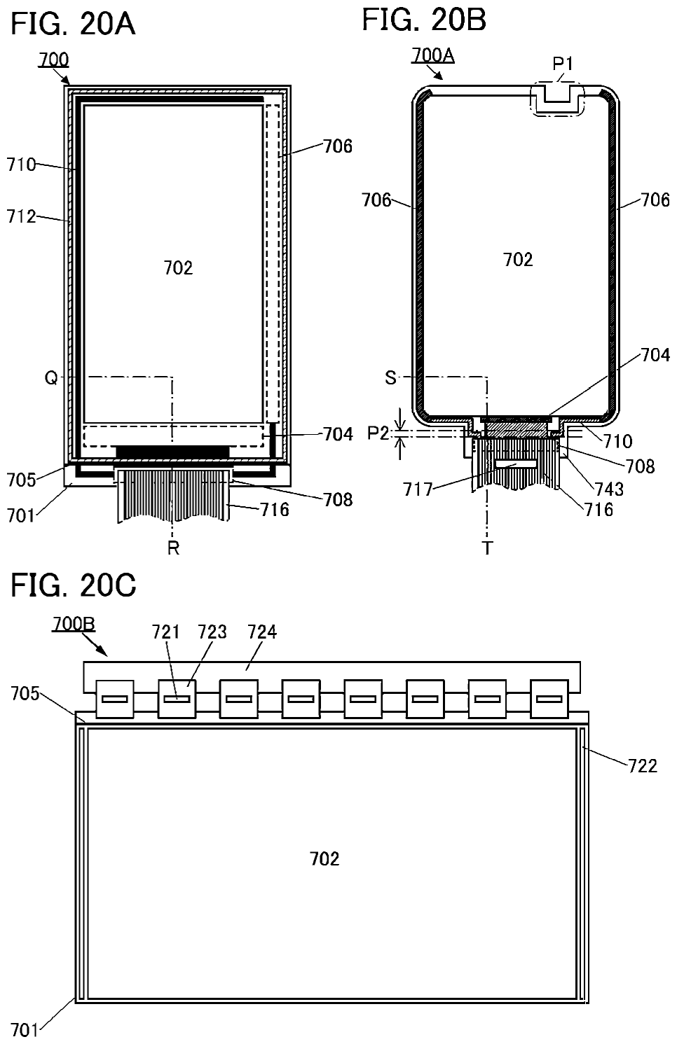

FIG. 20A is a top view of a display device 700. The display device 700 includes a first substrate 701 and a second substrate 705 that are attached to each other with a sealant 712. In a region sealed with the first substrate 701, the second substrate 705, and the sealant 712, a pixel portion 702, a source driver circuit portion 704, and a gate driver circuit portion 706 are provided over the first substrate 701. In the pixel portion 702, a plurality of display elements are provided.

An FPC terminal portion 708 to which an FPC 716 (FPC: Flexible printed circuit) is connected is provided in a portion of the first substrate 701 that does not overlap with the second substrate 705. The pixel portion 702, the source driver circuit portion 704, and the gate driver circuit portion 706 are each supplied with a variety of signals and the like from the FPC 716 through the FPC terminal portion 708 and a signal line 710.

A plurality of gate driver circuit portions 706 may be provided. The gate driver circuit portion 706 and the source driver circuit portion 704 may be formed separately on semiconductor substrates or the like to obtain packaged IC chips. The IC chips can be mounted on the first substrate 701 or the FPC 716.

Any of the transistors that are the semiconductor devices of embodiments of the present invention can be used as transistors included in the pixel portion 702, the source driver circuit portion 704, and the gate driver circuit portion 706.

Examples of the display element provided in the pixel portion 702 include a liquid crystal element and a light-emitting element. As the liquid crystal element, a transmissive liquid crystal element, a reflective liquid crystal element, a transflective liquid crystal element, or the like can be used. As the light-emitting element, a self-luminous light-emitting element such as an LED (Light Emitting Diode), an OLED (Organic LED), a QLED (Quantum-dot LED), or a semiconductor laser can be used. It is also possible to use a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like, for instance.

A display device 700A illustrated in FIG. 20B is an example of a display device which includes a flexible resin layer 743 instead of the first substrate 701 and can be used as a flexible display.

In the display device 700A, the pixel portion 702 has not a rectangular shape but a shape with rounded corners. The display device 700A includes a notch portion in which part of the pixel portion 702 and part of the resin layer 743 are cut as illustrated in a region P1 in FIG. 20B. A pair of gate driver circuit portions 706 is provided on the opposite sides with the pixel portion 702 therebetween. The gate driver circuit portions 706 are provided along a curved outline at the corners of the pixel portion 702.

The resin layer 743 has a shape with a sticking-out portion where the FPC terminal portion 708 is provided. Furthermore, part of the resin layer 743 that includes the FPC terminal portion 708 can be bent backward in a region P2 in FIG. 20B. When part of the resin layer 743 is bent backward, the display device 700A can be mounted on an electronic device while the FPC 716 overlaps with the back side of the pixel portion 702; thus, the electronic device can be downsized.

An IC 717 is mounted on the FPC 716 connected to the display device 700A. The IC 717 functions as a source driver circuit, for example. In this case, the source driver circuit portion 704 in the display device 700B can include at least one of a protection circuit, a buffer circuit, a demultiplexer circuit, and the like.

A display device 700B illustrated in FIG. 20C is a display device that can be suitably used for an electronic device with a large screen. For example, the display device 700B can be suitably used for a television device, a monitor device, a personal computer (including a notebook type and a desktop type), a tablet terminal, digital signage, or the like.

The display device 700B includes a plurality of source driver ICs 721 and a pair of gate driver circuit portions 722.

The plurality of source driver ICs 721 are attached to respective FPCs 723. In each of the plurality of FPCs 723, one of terminals is connected to the first substrate 701, and the other terminal is connected to a printed circuit board 724. By bending the FPCs 723, the printed circuit board 724 can be placed on the back side of the pixel portion 702 so that the display device 700B can be mounted on an electronic device; thus, the electronic device can be downsized.

Meanwhile, the gate driver circuit portions 722 are provided over the first substrate 701. Thus, an electronic device with a narrow bezel can be provided.

With such a structure, a large-size and high-resolution display device can be provided. For example, a display device with a diagonal screen size of 30 inches or more, 40 inches or more, 50 inches or more, or 60 inches or more can be obtained. Furthermore, a display device with extremely high resolution such as 4K2K or 8K4K can be provided.

### <Cross-Sectional Structure Example>

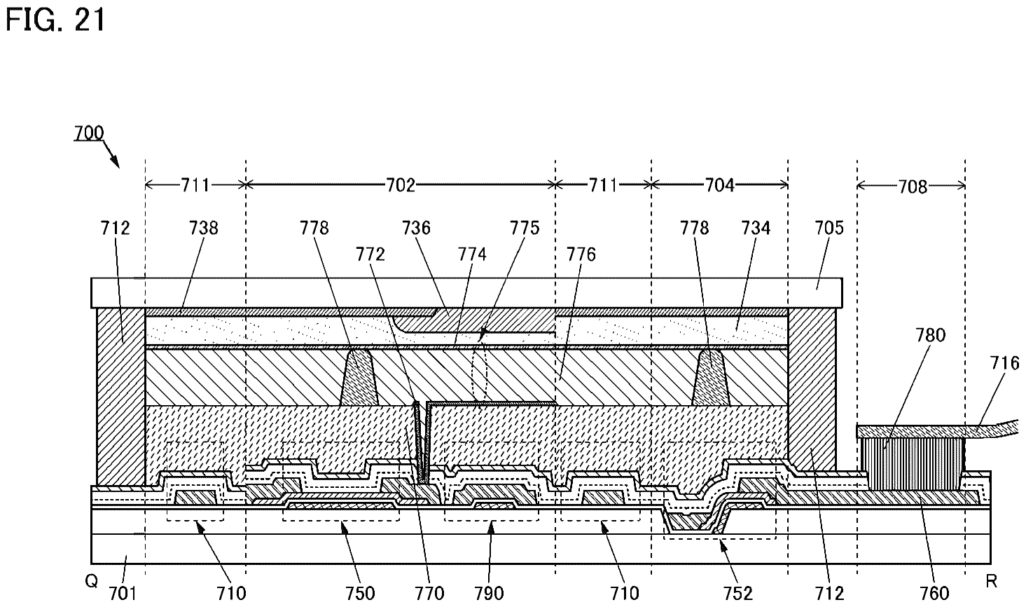

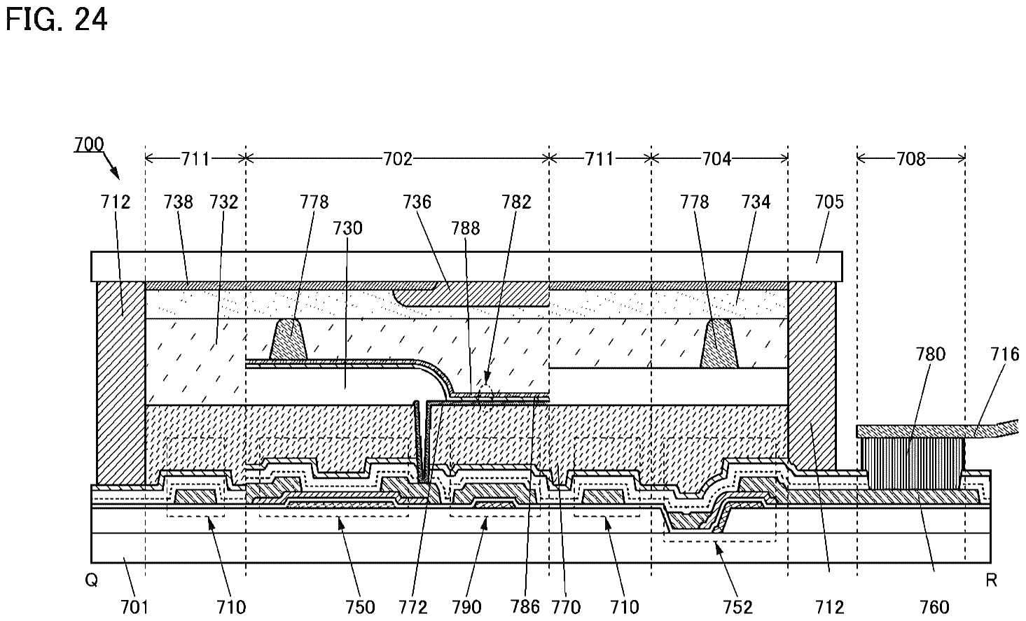

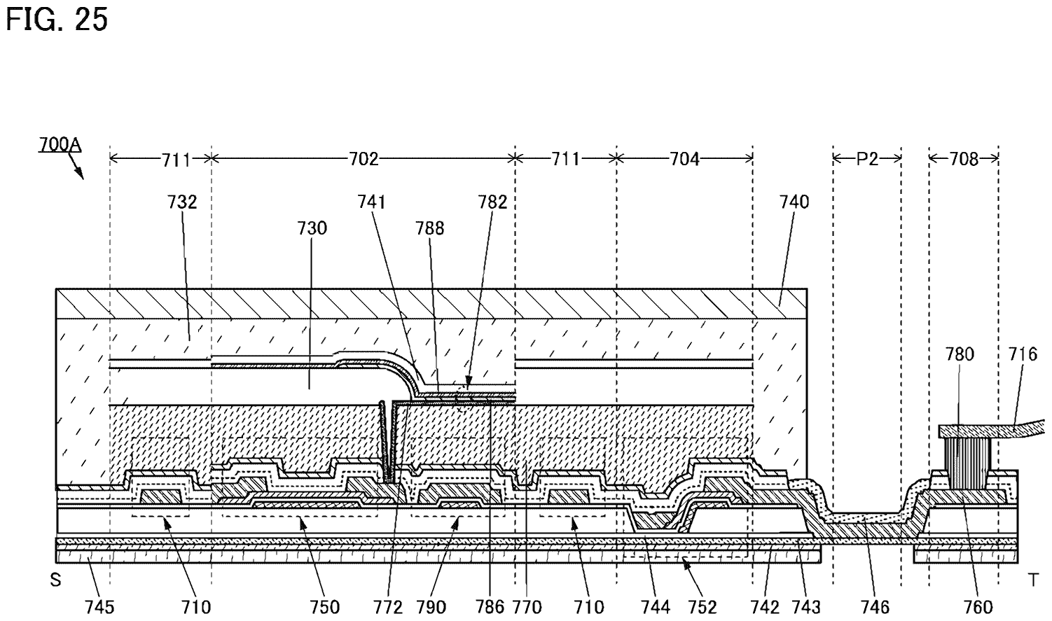

Structures using a liquid crystal element and an EL element as display elements will be described below with reference to FIG. 21 to FIG. 25. Note that FIG. 21 to FIG. 24 are cross-sectional views along the dashed-dotted line Q-R in FIG. 20A. FIG. 25 is a cross-sectional view along the dashed-dotted line S-T illustrated in FIG. 20B. FIG. 21 to FIG. 23 each show a structure using a liquid crystal element as a display element, and FIG. 24 and FIG. 25 each show a structure using an EL element.

### [Description of Common Portions in Display Devices]

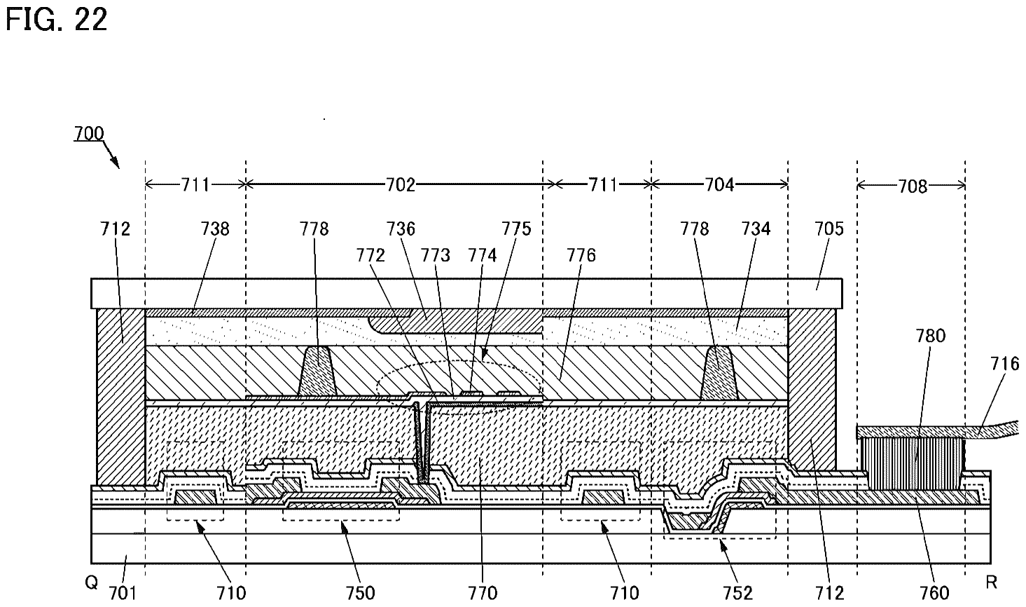

Display devices in FIG. 21 to FIG. 25 each include a lead wiring portion 711, the pixel portion 702, the source driver circuit portion 704, and the FPC terminal portion 708. The lead wiring portion 711 includes the signal line 710. The pixel portion 702 includes a transistor 750 and a capacitor 790. The source driver circuit portion 704 includes a transistor 752. FIG. 22 illustrates a case where the capacitor 790 is not provided.

The transistors exemplified in Embodiment 1 can be used as the transistor 750 and the transistor 752. For example, the source driver circuit portion 704 can include one or more of the transistor 100 to the transistor 100E each having high on-state current. For example, the pixel portion 702 can include one or more of the transistor 101 to the transistor 101B each having favorable saturation characteristics. Note that the source driver circuit portion 704 may include one or more of the transistor 100 to the transistor 100E and one or more of the transistor 101 to the transistor 101B. The pixel portion 702 may include one or more of the transistor 100 to the transistor 100E and one or more of the transistor 101 to the transistor 101B.

The transistor used in this embodiment includes a highly purified oxide semiconductor film in which formation of oxygen vacancies is suppressed. The transistor can have low off-state current. Accordingly, an electrical signal such as an image signal can be held for a longer period, and the interval between writes of an electrical signal can be set longer. Thus, the frequency of refresh operation can be reduced, which leads to lower power consumption.

The transistor used in this embodiment can have relatively high field-effect mobility and thus is capable of high-speed operation. For example, with such a transistor capable of high-speed operation used for a display device, a switching transistor in a pixel portion and a driver transistor used in a driver circuit portion can be formed over one substrate. That is, a structure in which a driver circuit formed using a silicon wafer or the like is not used is possible, in which case the number of components of the semiconductor device can be reduced. Moreover, the use of the transistor capable of high-speed operation also in the pixel portion can provide a high-quality image.

The capacitor 790 illustrated in FIG. 21, FIG. 24, and FIG. 25 includes a lower electrode formed by processing the same film as the gate electrode of the transistor 750 and an upper electrode formed by processing the same conductive film as the source electrode or the drain electrode. Part of an insulating film functioning as a gate insulating layer of the transistor 750 is provided between the lower electrode and the upper electrode. That is, the capacitor 790 has a stacked-layer structure in which an insulating film functioning as a dielectric film is positioned between a pair of electrodes.

A planarization insulating film 770 is provided over the transistor 750, the transistor 752, and the capacitor 790.

The transistor 750 in the pixel portion 702 and the transistor 752 in the source driver circuit portion 704 may have different structures. For example, a top-gate transistor may be used as one of the transistors 750 and 752, and a bottom-gate transistor may be used as the other. Note that the same can be said for the gate driver circuit portion 706, as the source driver circuit portion 704.

The signal line 710 is formed using the same conductive film as the source electrodes, the drain electrodes, and the like of the transistors 750 and 752. In this case, a low-resistance material such as a material containing a copper element is preferably used because signal delay or the like due to the wiring resistance can be reduced and display on a large screen is possible.

The FPC terminal portion 708 includes a connection electrode 760, an anisotropic conductive film 780, and the FPC 716. The connection electrode 760 is electrically connected to a terminal included in the FPC 716 through the anisotropic conductive film 780. Here, the connection electrode 760 is formed using the same conductive film as the source electrodes, the drain electrodes, and the like of the transistors 750 and 752.

As the first substrate 701 and the second substrate 705, a glass substrate or a flexible substrate such as a plastic substrate can be used, for example. In the case where a flexible substrate is used as the first substrate 701, an insulating layer having a barrier property against water or hydrogen is preferably provided between the first substrate 701 and the transistor 750, for example.

A light-shielding layer 738, a coloring layer 736, and an insulating layer 734 in contact with these layers are provided on the second substrate 705 side.

### Structure Example of Display Device Using Liquid Crystal Element

The display device 700 illustrated in FIG. 21 includes a liquid crystal element 775. The liquid crystal element 775 includes a conductive layer 772, a conductive layer 774, and a liquid crystal layer 776 therebetween. The conductive layer 774 is provided on the second substrate 705 side and has a function of a common electrode. The conductive layer 772 is electrically connected to the source electrode or the drain electrode of the transistor 750. The conductive layer 772 is formed over the planarization insulating film 770 and functions as a pixel electrode.

A material that transmits visible light or a material that reflects visible light can be used for the conductive layer 772. As a light-transmitting material, for example, an oxide material containing indium, zinc, tin, or the like is preferably used. As a reflective material, for example, a material containing aluminum, silver, or the like is preferably used.

When a reflective material is used for the conductive layer 772, the display device 700 is a reflective liquid crystal display device. Meanwhile, when a light-transmitting material is used for the conductive layer 772, a transmissive liquid crystal display device is obtained. For a reflective liquid crystal display device, a polarizing plate is provided on the viewer side. By contrast, for a transmissive liquid crystal display device, a pair of polarizing plates is provided such that the liquid crystal element is placed therebetween.

A structure body 778 is provided between the first substrate 701 and the second substrate 705. The structure body 778 is a columnar spacer and is provided to control the distance (cell gap) between the first substrate 701 and the second substrate 705. Note that a spherical spacer may be used as the structure body 778.

The display device 700 in FIG. 22 is an example of employing the liquid crystal element 775 of a horizontal electric field mode (e.g., an FFS mode). The conductive layer 774 functioning as a common electrode is provided over the conductive layer 772 with an insulating layer 773 therebetween. An electric field generated between the conductive layer 772 and the conductive layer 774 can control the alignment state in the liquid crystal layer 776.

In FIG. 22, a storage capacitor can be formed with a stacked-layer structure including the conductive layer 774, the insulating layer 773, and the conductive layer 772. Thus, another capacitor need not be provided, and thus the aperture ratio can be increased.

Although not illustrated in FIG. 21 and FIG. 22, a structure in which an alignment film in contact with the liquid crystal layer 776 is provided may be employed. Furthermore, an optical member (an optical substrate) such as a polarizing member, a retardation member, or an anti-reflection member, and a light source such as a backlight or a sidelight can be provided as appropriate.

For the liquid crystal layer 776, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, or the like can be used. In the case where a horizontal electric field mode is employed, a liquid crystal exhibiting a blue phase for which an alignment film is not used may be used.

The following can be used as a mode of the liquid crystal element: a TN (Twisted Nematic) mode, a VA (Vertical Alignment) mode, an IPS (In-Plane-Switching) mode, an FFS (Fringe Field Switching) mode, an ASM (Axially Symmetric aligned Micro-cell) mode, an OCB (Optically Compensated Birefringence) mode, an ECB (Electrically Controlled Birefringence) mode, a guest-host mode, or the like.

A scattering liquid crystal employing a polymer dispersed liquid crystal, a polymer network liquid crystal, or the like can be used for the liquid crystal layer 776. At this time, monochrome image display may be performed without the coloring layer 736, or color display may be performed using the coloring layer 736.

As a method for driving the liquid crystal element, a time-division display method (also referred to as a field-sequential driving method) in which color display is performed on the basis of a successive additive color mixing method may be employed. In that case, a structure in which the coloring layer 736 is not provided may be employed. In the case where the time-division display method is employed, advantages such as the aperture ratio of each pixel or the resolution being increased can be obtained because subpixels that emit light of, for example, R (red), G (green), and B (blue), need not be provided.

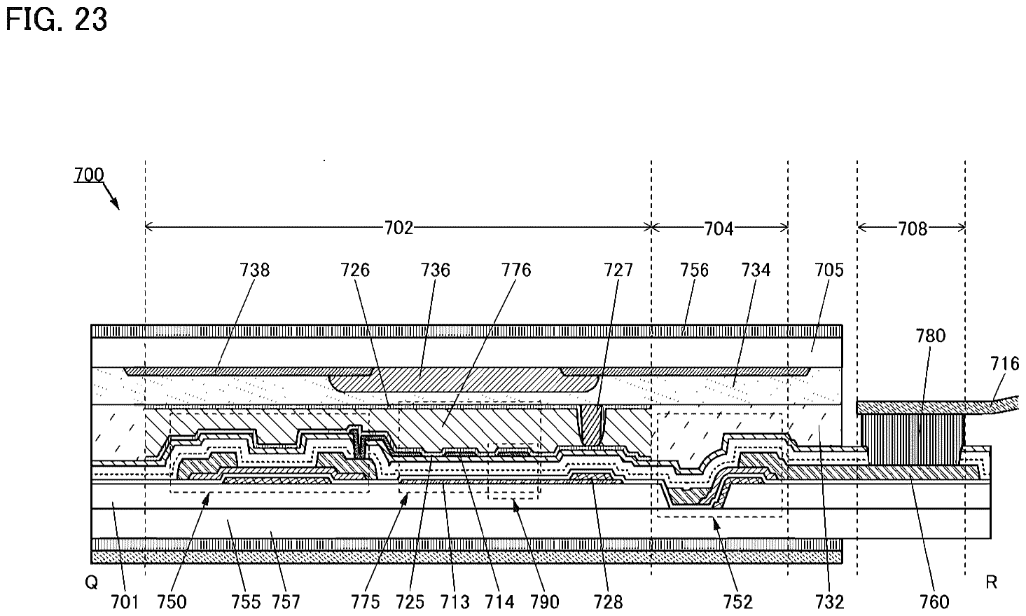

FIG. 23 illustrates an example of employing the liquid crystal element 775 of a horizontal electric field mode (e.g., an FFS mode), which is different from that in the display device 700 in FIG. 22.

The display device 700 illustrated in FIG. 23 includes the transistor 750, the transistor 752, the liquid crystal element 775, and the like between the first substrate 701 and the second substrate 705. The first substrate 701 and the second substrate 705 are attached to each other with a sealing layer 732.

The liquid crystal element 775 includes a conductive layer 714, the liquid crystal layer 776, and a conductive layer 713. The conductive layer 713 is provided over the first substrate 701. One or more insulating layers are provided over the conductive layer 713, and the conductive layer 714 is provided over the insulating layer(s). Furthermore, the liquid crystal layer 776 is positioned between the conductive layer 714 and the second substrate 705. The conductive layer 713 is electrically connected to a wiring 728 and functions as a common electrode. The conductive layer 714 is electrically connected to the transistor 750 and serves as a pixel electrode. A common potential is applied to the wiring 728.

The conductive layer 714 has a comb-like top surface shape or a top surface shape including a slit. In the liquid crystal element 775, the alignment state of the liquid crystal layer 776 is controlled by an electric field generated between the conductive layer 714 and the conductive layer 713.

The capacitor 790 functioning as a storage capacitor is formed of a stacked-layer structure of the conductive layer 714, the conductive layer 713, and one or more insulating layers sandwiched therebetween. Thus, another capacitor need not be provided, and thus the aperture ratio can be increased.

A material that transmits visible light or a material that reflects visible light can be used for the conductive layer 714 and the conductive layer 713. As a light-transmitting material, for example, an oxide material containing indium, zinc, tin, or the like is preferably used. As a reflective material, for example, a material containing aluminum, silver, or the like is preferably used.

When a reflective material is used for one or both of the conductive layer 714 and the conductive layer 713, the display device 700 is a reflective liquid crystal display device. Meanwhile, when a light-transmitting material is used for both of the conductive layer 714 and the conductive layer 713, the display device 700 is a transmissive liquid crystal display device. For a reflective liquid crystal display device, a polarizing plate is provided on the viewer side. By contrast, for a transmissive liquid crystal display device, a pair of polarizing plates is provided such that the liquid crystal element is placed therebetween.

FIG. 23 illustrates an example of a transmissive liquid crystal display device. A polarizing plate 755 and a light source 757 are provided on the outer side of the first substrate 701, and a polarizing plate 756 is provided on the outer side of the second substrate 705. The light source 757 functions as a backlight.

The light-shielding layer 738 and the coloring layer 736 are provided on a surface of the second substrate 705 that is on the first substrate 701 side. The insulating layer 734 functioning as a planarization layer is provided to cover the light-shielding layer 738 and the coloring layer 736. A spacer 727 is provided on a surface of the insulating layer 734 that is on the first substrate 701 side.

The liquid crystal layer 776 is positioned between an alignment film 725 covering the conductive layer 714 and an alignment film 726 covering the insulating layer 734. Note that the alignment film 725 and the alignment film 726 are not necessarily provided when not needed.

Although not illustrated in FIG. 23, an optical member (optical film) such as a retardation film or an anti-reflection film, a protective film, an antifouling film, or the like can be provided on the outer side of the second substrate 705 as appropriate. Examples of the anti-reflection film include an AG (Anti Glare) film and an AR (Anti Reflection) film.

The display device 700 illustrated in FIG. 23 has a structure in which an organic insulating film functioning as a planarization layer is not provided on a surface on which the conductive layer 714 functioning as a pixel electrode or the conductive layer 713 functioning as a common electrode is formed. Furthermore, bottom-gate transistors, which have a relatively small number of fabrication steps, are used as the transistor 750 and the like included in the display device 700. With such a structure, the manufacturing cost can be reduced and the manufacturing yield can be increased, so that a display device having high reliability can be provided at low cost.

### Structure Example of Display Device Using Light-Emitting Element

The display device 700 illustrated in FIG. 24 includes a light-emitting element 782. The light-emitting element 782 includes the conductive layer 772, an EL layer 786, and a conductive film 788. The EL layer 786 contains an organic compound or an inorganic compound such as quantum dots.

Examples of materials that can be used for an organic compound include a fluorescent material and a phosphorescent material. Examples of materials that can be used for quantum dots include a colloidal quantum dot material, an alloyed quantum dot material, a core-shell quantum dot material, and a core quantum dot material.

In the display device 700 illustrated in FIG. 24, an insulating film 730 covering part of the conductive layer 772 is provided over the planarization insulating film 770. Here, the light-emitting element 782 is a top-emission light-emitting element, which includes the conductive film 788 with a light-transmitting property. Note that the light-emitting element 782 may have a bottom-emission structure in which light is emitted to the conductive layer 772 side, or a dual-emission structure in which light is emitted to both the conductive layer 772 side and the conductive film 788 side.

The coloring layer 736 is provided in a position overlapping with the light-emitting element 782, and the light-shielding layer 738 is provided in the lead wiring portion 711, the source driver circuit portion 704, and a position overlapping with the insulating film 730. The coloring layer 736 and the light-shielding layer 738 are covered with the insulating layer 734. A space between the light-emitting element 782 and the insulating layer 734 is filled with the sealing layer 732. Note that a structure in which the coloring layer 736 is not provided may be employed when the EL layer 786 is formed into an island shape for each pixel or into a stripe shape for each pixel column, i.e., the EL layer 786 is formed by separate coloring.

FIG. 25 illustrates a structure of a display device suitably applicable to a flexible display. FIG. 25 is a cross-sectional view along the dashed-dotted line S-T in the display device 700A in FIG. 20B.

The display device 700A in FIG. 25 has a structure in which a support substrate 745, a bonding layer 742, the resin layer 743, and an insulating layer 744 are stacked instead of the first substrate 701 in FIG. 24. The transistor 750 and the like are provided over the insulating layer 744 over the resin layer 743.

The support substrate 745 includes an organic resin, glass, or the like and is thin enough to have flexibility. The resin layer 743 is a layer containing an organic resin such as polyimide or acrylic. The insulating layer 744 includes an inorganic insulating film such as silicon oxide, silicon oxynitride, or silicon nitride. The resin layer 743 and the support substrate 745 are attached to each other with the bonding layer 742. The resin layer 743 is preferably thinner than the support substrate 745.

The display device 700 in FIG. 25 includes a protective layer 740 instead of the second substrate 705 in FIG. 24. The protective layer 740 is attached to the sealing layer 732. A glass substrate, a resin film, or the like can be used as the protective layer 740. Alternatively, as the protective layer 740, an optical member such as a polarizing plate or a scattering plate, an input device such as a touch sensor panel, or a structure in which two or more of the above are stacked may be employed.

The EL layer 786 included in the light-emitting element 782 is provided in an island shape over the insulating film 730 and the conductive layer 772. The EL layers 786 are formed separately so that respective subpixels emit light of different colors, whereby color display can be performed without use of the coloring layer 736. A protective layer 741 is provided to cover the light-emitting element 782. The protective layer 741 has a function of preventing diffusion of impurities such as water into the light-emitting element 782. The protective layer 741 is preferably formed using an inorganic insulating film. The protective layer 741 further preferably has a stacked-layer structure including one or more inorganic insulating films and one or more organic insulating films.

FIG. 25 illustrates the region P2 that can be bent. The region P2 includes a portion where the support substrate 745, the bonding layer 742, and the inorganic insulating film such as the insulating layer 744 are not provided. In the region P2, a resin layer 746 is provided to cover the connection electrode 760. When a structure is employed in which an inorganic insulating film is not provided in the region P2 that can be bent and only a conductive layer containing a metal or an alloy and a layer containing an organic material are stacked, generation of cracks caused at bending can be prevented. When the support substrate 745 is not provided in the region P2, part of the display device 700A can be bent with an extremely small radius of curvature.

### Structure Example of Display Device Provided with Input Device

An input device may be provided in the display device illustrated in FIG. 21 to FIG. 25. Examples of the input device include a touch sensor.

A variety of types such as a capacitive type, a resistive type, a surface acoustic wave type, an infrared type, an optical type, and a pressure-sensitive type can be used as the sensor type, for example. Alternatively, two or more of these types may be combined and used.

Examples of the touch panel structure include what is called an in-cell touch panel in which an input device is provided between a pair of substrates, what is called an on-cell touch panel in which an input device is formed over the display device, and what is called an out-cell touch panel in which an input device is attached to the display device.

At least part of the structure examples, the drawings corresponding thereto, and the like exemplified in this embodiment can be implemented in combination with the other structure examples, the other drawings, and the like as appropriate.

At least part of this embodiment can be implemented in combination with any of the other embodiments described in this specification as appropriate.

### Embodiment 3

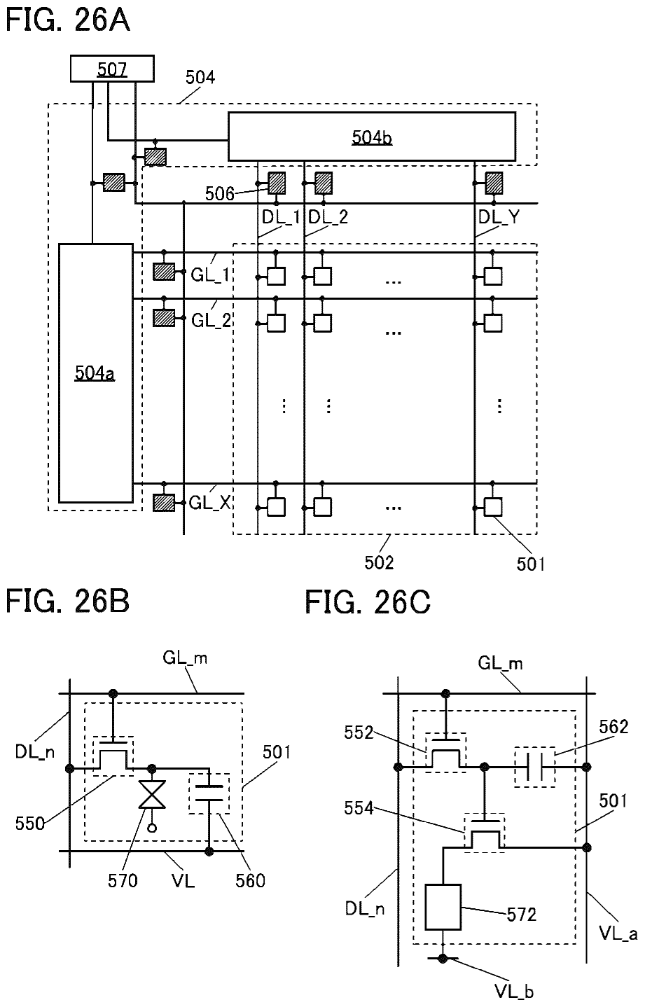

In this embodiment, a display device that includes the semiconductor device of one embodiment of the present invention will be described with reference to FIG. 26A to FIG. 26C.

A display device illustrated in FIG. 26A includes a pixel portion 502, a driver circuit portion 504, protection circuits 506, and a terminal portion 507. Note that a structure in which the protection circuits 506 are not provided may be employed.

The transistor of one embodiment of the present invention can be used as transistors included in the pixel portion 502 and the driver circuit portion 504. The transistor of one embodiment of the present invention may also be used in the protection circuits 506.

The pixel portion 502 includes a plurality of pixel circuits 501 that drive a plurality of display elements arranged in X rows and Y columns (X and Y each independently represent a natural number of 2 or more).

The driver circuit portion 504 includes driver circuits such as a gate driver 504a that outputs a scan signal to a scan line GL_1 to a scan line GL_X and a source driver 504b that supplies a data signal to a data line DL_1 to a data line DL_Y The gate driver 504a includes at least a shift register. The source driver 504b is formed using a plurality of analog switches, for example. Alternatively, the source driver 504b may be formed using a shift register or the like.

The terminal portion 507 refers to a portion provided with terminals for inputting power, control signals, image signals, and the like to the display device from external circuits.

The protection circuit 506 is a circuit that, when a potential out of a certain range is applied to a wiring to which the protection circuit 506 is connected, establishes continuity between the wiring and another wiring. The protection circuit 506 illustrated in FIG. 26A is connected to a variety of wirings such as the scan line GL_1 to the scan line GL_X that are wirings between the gate driver 504a and the pixel circuits 501 and the data line DL_1 to the data line DL_Y that are wirings between the source driver 504b and the pixel circuits 501, for example.

The gate driver 504a and the source driver 504b may be provided over a substrate over which the pixel portion 502 is provided, or a substrate where a gate driver circuit or a source driver circuit is separately formed (e.g., a driver circuit board formed using a single crystal semiconductor film or a polycrystalline semiconductor film) may be mounted on the substrate by COG or TAB (Tape Automated Bonding).

The plurality of pixel circuits 501 illustrated in FIG. 26A can have a structure illustrated in FIG. 26B or FIG. 26C, for example.

The pixel circuit 501 illustrated in FIG. 26B includes a liquid crystal element 570, a transistor 550, and a capacitor 560. The data line DL_n, the scan line GL_m, a potential supply line VL, and the like are connected to the pixel circuit 501.

The potential of one of a pair of electrodes of the liquid crystal element 570 is set appropriately in accordance with the specifications of the pixel circuit 501. The alignment state of the liquid crystal element 570 is set depending on written data. Note that a common potential may be supplied to one of the pair of electrodes of the liquid crystal element 570 included in each of the plurality of pixel circuits 501. Alternatively, a potential supplied to one of the pair of electrodes of the liquid crystal element 570 of the pixel circuit 501 may differ between rows.

The pixel circuit 501 illustrated in FIG. 26C includes transistors 552 and 554, a capacitor 562, and a light-emitting element 572. The data line DL_n, the scan line GL_m, a potential supply line VL_a, a potential supply line VL_b, and the like are connected to the pixel circuit 501.

Note that a high power supply potential VDD is supplied to one of the potential supply line VL_a and the potential supply line VL_b, and a low power supply potential VSS is supplied to the other. Current flowing through the light-emitting element 572 is controlled in accordance with a potential supplied to a gate of the transistor 554, whereby the luminance of light emitted from the light-emitting element 572 is controlled.

At least part of the structure examples, the drawings corresponding thereto, and the like exemplified in this embodiment can be implemented in combination with the other structure examples, the other drawings, and the like as appropriate.

At least part of this embodiment can be implemented in combination with any of the other embodiments described in this specification as appropriate.

### Embodiment 4

A pixel circuit including a memory for correcting gray levels displayed by pixels and a display device including the pixel circuit will be described below. The transistor described in Embodiment 1 can be used as a transistor used in the pixel circuit described below.

### <Circuit Structure>

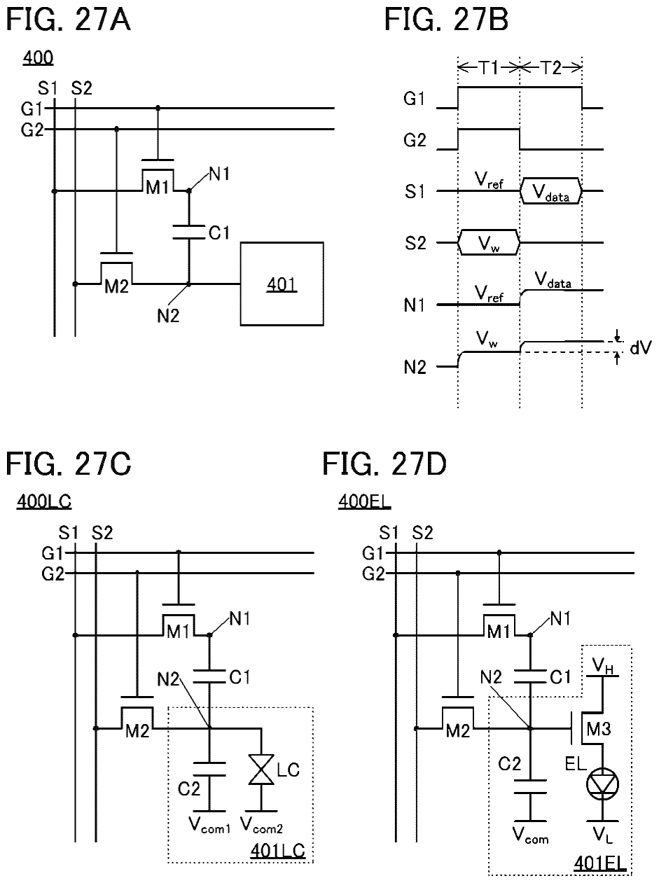

FIG. 27A is a circuit diagram of a pixel circuit 400. The pixel circuit 400 includes a transistor M1, a transistor M2, a capacitor C1, and a circuit 401. A wiring S1, a wiring S2, a wiring G1, and a wiring G2 are connected to the pixel circuit 400.

In the transistor M1, a gate is connected to the wiring G1, one of a source and a drain is connected to the wiring S1, and the other is connected to one electrode of the capacitor C1. In the transistor M2, a gate is connected to the wiring G2, one of a source and a drain is connected to the wiring S2, and the other is connected to the other electrode of the capacitor C1 and the circuit 401.

The circuit 401 is a circuit including at least one display element. Any of a variety of elements can be used as the display element, and typically, a light-emitting element such as an organic EL element or an LED element, a liquid crystal element, a MEMS (Micro Electro Mechanical Systems) element, or the like can be used.

A node connecting the transistor M1 and the capacitor C1 is denoted as a node N1, and a node connecting the transistor M2 and the circuit 401 is denoted as a node N2.

In the pixel circuit 400, the potential of the node N1 can be retained when the transistor M1 is turned off. The potential of the node N2 can be retained when the transistor M2 is turned off. When a predetermined potential is written to the node N1 through the transistor M1 with the transistor M2 being in an off state, the potential of the node N2 can be changed in accordance with displacement of the potential of the node N1 owing to capacitive coupling through the capacitor C1.

Here, the transistor using an oxide semiconductor, which is described in Embodiment 1, can be used as one or both of the transistor M1 and the transistor M2. Accordingly, owing to an extremely low off-state current, the potentials of the node N1 and the node N2 can be retained for a long time. Note that in the case where the period in which the potential of each node is retained is short (specifically, the case where the frame frequency is higher than or equal to 30 Hz, for example), a transistor using a semiconductor such as silicon may be used.

### <Driving Method Example>

Next, an example of a method for operating the pixel circuit 400 is described with reference to FIG. 27B. FIG. 27B is a timing chart of the operation of the pixel circuit 400. Note that for simplification of description, the influence of various kinds of resistance such as wiring resistance, parasitic capacitance of a transistor, a wiring, or the like, the threshold voltage of the transistor, and the like is not taken into account here.

In the operation shown in FIG. 27B, one frame period is divided into a period T1 and a period T2. The period T1 is a period in which a potential is written to the node N2, and the period T2 is a period in which a potential is written to the node N1.

### [Period T1]

In the period T1, a potential for turning on the transistor is supplied to both the wiring G1 and the wiring G2. In addition, a potential V_{ref} that is a fixed potential is supplied to the wiring S1, and a first data potential V_{w} is supplied to the wiring S2.

The potential V_{ref} is supplied from the wiring S1 to the node N1 through the transistor M1. The first data potential V_{w} is supplied from the wiring S2 to the node N2 through the transistor M2. Accordingly, a potential difference V_{w}-V_{ref} is retained in the capacitor C1.

### [Period T2]

Next, in the period T2, a potential for turning on the transistor M1 is supplied to the wiring G1, and a potential for turning off the transistor M2 is supplied to the wiring G2. A second data potential V_{data} is supplied to the wiring S1. The wiring S2 may be supplied with a predetermined constant potential or brought into a floating state.

The second data potential V_{data} is supplied from the wiring S1 to the node N1 through the transistor M1. At this time, capacitive coupling due to the capacitor C1 changes the potential of the node N2 in accordance with the second data potential V_{data} by a potential dV. That is, a potential that is the sum of the first data potential V_{w} and the potential dV is input to the circuit 401. Note that although the potential dV is shown as a positive value in FIG. 27B, the potential dV may be a negative value. That is, the second data potential V_{data} may be lower than the potential V_{ref}.

Here, the potential dV is roughly determined by the capacitance of the capacitor C1 and the capacitance of the circuit 401. When the capacitance of the capacitor C1 is sufficiently larger than the capacitance of the circuit 401, the potential dV is a potential close to the second data potential V_{data}.

In the above manner, the pixel circuit 400 can generate a potential to be supplied to the circuit 401 including the display element, by combining two kinds of data signals; hence, a gray level can be corrected in the pixel circuit 400.

The pixel circuit 400 can also generate a potential exceeding the maximum potential that can be supplied to the wiring S1 and the wiring S2. For example, in the case where a light-emitting element is used, high-dynamic range (HDR) display or the like can be performed. In the case where a liquid crystal element is used, overdriving or the like can be achieved.

### Application Examples

### Example Using Liquid Crystal Element

A pixel circuit 400LC illustrated in FIG. 27C includes a circuit 401LC. The circuit 401LC includes a liquid crystal element LC and a capacitor C2.

In the liquid crystal element LC, one electrode is connected to the node N2 and one electrode of the capacitor C2, and the other electrode is connected to a wiring supplied with a potential V_{com2}. The other electrode of the capacitor C2 is connected to a wiring supplied with a potential V_{com1}.

The capacitor C2 functions as a storage capacitor. Note that the capacitor C2 can be omitted when not needed.

In the pixel circuit 400LC, a high voltage can be supplied to the liquid crystal element LC; thus, high-speed display can be performed by overdriving or a liquid crystal material with a high driving voltage can be employed, for example. Moreover, by supply of a correction signal to the wiring S1 or the wiring S2, a gray level can be corrected in accordance with the operating temperature, the deterioration state of the liquid crystal element LC, or the like.

### Example Using Light-Emitting Element

A pixel circuit 400EL illustrated in FIG. 27D includes a circuit 401EL. The circuit 401EL includes a light-emitting element EL, a transistor M3, and the capacitor C2.

In the transistor M3, a gate is connected to the node N2 and one electrode of the capacitor C2, one of a source and a drain is connected to a wiring supplied with a potential V_{H}, and the other is connected to one electrode of the light-emitting element EL. The other electrode of the capacitor C2 is connected to a wiring supplied with a potential V_{com}. The other electrode of the light-emitting element EL is connected to a wiring supplied with a potential V_{L}.

The transistor M3 has a function of controlling a current to be supplied to the light-emitting element EL. The capacitor C2 functions as a storage capacitor. The capacitor C2 can be omitted when not needed.

Note that although the structure in which the anode side of the light-emitting element EL is connected to the transistor M3 is described here, the transistor M3 may be connected to the cathode side. In that case, the values of the potential V_{H} and the potential V_{L} can be appropriately changed.

In the pixel circuit 400EL, a large amount of current can flow through the light-emitting element EL when a high potential is applied to the gate of the transistor M3, which enables HDR display, for example. Moreover, a variation in the electrical characteristics of the transistor M3 and the light-emitting element EL can be corrected by supply of a correction signal to the wiring S1 or the wiring S2.

Note that the structure is not limited to the circuits illustrated in FIG. 27C and FIG. 27D, and a structure to which a transistor, a capacitor, or the like is further added may be employed. At least part of this embodiment can be implemented in combination with any of the other embodiments described in this specification as appropriate.

### Embodiment 5

In this embodiment, a display module that can be fabricated using one embodiment of the present invention is described.

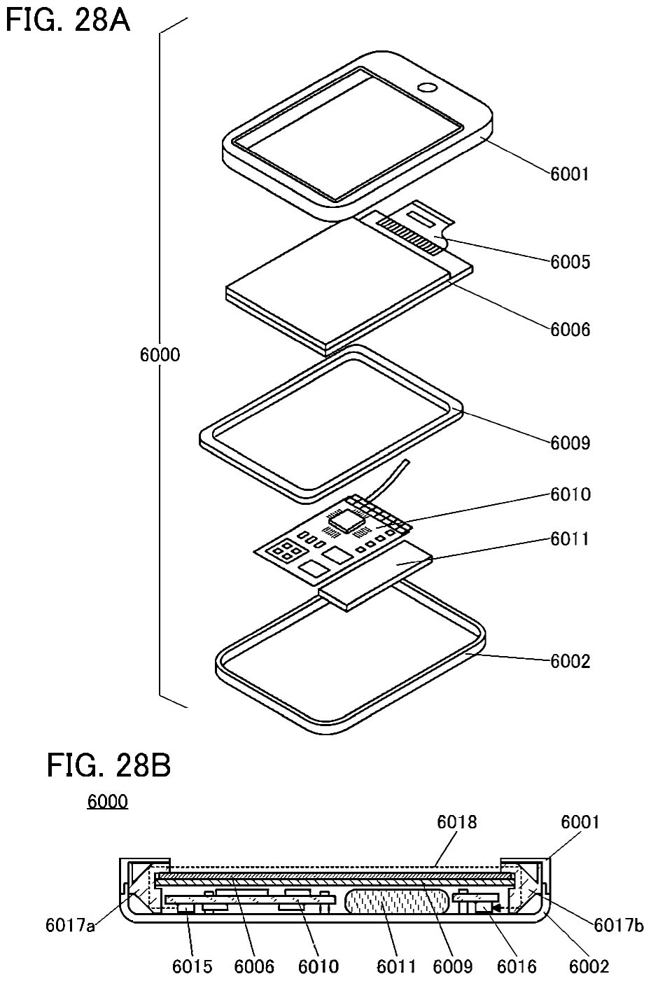

In a display module 6000 illustrated in FIG. 28A, a display device 6006 to which an FPC 6005 is connected, a frame 6009, a printed circuit board 6010, and a battery 6011 are provided between an upper cover 6001 and a lower cover 6002.

A display device fabricated using one embodiment of the present invention can be used as the display device 6006, for example. With the display device 6006, a display module with extremely low power consumption can be achieved.

The shape and size of the upper cover 6001 and the lower cover 6002 can be changed as appropriate in accordance with the size of the display device 6006.

The display device 6006 may have a function of a touch panel.

The frame 6009 may have a function of protecting the display device 6006, a function of blocking electromagnetic waves generated by the operation of the printed circuit board 6010, a function of a heat dissipation plate, or the like.

The printed circuit board 6010 includes a power supply circuit, a signal processing circuit for outputting a video signal and a clock signal, a battery control circuit, and the like.

FIG. 28B is a schematic cross-sectional view of the display module 6000 having an optical touch sensor.

The display module 6000 includes a light-emitting portion 6015 and a light-receiving portion 6016 that are provided on the printed circuit board 6010. Furthermore, a pair of light guide portions (a light guide portion 6017a and a light guide portion 6017b) is provided in a region surrounded by the upper cover 6001 and the lower cover 6002.

The display device 6006 is provided to overlap with the printed circuit board 6010 and the battery 6011 with the frame 6009 therebetween. The display device 6006 and the frame 6009 are fixed to the light guide portion 6017a and the light guide portion 6017b.

Light 6018 emitted from the light-emitting portion 6015 travels over the display device 6006 through the light guide portion 6017a and reaches the light-receiving portion 6016 through the light guide portion 6017b. For example, blocking of the light 6018 by a sensing target such as a finger or a stylus enables detection of touch operation.

A plurality of light-emitting portions 6015 are provided along two adjacent sides of the display device 6006, for example. A plurality of light-receiving portions 6016 are provided at the positions on the opposite side of the light-emitting portions 6015. Accordingly, information about the position of touch operation can be obtained.

As the light-emitting portion 6015, a light source such as an LED element can be used, for example, and it is particularly preferable to use a light source emitting infrared rays. As the light-receiving portion 6016, a photoelectric element that receives light emitted from the light-emitting portion 6015 and converts it into an electric signal can be used. A photodiode that can receive infrared rays can be suitably used.

With the use of the light guide portion 6017a and the light guide portion 6017b which transmit the light 6018, the light-emitting portion 6015 and the light-receiving portion 6016 can be placed under the display device 6006, and a malfunction of the touch sensor due to external light reaching the light-receiving portion 6016 can be inhibited. Particularly when a resin that absorbs visible light and transmits infrared rays is used, a malfunction of the touch sensor can be inhibited more effectively.

At least part of this embodiment can be implemented in combination with any of the other embodiments described in this specification as appropriate.

### Embodiment 6

In this embodiment, examples of an electronic device for which the display device of one embodiment of the present invention can be used are described.

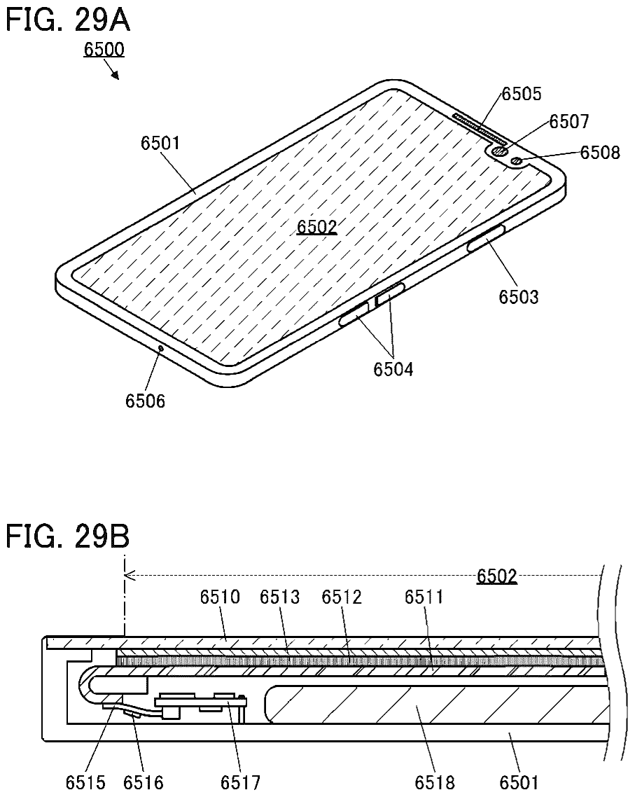

An electronic device 6500 illustrated in FIG. 29A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 29B is a schematic cross-sectional view including an end portion of the housing 6501 on the microphone 6506 side.

A protective member 6510 having alight-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protective member 6510.

The display panel 6511, the optical member 6512, and the touch sensor panel 6513 are fixed to the protective member 6510 with a bonding layer not illustrated.

Part of the display panel 6511 is bent in a region outside the display portion 6502. An FPC 6515 is connected to the bent part. An IC 6516 is mounted on the FPC 6515. The FPC 6515 is connected to a terminal provided for the printed circuit board 6517.

A flexible display panel of one embodiment of the present invention can be used as the display panel 6511. Thus, an extremely lightweight electronic device can be achieved. Furthermore, since the display panel 6511 is extremely thin, the battery 6518 with a high capacity can be provided without an increase in the thickness of the electronic device. Moreover, part of the display panel 6511 is bent to provide a connection portion with the FPC 6515 on the back side of the pixel portion, whereby an electronic device with a narrow bezel can be obtained.

At least part of this embodiment can be implemented in combination with any of the other embodiments described in this specification as appropriate.

### Embodiment 7

In this embodiment, electronic devices each including a display device fabricated using one embodiment of the present invention will be described.

Electronic devices exemplified below each include a display device of one embodiment of the present invention in a display portion. Thus, the electronic devices achieve high resolution. In addition, the electronic devices can each achieve both high resolution and a large screen.

A display portion in an electronic device of one embodiment of the present invention can display a video with a resolution of, for example, full high definition, 4K2K, 8K4K, 16K8K, or higher.

Examples of the electronic devices include a digital camera, a digital video camera, a digital photo frame, a cellular phone, a portable game machine, a portable information terminal, and an audio reproducing device, in addition to electronic devices with comparatively large screens, such as a television device, a notebook personal computer, a monitor device, digital signage, a pachinko machine, and a game machine.

An electronic device using one embodiment of the present invention can be incorporated along a flat surface or a curved surface of an inside wall or an outside wall of a house or a building, an interior or an exterior of a car, or the like.

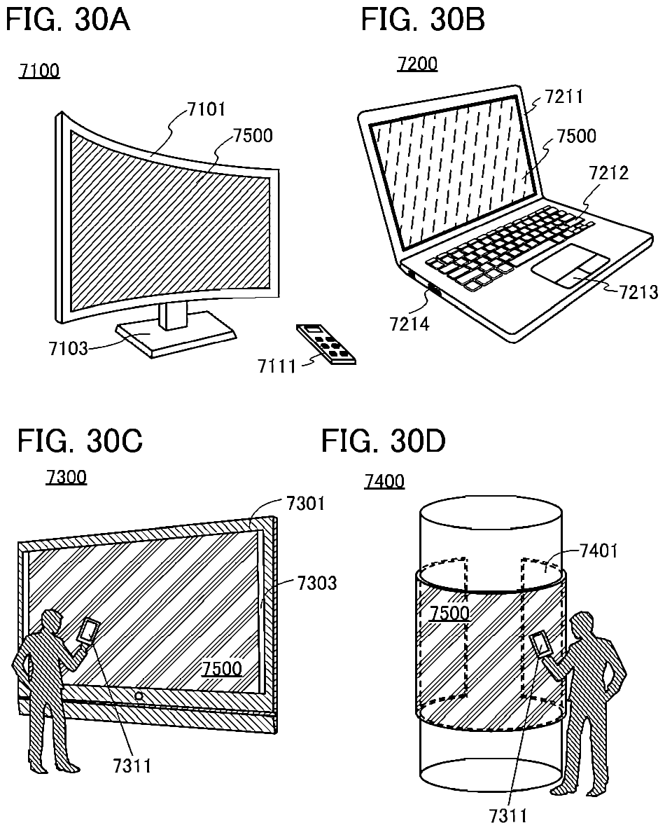

FIG. 30A illustrates an example of a television device. In a television device 7100, a display portion 7500 is incorporated in a housing 7101. Here, a structure in which the housing 7101 is supported by a stand 7103 is illustrated.

Operation of the television device 7100 illustrated in FIG. 30A can be performed with an operation switch provided in the housing 7101 or a separate remote controller 7111. Alternatively, a touch panel may be used for the display portion 7500, and the television device 7100 may be operated by touch on the touch panel. The remote controller 7111 may include a display portion in addition to operation buttons.

Note that the television device 7100 may include a television receiver and a communication device for network connection. FIG. 30B illustrates a notebook personal computer 7200. The notebook personal computer 7200 includes a housing 7211, a keyboard 7212, a pointing device 7213, an external connection port 7214, and the like. The display portion 7500 is incorporated in the housing 7211.

FIG. 30C and FIG. 30D illustrate examples of digital signage.

Digital signage 7300 illustrated in FIG. 30C includes a housing 7301, the display portion 7500, a speaker 7303, and the like. Furthermore, the digital signage can include an LED lamp, operation keys (including a power switch or an operation switch), a connection terminal, a variety of sensors, a microphone, and the like.

FIG. 30D is digital signage 7400 attached to a cylindrical pillar 7401. The digital signage 7400 includes the display portion 7500 provided along a curved surface of the pillar 7401.

The larger display portion 7500 can increase the amount of information that can be provided at a time and attracts more attention, so that the effectiveness of the advertisement can be increased, for example.

A touch panel is preferably used for the display portion 7500 so that the user can operate the digital signage. Thus, the digital signage can be used not only for advertising but also for providing information that the user needs, such as route information, traffic information, and guidance information on a commercial facility.

As illustrated in FIG. 30C and FIG. 30D, it is preferable that the digital signage 7300 or the digital signage 7400 can work with an information terminal 7311 such as a user's smartphone through wireless communication. For example, information of an advertisement displayed on the display portion 7500 can be displayed on a screen of the information terminal 7311, or display on the display portion 7500 can be switched by operation of the information terminal 7311.

It is possible to make the digital signage 7300 or the digital signage 7400 execute a game with the use of the information terminal 7311 as an operation means (controller). Thus, an unspecified number of users can join in and enjoy the game concurrently.

The display device of one embodiment of the present invention can be used for the display portion 7500 in FIG. 30A to FIG. 30D.

The electronic devices in this embodiment each have a structure including a display portion; however, one embodiment of the present invention can also be applied to an electronic device that does not include a display portion.

At least part of this embodiment can be implemented in combination with any of the other embodiments described in this specification as appropriate.

### Example

In this example, a sample corresponding to the transistor 100D illustrated in FIG. 5A was fabricated and the cross-sectional shape was evaluated.

### <Fabrication of Sample>

First, a 1000-nm-thick silicon oxynitride film was formed over a glass substrate 202 with a PECVD apparatus. Next, the silicon oxynitride film was selectively etched to form an island-shaped silicon oxynitride layer 210.

Next, a base film was formed over the glass substrate 202 and the silicon oxynitride layer 210 with a PECVD apparatus. As the base film, a 50-nm-thick silicon nitride film 260 and a 100-nm-thick silicon oxynitride film 270 were formed in this order.

Next, a 40-nm-thick metal oxide film was formed over the silicon oxynitride film. The metal oxide film was formed by a sputtering method using an In—Ga—Zn oxide target (In:Ga:Zn=4:1:4.1, atomic ratio). The deposition pressure was 0.6 Pa, the power supply was 2.5 kW, and the substrate temperature was 130° C. A mixed gas of an oxygen gas and an argon gas was used as a deposition gas, and the proportion of the flow rate of the oxygen gas to the total flow rate of the deposition gas (oxygen flow rate ratio) was 50%. Then, the metal oxide film was processed into an island shape to form a metal oxide layer 208.

Subsequently, after heat treatment was performed in a nitrogen atmosphere at 380° C. for 30 minutes, another heat treatment was performed in a mixed gas atmosphere of nitrogen and oxygen (nitrogen gas flow rate:oxygen gas flow rate=4:1) at 380° C. for 30 minutes. An oven apparatus was used for the heat treatment.

Next, a 100-nm-thick tungsten film was formed over the silicon oxynitride film 270 and the metal oxide layer 208. The tungsten film was formed by a sputtering method.

Next, a resist was formed over the tungsten film.

Then, the resist was exposed to light using a photomask. At this time, a first unexposed region was formed over a first silicon nitride by a light-shielding portion of the photomask. A second unexposed region is formed between the silicon oxynitride layer 210 and an island-shaped silicon oxynitride film adjacent to the silicon oxynitride layer 210. For the light exposure, a light exposure apparatus with an exposure limit of 1.5 m was used.

Next, the resist was developed, a first photomask was formed in the first unexposed region, and a second photomask was formed in the second unexposed region.

Next, the tungsten film was etched using the first photomask and the second photomask as a mask to form a conductive layer 212a and a conductive layer 212b. For the formation of the conductive layer 212a and the conductive layer 212b, a dry etching method was used.

Next, as a gate insulating layer 206, a 10-nm-thick first silicon oxynitride layer and a 150-nm-thick silicon nitride layer were formed in this order. The gate insulating layer 206 was formed with a PECVD apparatus.

Next, a 100-nm-thick metal oxide film to be a gate electrode 204 was formed by a sputtering method. The metal oxide film was formed by a sputtering method using an In—Ga—Zn oxide target (In:Ga:Zn=5:1:3, atomic ratio). For the deposition, the substrate temperature was set to room temperature and the oxygen flow rate ratio was set to 0%. Then, the metal oxide film was processed into an island shape to form the gate electrode 204.

Next, as a planarization film 280, an approximately 1.5-μm-thick acrylic resin film was formed. As the acrylic resin film, an acrylic photosensitive resin was used. Subsequently, heat treatment was performed in a nitrogen atmosphere at 250° C. for one hour.

Through the above process, the sample was obtained.

### <Cross-Sectional Observation>

Next, the sample was thinned by focused ion beam (FIB) and cross sections were observed with a scanning transmission electron microscope (by STEM: Scanning Transmission Electron Microscopy).

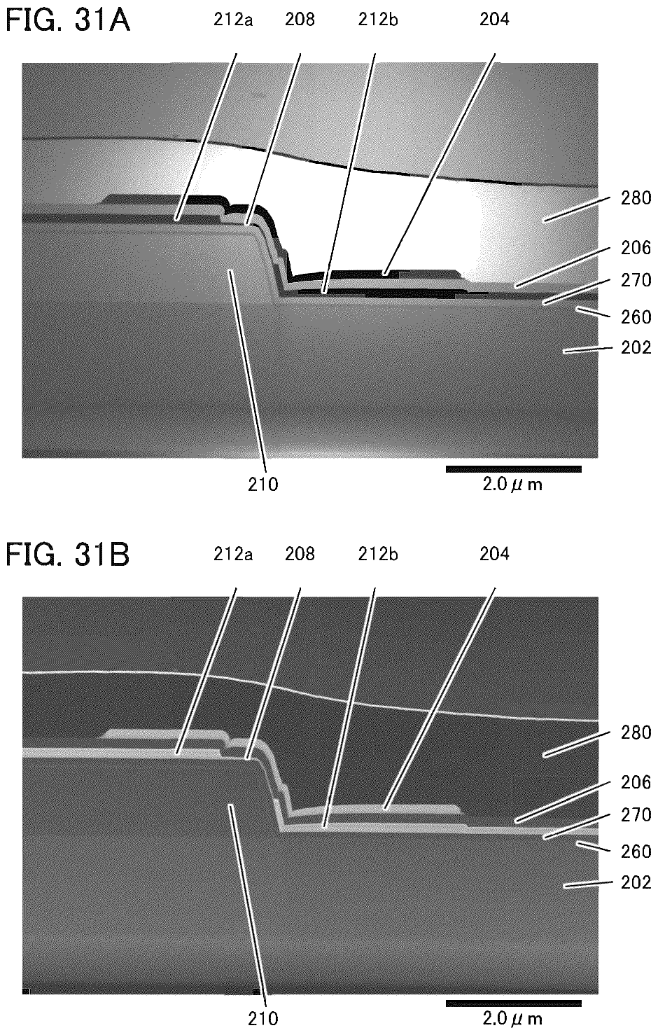

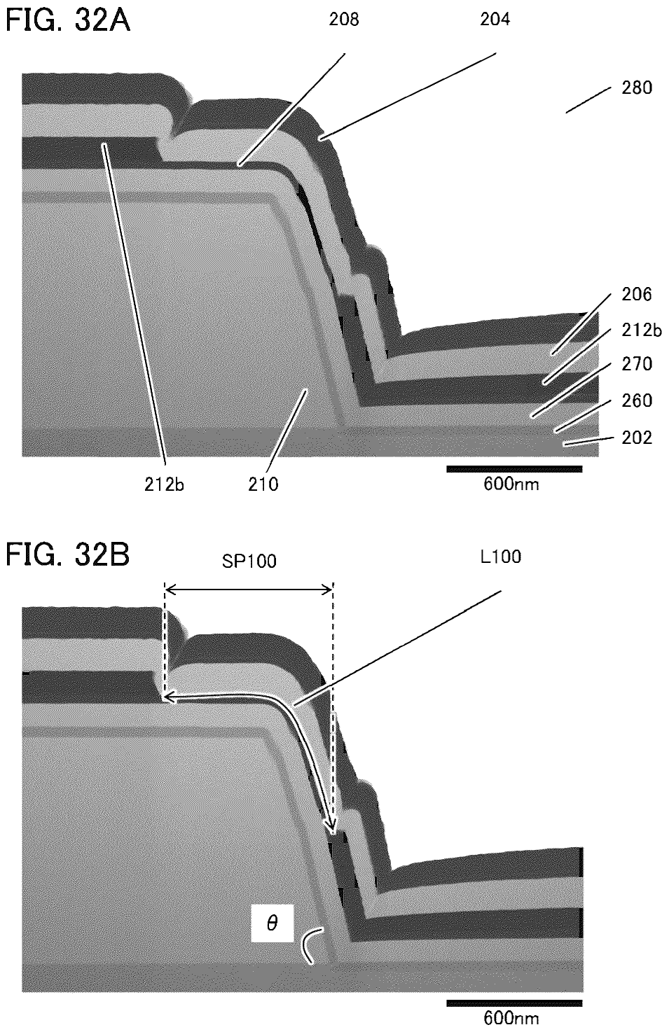

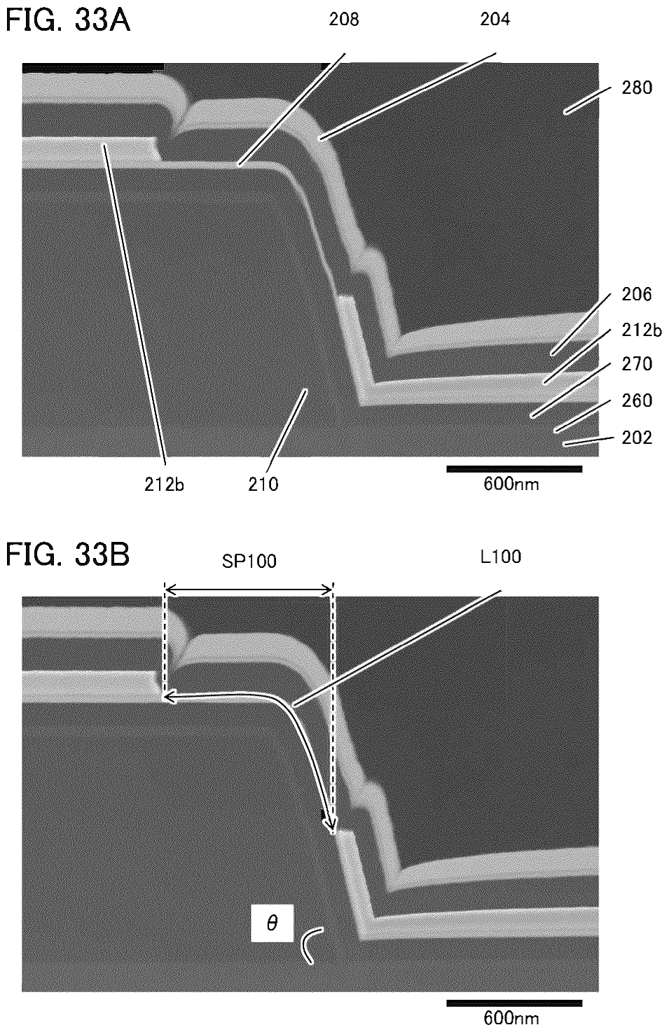

FIG. 31A, FIG. 31B, FIG. 32A, FIG. 32B, FIG. 33A, and FIG. 33B show STEM images of the cross sections. FIG. 31A is an image of transmitted electrons (TE) at a magnification of 15000 times. FIG. 31A is a Z contrast (ZC) image in the same position as FIG. 31B. A substance having a larger atomic number is observed brighter in a Z contrast image.

FIG. 32A is a transmission electron (TE) image at a magnification of 50000 times. FIG. 32B is obtained by adding arrows indicating the distance SP100 between the conductive layer 212a and the conductive layer 212b and the channel length L100 to the image of FIG. 32A. FIG. 32A is a Z contrast (ZC) image in the same position as FIG. 31A. FIG. 32B is obtained by adding arrows indicating the distance SP100 and the channel length L100 to the image of FIG. 32A.

As shown in FIG. 31A to FIG. 33B, it can be confirmed that the sample has a favorable shape. The distance SP100 was approximately 0.77 m, the channel length L100 was approximately 1.2 m, and the taper angle θ of the silicon oxynitride layer 210 was approximately 770.

As described in this example, it was able to be confirmed that according to one embodiment of the present invention, a transistor in which the channel length L100 is shorter than the exposure limit of a light exposure apparatus can be fabricated.

### REFERENCE NUMERALS

DL_1: data line, DL_n: data line, DL_Y: data line, GL_1: scan line, GL_m: scan line, GL_X: scan line, L100: channel length, L101: channel length, LC: liquid crystal element, SP100: distance, SP101: distance, V_{L}_a: potential supply line, V_{L}_b: potential supply line, V_{L}: potential supply line, 10A: semiconductor device, 10B: semiconductor device, 10: semiconductor device, 100A: transistor, 100B: transistor, 100C: transistor, 100D: transistor, 100E: transistor, 100F: transistor, 100G: transistor, 100: transistor, 101A: transistor, 101B: transistor, 101: transistor, 102: substrate, 104A: conductive layer, 104: conductive layer, 106a: insulating layer, 106b: insulating layer, 106: insulating layer, 108A: semiconductor layer, 108a: semiconductor layer, 108Aa: semiconductor layer, 108Ab: semiconductor layer, 108af: metal oxide film, 108b: semiconductor layer, 108bf: metal oxide film, 108c: semiconductor layer, 108f: metal oxide film, 108: semiconductor layer, 110A: insulating layer, 110: insulating layer, 111: groove, 112a: conductive layer, 112Aa: conductive layer, 112Ab: conductive layer, 112b: conductive layer, 113a: conductive layer, 113Aa: conductive layer, 113Ab: conductive layer, 113Ac: conductive layer, 113af: conductive film, 113b: conductive layer, 113bf: conductive film, 113c: conductive layer, 113cf: conductive film, 114: insulating layer, 116: insulating layer, 118: insulating layer, 120a: conductive layer, 120b: conductive layer, 120: conductive layer, 130: plasma, 138a: light-shielding portion, 138b: light-shielding portion, 138c: light-shielding portion, 139: light, 140a: resist mask, 140Aa: resist mask, 140Ab: resist mask, 140b: resist mask, 141: resist, 150: metal oxide layer, 191: target, 192: plasma, 193: target, 194: plasma, 202: glass substrate, 204: gate electrode, 206: gate insulating layer, 208: metal oxide layer, 210: silicon oxynitride layer, 212a: conductive layer, 212b: conductive layer, 260: silicon nitride film, 270: silicon oxynitride film, 280: planarization film, 400EL: pixel circuit, 400LC: pixel circuit, 400: pixel circuit, 401EL: circuit, 401LC: circuit, 401: circuit, 501: pixel circuit, 502: pixel portion, 504a: gate driver, 504b: source driver, 504: driver circuit portion, 506: protection circuit, 507: terminal portion, 550: transistor, 552: transistor, 554: transistor, 560: capacitor, 562: capacitor, 570: liquid crystal element, 572: light-emitting element, 700A: display device, 700B: display device, 700: display device, 701: first substrate, 702: pixel portion, 704: source driver circuit portion, 705: second substrate, 706: gate driver circuit portion, 708: FPC terminal portion, 710: signal line, 711: lead wiring portion, 712: sealing material, 713: conductive layer, 714: conductive layer, 716: FPC, 717: IC, 721: source driver IC, 722: gate driver circuit portion, 723: FPC, 724: printed circuit board, 725: alignment film, 726: alignment film, 727: spacer, 728: wiring, 730: insulating film, 732: sealing layer, 734: insulating layer, 736: coloring layer, 738: light-shielding layer, 740: protective layer, 741: protective layer, 742: bonding layer, 743: resin layer, 744: insulating layer, 745: support substrate, 746: resin layer, 750: transistor, 752: transistor, 755: polarizing plate, 756: polarizing plate, 757: light source, 760: connection electrode, 770: planarization insulating film, 772: conductive layer, 773: insulating layer, 774: conductive layer, 775: liquid crystal element, 776: liquid crystal layer, 778: structure body, 780: anisotropic conductive film, 782: light-emitting element, 786: EL layer, 788: conductive film, 790: capacitor, 6000: display module, 6001: upper cover, 6002: lower cover, 6005: FPC, 6006: display device, 6009: frame, 6010: printed circuit board, 6011: battery, 6015: light-emitting portion, 6016: light-receiving portion, 6017a: light guide portion, 6017b: light guide portion, 6018: light, 6500: electronic device, 6501: housing, 6502: display portion, 6503: power supply button, 6504: button, 6505: speaker, 6506: microphone, 6507: camera, 6508: light source, 6510: protective member, 6511: display panel, 6512: optical member, 6513: touch sensor panel, 6515: FPC, 6516: IC, 6517: printed circuit board, 6518: battery, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7500: display portion

1. A semiconductor device comprising:
a substrate;
an insulating layer over the substrate; and
a transistor over the substrate and the insulating layer,
wherein the insulating layer has an island shape,
wherein the transistor comprises a gate electrode, a gate insulating layer, a semiconductor layer, and a pair of conductive layers,
wherein one of the pair of the conductive layers comprises a region overlapping with the insulating layer,
wherein the other of the pair of the conductive layers comprises a region not overlapping with the insulating layer,
wherein the level of an end surface of the other of the pair of the conductive layers is lower than the level of an end surface of the one of the pair of the conductive layers,
wherein each of the pair of the conductive layers is in contact with the semiconductor layer, and
wherein the semiconductor layer comprises a region overlapping with the gate electrode through the gate insulating layer.

2. The semiconductor device according to claim 1,
wherein the gate electrode is in contact with a top surface and a side surface of the insulating layer, and
wherein each of the pair of the conductive layers is in contact with a top surface of the semiconductor layer.

3. The semiconductor device according to claim 1,
wherein the gate electrode is in contact with a top surface and a side surface of the insulating layer, and
wherein each of the pair of the conductive layers is in contact with a bottom surface of the semiconductor layer.

4. The semiconductor device according to claim 1,
wherein the semiconductor layer is in contact with a top surface and a side surface of the insulating layer, and
wherein each of the pair of the conductive layers is in contact with a top surface of the semiconductor layer.

5. The semiconductor device according to claim 1,
wherein the one of the pair of the conductive layers is in contact with a top surface of the insulating layer,
wherein the other of the pair of the conductive layers is in contact with a side surface of the insulating layer, and
wherein each of the pair of the conductive layers is in contact with a bottom surface of the semiconductor layer.

6. The semiconductor device according to claim 1,
wherein a taper angle of the insulating layer is greater than or equal to 45° and less than 90°.

7. The semiconductor device according to claim 1,
wherein the semiconductor layer comprises a first layer and a second layer in this order from the gate insulating layer side, and
wherein the second layer comprises a region with a crystallinity higher than a crystallinity of the first layer.

8. The semiconductor device according to claim 1,
wherein the semiconductor layer comprises a first layer, a second layer, and a third layer in this order from the gate insulating layer side,
wherein the first layer comprises a region with a crystallinity higher than a crystallinity of the second layer, and
wherein the third layer comprises a region with a crystallinity higher than a crystallinity of the second layer.

9. A method of fabricating a semiconductor device, comprising:
a step of forming a first insulating layer and a second insulating layer over a substrate;
a step of forming a gate electrode in contact with a top surface and a side surface of the first insulating layer;
a step of forming a gate insulating layer over the gate electrode;
a step of forming, over the gate insulating layer, a semiconductor layer comprising a region overlapping with the gate electrode;
a step of forming a conductive film over the semiconductor layer;
a step of forming a resist over the conductive film;
a step of exposing the resist to light with use of a photomask having a light-shielding portion, thereby forming a first unexposed region over the first light-shielding portion that is shielded by the light-shielding portion and a second unexposed region between the first insulating layer and the second insulating layer;
a step of developing the resist to form a first resist mask and a second resist mask in the first unexposed region and the second unexposed region, respectively; and
a step of processing the conductive film using the first resist mask and the second resist mask as a mask to form a pair of conductive layers,
wherein the first insulating layer has an island shape,
wherein the second insulating layer has an island shape, and
wherein the pair of the conductive layers are apart from each other over the semiconductor layer.
